(19) United States
(12) Patent Application Publication
(10) Pub. No.: US 2022/0236785 A1
(43) Pub. Date: Jul. 28, 2022

(54) SEMICONDUCTOR DEVICE, SEMICONDUCTOR WAFER, AND ELECTRONIC DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Takahiko ISHIZU, Sagamihara (JP); Tatsuya ONUKI, Atsugi (JP); Hitoshi KUNITAKE, Isehara (JP)

(21) Appl. No.: 17/614,409

(22) PCT Filed: May 21, 2020
(86) PCT No.: PCT/IB2020/054810

§ 371 Date: Nov. 26, 2021

(30) Foreign Application Priority Data
Jun. 4, 2019 (JP) 2019-104242

(51) Int. Cl. G06F 1/3287; H01L 27/108; H01L 27/11

(52) U.S. Cl. CPC G06F 1/3287; H01L 27/11; H01L 27/108

(57) ABSTRACT

A semiconductor device with low power consumption is provided. The semiconductor device includes a power management unit, a CPU core, and a memory device, the power management unit includes a power switch and a power controller, and the memory device includes a working memory and a long-term memory storage portion. The power switch has a function of controlling supply of a power supply voltage to the CPU core and the memory device, and the power controller has a function of controlling operation of the power switch. The CPU core has a function of transmitting a timing of stopping the supply of the power supply voltage to the power controller, and the memory device has a function of saving data retained in the working memory to the long-term memory storage portion before the supply of the power supply voltage is stopped by the power switch. Transistors included in each of the power management unit and the CPU core are preferably Si transistors.

### TECHNICAL FIELD

One embodiment of the present invention relates to a semiconductor device, a semiconductor wafer, and an electronic device.

Furthermore, one embodiment of the present invention relates to an object, a driving method, or a manufacturing method. Alternatively, one embodiment of the present invention relates to a process, a machine, manufacture, or a composition of matter. One embodiment of the present invention relates to a driving method of any one of them or a manufacturing method of any one of them.

In this specification and the like, a semiconductor device generally means a device that can function by utilizing semiconductor characteristics. A memory device, a display device, an electro-optical device, a power storage device, a semiconductor circuit, and an electronic device include a semiconductor device in some cases.

### BACKGROUND ART

A reduction in power consumption of electronic devices is regarded as important. Thus, a reduction in the power consumption of integrated circuits (ICs) such as CPUs (Central Processing Units) is a major challenge in circuit design. The power consumption of ICs is broadly classified into operating power consumption (dynamic power) and non-operating (standby) power consumption (static power). Dynamic power increases when operation frequency is increased for higher performance. Most of the static power is power consumed by the leakage current of transistors. Examples of leakage current include subthreshold leakage current, gate tunnel leakage current, gate-induced drain leakage (GIDL) current, and junction tunnel leakage current. These leakage currents increase in accordance with scaling down of transistors. Thus, an increase in power consumption is a large barrier to high performance and high integration of ICs.

In order to reduce power consumption of a semiconductor device, circuits that do not need to operate are stopped by power gating or clock gating. Power gating has the effect of eliminating standby power because supply of power is stopped. In order to perform power gating in a CPU, it is necessary to back up contents stored in a register or a cache to a nonvolatile memory.

A memory circuit capable of retaining data even when power is off, which takes advantage of a feature of extremely low off-state current of a transistor whose active layer is formed using an oxide semiconductor (Oxide Semiconductor) (hereinafter, such a transistor is sometimes referred to as an “oxide semiconductor transistor” or an “OS transistor”), has been proposed. For example, Non-Patent Document 1 discloses an OS-SRAM (static random access memory) including a backup circuit that includes an OS transistor. Non-Patent Document 1 discloses that a microprocessor mounted with an OS-SRAM is capable of power gating in a short break-even time (BET) without affecting normal operation.

### REFERENCE

### Non-Patent Document

[Non-Patent Document 1] T. Ishizu et al., Int. Memory Workshop, 2014, pp. 106-103.
[Non-Patent Document 2] S. Baffling et al., ISSCC Dig. Tech. Papers, pp. 432-434, 2013.
[Non-Patent Document 3] N. Sakimura et al., ISSCC Dig. Tech. Papers, pp. 184-185, 2014.
[Non-Patent Document 4] V K. Singhal et al., ISSCC Dig. Tech. Papers, pp. 148-149, 2015.

### SUMMARY OF THE INVENTION

### Problems to be Solved by the Invention

For temporary retention of data, for example, an SRAM is included in a logic circuit such as a CPU. In addition, for example, a power management unit for driving or stopping the CPU may be included in a peripheral circuit of the CPU. Since various circuits can be provided in the CPU and its peripheral circuit as described above, the structures of transistors included in the CPU and the peripheral circuit or semiconductor layers of the transistors are preferably determined in accordance with their specifications.

An object of one embodiment of the present invention is to provide a semiconductor device with low power consumption. Another object of one embodiment of the present invention is to provide a semiconductor device with a small circuit area. Another object of one embodiment of the present invention is to provide a novel semiconductor device.

Note that the description of a plurality of objects does not preclude the existence of each object. One embodiment of the present invention does not necessarily achieve all the objects described as examples. Furthermore, objects other than those listed above are apparent from description of this specification and the like, and such objects can be objects of one embodiment of the present invention.

### Means for Solving the Problems

(1)

One embodiment of the present invention is a semiconductor device including a power management unit, a CPU core, and a memory device. The power management unit includes a power switch and a power controller. The power switch has a function of controlling supply of a power supply voltage to the CPU core and the memory device. The power controller has a function of controlling operation of the power switch. The memory device includes a working memory and a long-term memory storage portion. The CPU core has a function of transmitting a timing of stopping the supply of the power supply voltage, to the power controller. The memory device has a function of saving data retained in the working memory to the long-term memory storage portion before the supply of the power supply voltage is stopped by the power switch.

(2)

Another embodiment of the present invention is the semiconductor device with the above-described structure (1), in which each of the power management unit, the CPU core, and the memory device includes a transistor, and each of the transistors includes silicon in a channel formation region.

(3)

Another embodiment of the present invention is the semiconductor device with the above-described structure (1), in which the power management unit includes a transistor, and the transistor includes silicon in a channel formation region

(4)

Another embodiment of the present invention is the semiconductor device with the above-described structure (1), in which the CPU core includes a transistor, and the transistor includes silicon in a channel formation region.

(5)

Another embodiment of the present invention is the semiconductor device with the above-described structure (1), in which the memory device includes a transistor, and the transistor includes silicon in a channel formation region.

(6)

Another embodiment of the present invention is the semiconductor device with the above-described structure (1), in which each of the power management unit, the CPU core, and the memory device includes a transistor, and each of the transistors includes a metal oxide in a channel formation region.

(7)

Another embodiment of the present invention is the semiconductor device with the above-described structure (1), in which the power management unit includes a transistor, and the transistor includes a metal oxide in a channel formation region.

(8)

Another embodiment of the present invention is the semiconductor device with the above-described structure (1), in which the CPU core includes a transistor, and the transistor includes a metal oxide in a channel formation region.

(9)

Another embodiment of the present invention is the semiconductor device with the above-described structure (1), in which the memory device includes a transistor, and the transistor includes a metal oxide in a channel formation region.

(10)

Another embodiment of the present invention is the semiconductor device with any one of the above-described structures (6) to (9), in which the metal oxide is an In-M-Zn oxide (M is aluminum, gallium, yttrium, tin, copper, vanadium, beryllium, boron, titanium, iron, nickel, germanium, zirconium, molybdenum, lanthanum, cerium, neodymium, hafnium, tantalum, tungsten, or magnesium).

(11)

Another embodiment of the present invention is a semiconductor wafer including a plurality of semiconductor devices with any one of the above-described structures (1) to (10) and a separation region.

(12)

Another embodiment of the present invention is an electronic device including a semiconductor device with any one of the above-described structures (1) to (10) and a battery.

### Effect of the Invention

According to one embodiment of the present invention, a semiconductor device with low power consumption can be provided. According to another embodiment of the present invention, a semiconductor device with a small circuit area can be provided. According to another embodiment of the present invention, a novel semiconductor device can be provided.

Note that description of the plurality of effects does not preclude the existence of other effects. Furthermore, One embodiment of the present invention does not necessarily obtain all the effects listed above. In one embodiment of the present invention, an object other than the objects described as examples, an effect other than the effects described as examples, and a novel feature will be apparent from description of the specification and the like.

### BRIEF DESCRIPTION OF THE DRAWINGS

FIG. 1 is a block diagram illustrating a structure example of a processor (CPU).

FIG. 2 is a block diagram illustrating a structure example of a processor (RFIC).

FIG. 3 is a block diagram illustrating a structure example of a memory device.

FIG. 4 is a circuit diagram illustrating a structure example of a memory cell.

FIG. 5 is a timing chart showing an operation example of a memory device.

FIG. 6 is a circuit diagram illustrating a structure example of a memory cell.

FIG. 7 is a block diagram illustrating a structure example of a memory cell array.

FIG. 8 is a circuit diagram illustrating a structure example of a memory cell.

FIG. 9 is a circuit diagram illustrating a structure example of a memory cell.

FIG. 10 is a circuit diagram illustrating a structure example of a memory cell.

FIG. 11 is a circuit diagram illustrating a structure example of a memory cell.

FIG. 12 is a circuit diagram illustrating a memory cell, a voltage retention circuit, and a voltage generation circuit.

FIG. 13A and FIG. 13B are circuit diagrams illustrating structure examples of a voltage generation circuit.

FIG. 14 is a circuit diagram illustrating a structure example of a memory cell.

FIG. 15 is a schematic cross-sectional view illustrating a structure example of a semiconductor device.

FIG. 16A and FIG. 16B are schematic cross-sectional views illustrating structure examples of a semiconductor device.

FIG. 17A to FIG. 17C are schematic cross-sectional views illustrating structure examples of a semiconductor device.

FIG. 18 is a schematic cross-sectional view illustrating a structure example of a semiconductor device.

FIG. 19 is a schematic cross-sectional view illustrating a structure example of a semiconductor device.

FIG. 20 is a schematic cross-sectional view illustrating a structure example of a semiconductor device.

FIG. 21A is a schematic top view illustrating a structure example of a semiconductor device, and FIG. 21B and FIG. 21C are schematic cross-sectional views illustrating the structure example of the semiconductor device.

FIG. 22A is a table showing classification of crystal structures of IGZO, FIG. 22B is a graph showing an XRD spectrum of crystalline IGZO, and FIG. 22C is an image showing a nanobeam electron diffraction pattern of the crystalline IGZO.

FIG. 23A and FIG. 23B are top views of a semiconductor wafer.

FIG. 24A is a flow chart showing a manufacturing process of a semiconductor device, and FIG. 24B is a perspective view of the semiconductor device.

FIG. 25 is a diagram illustrating a hierarchical structure of an IoT network and tendencies of required specifications.

FIG. 26 is a conceptual diagram of factory automation.

FIG. 27A to FIG. 27F are perspective views illustrating examples of electronic devices.

FIG. 28 is a block diagram illustrating a structure example of a fabricated chip.

FIG. 29 is a block diagram illustrating a structure example of a fabricated DOSRAM.

FIG. 30A and FIG. 30B are schematic views illustrating structure examples of a DOSRAM.

FIG. 31 is a graph showing calculation results of active energy of a DOSRAM.

FIG. 32 is the layout of a fabricated DOSRAM.

FIG. 33 is a circuit diagram of a fabricated OS flip-flop.

FIG. 34 is an optical micrograph of a fabricated chip.

FIG. 35 is a graph showing retention characteristics of a fabricated chip.

FIG. 36 is a diagram showing backup-recovery waveforms of a fabricated chip.

FIG. 37 is an optical micrograph of a fabricated chip.

FIG. 38 is a graph showing temperature dependence of cutoff frequency fr.

### MODE FOR CARRYING OUT THE INVENTION

Embodiments of the present invention will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments and example.

Note that in structures of the invention described below, the same portions or portions having similar functions are denoted by the same reference numerals in different drawings, and a description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Unless otherwise specified, an on-state current in this specification refers to a drain current of a transistor in an on state. Unless otherwise specified, the on state of an n-channel transistor means that the voltage (V_{G}) between its gate and source is higher than or equal to the threshold voltage (Vₜₕ), and the on state of a p-channel transistor means that V_{G} is lower than or equal to Vₜₕ. For example, the on-state current of an n-channel transistor refers to a drain current when V_{G} is higher than or equal to Vₜₕ. Furthermore, the on-state current of a transistor depends on a voltage between a drain and a source (V_{D}) in some cases.

Unless otherwise specified, an off-state current in this specification refers to a drain current of a transistor in an off state. Unless otherwise specified, the off state of an n-channel transistor means that V_{G} is lower than Vₜₕ, and the off state of a p-channel transistor means that V_{G} is higher than Vₜₕ. For example, the off-state current of an n-channel transistor refers to a drain current when V_{G} is lower than Vₜₕ. The off-state current of a transistor depends on V_{G} in some cases. Thus, “the off-state current of a transistor is lower than 10⁻²¹ A” may mean that there is V_{G} at which the off-state current of the transistor is lower than 10⁻²¹ A.

Furthermore, the off-state current of a transistor depends on V_{D} in some cases. Unless otherwise specified, the off-state current in this specification may refer to an off-state current at V_{D} with an absolute value of 0.1 V, 0.8 V, 1 V, 1.2 V, 1.8 V, 2.5 V, 3 V, 3.3 V, 10 V, 12 V, 16 V, or 20 V. Alternatively, the off-state current may refer to an off-state current at V_{D} used in a semiconductor device or the like including the transistor.

Note that in this specification, a high power supply voltage and a low power supply voltage are sometimes referred to as an H level (or V_{DD}) and an L level (or GND), respectively.

In this specification, the embodiments described below can be combined with any of the other embodiments as appropriate. In addition, in the case where a plurality of structure examples are described in one embodiment, the structure examples can be combined as appropriate.

### Embodiment 1

In this embodiment, a semiconductor device of one embodiment of the present invention and a memory device included in the semiconductor device will be described.

For example, a memory device is incorporated in a processor (also referred to as a “processing unit”) that is the semiconductor device of one embodiment of the present invention, and the memory device can store data (including instructions) necessary for processing of the processor. In particular, the memory device is preferably a memory device that will be described in Embodiment 2. Examples of the processor include a CPU, a GPU (Graphics Processing Unit), a PLD (Programmable Logic Device), a DSP (Digital Signal Processor), an MCU (Microcontroller Unit), a custom LSI, and an RFIC.

### <<CPU>>

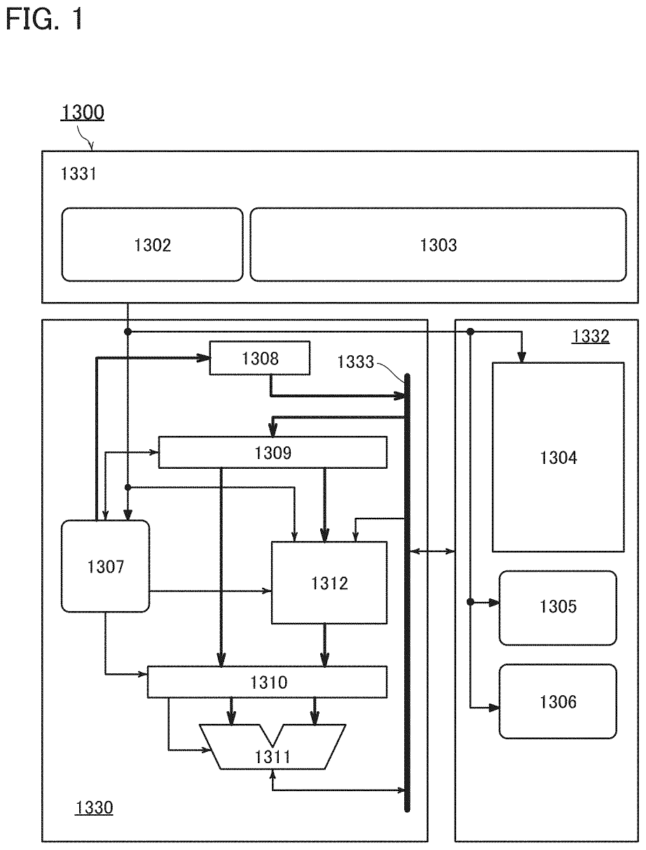

FIG. 1 is a block diagram illustrating a structure example of a CPU. A CPU 1300 illustrated in FIG. 1 includes a CPU core 1330, a power management unit (PMU) 1331, and a peripheral circuit 1332.

The CPU core 1330 includes a control device 1307, a program counter (PC) 1308, a pipeline register 1309, a pipeline register 1310, an arithmetic logic unit (ALU) 1311, a register file 1312, and a data bus 1333. Data is transmitted between the CPU core 1330 and the peripheral circuit 1332 via the data bus 1333.

The PMU 1331 includes a power controller 1302 and a power switch 1303. The peripheral circuit 1332 includes a cache memory 1304, a bus interface (BUS I/F) 1305, and a debug interface (Debug I/F) 1306.

For example, a structure of the memory device that will be described in Embodiment 2 can be used for the cache memory 1304. This can inhibit an increase in area and power consumption and increase the capacity of the cache memory 1304. Moreover, the standby power of the cache memory 1304 can be reduced; accordingly, the CPU 1300 with a small size and low power consumption can be provided.

The control device 1307 has functions of decoding and executing instructions contained in a program such as input applications by controlling the overall operations of the program counter 1308, the pipeline register 1309, the pipeline register 1310, the ALU 1311, the register file 1312, the cache memory 1304, the bus interface 1305, the debug interface 1306, and the power controller 1302.

The ALU 1311 has a function of performing a variety of arithmetic operations such as four arithmetic operations and logic operations. The cache memory 1304 has a function of temporarily storing frequently used data. The program counter 1308 is a register having a function of storing an address of an instruction to be executed next. Note that although not illustrated in FIG. 1, the cache memory 1304 is provided with a control circuit for controlling the operation of the cache memory 1304.

The pipeline register 1309 has a function of temporarily storing instruction data. The register file 1312 includes a plurality of registers including a general purpose register and can store data that is read from the main memory, data obtained as a result of arithmetic operations in the ALU 1311, or the like. The pipeline register 1310 has a function of temporarily storing data used for arithmetic operations performed in the ALU 1311, data obtained as a result of arithmetic operations in the ALU 1311, or the like.

The bus interface 1305 functions as a path for data between the CPU 1300 and devices outside the CPU 1300. The debug interface 1306 functions as a path of a signal for inputting an instruction to control debugging to the CPU 1300.

The power switch 1303 has a function of controlling supply of a power supply voltage to circuits other than the power controller 1302 in the CPU 1300. The CPU 1300 includes several power domains, and a circuit to be power gated belongs to any one of the power domains. The power switch 1303 controls supply of the power supply voltage to circuits belonging to the same power domain. The power controller 1302 has a function of controlling the operation of the power switch 1303. Note that the PMU 1331 may be provided with a circuit that generates a power supply voltage. With such a power supply management system, the CPU 1300 can perform power gating. An example of the procedure of the power gating will be described.

First, the CPU core 1330 sets the timing for stopping the supply of the power supply voltage in a register of the power controller 1302. Next, an instruction to start power gating is sent from the CPU core 1330 to the power controller 1302. Then, the registers and the cache memory 1304 in the CPU 1300 start data saving. Subsequently, the power switch 1303 stops the supply of the power supply voltage to the circuits other than the power controller 1302 in the CPU 1300. Then, an interrupt signal is input to the power controller 1302, thereby starting the supply of the power supply voltage to the circuits included in the CPU 1300. Note that a counter may be provided in the power controller 1302 to be used to determine the timing of starting the supply of the power supply voltage regardless of input of an interrupt signal. Next, the registers start data restoration. Furthermore, when the cache memory 1304 operates, for example, by a write-back method, data of an NVM 20 is loaded into an SMC 10. After that, execution of an instruction is resumed in the control device 1307.

As transistors included in the CPU core 1330, the power management unit (PMU) 1331, and the peripheral circuit 1332, for example, transistors including silicon in channel formation regions (hereinafter referred to as Si transistors) can be used. Single crystal silicon, microcrystalline silicon, polycrystalline silicon, hydrogenated amorphous silicon, or the like can be used as the silicon.

### <<RFIC>>

An RFIC is described as an example of a processor. The RFIC is also referred to as an RF tag, a wireless chip, a wireless ID chip, and the like. The RFIC includes a memory circuit, stores necessary information in the memory circuit, and transmits and receives information to/from the outside by using contactless means, for example, wireless communication. With these features, the RFIC can be used for an individual authentication system in which an object is recognized by reading the individual information of the object or the like, for example.

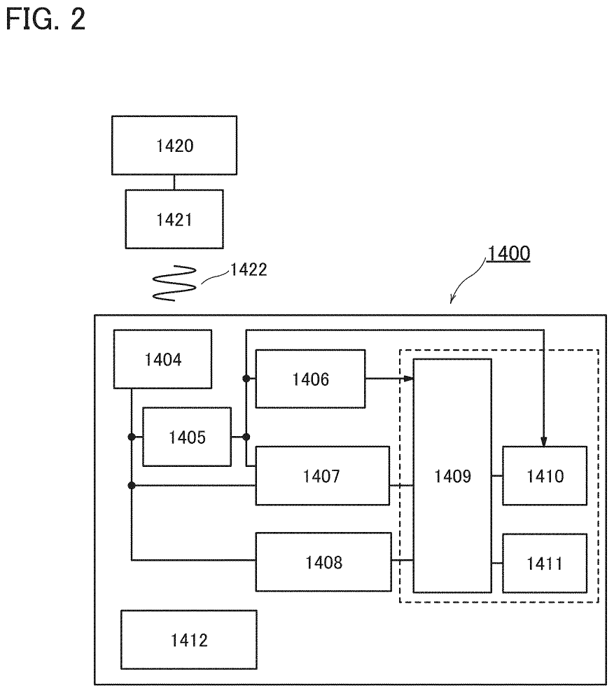

FIG. 2 is a block diagram illustrating a structure example of an RFIC. An RFIC 1400 includes an antenna 1404, a rectifier circuit 1405, a constant voltage circuit 1406, a demodulation circuit 1407, a modulation circuit 1408, a logic circuit 1409, a RAM 1410, a ROM (read-only memory) 1411, and a battery 1412. Decision whether each of these circuits is provided or not can be made as needed. For example, although the RFIC 1400 is of an active type, it may be of a passive type without the battery 1412. Here, although the RFIC 1400 is a semiconductor device including the antenna 1404, a semiconductor device not including the antenna 1404 can also be referred to as the RFIC 1400.

As the RAM 1410, for example, the memory device that will be described in Embodiment 2 can be used. Because the memory device has high compatibility with a CMOS circuit, circuits other than the antenna 1404 can be incorporated in one chip of the RFIC 1400, without complicating the manufacturing process. The antenna 1404 whose performance corresponds to the communication zone is mounted on the chip. As data transmission methods, an electromagnetic coupling method in which a pair of coils is provided so as to face each other and communicates with each other by mutual induction, an electromagnetic induction method in which communication is performed using an induction field, a radio wave method in which communication is performed using a radio wave, and the like are given. Any of these methods can be used in the RFIC 1400 described in this embodiment.

The antenna 1404 exchanges a radio signal 1422 with an antenna 1421 which is connected to a communication device 1420. The rectifier circuit 1405 generates an input voltage by rectification, for example, half-wave voltage doubler rectification of an input alternating signal generated by reception of a radio signal at the antenna 1404 and smoothing of the rectified signal with a capacitor provided in a later stage in the rectifier circuit 1405. Note that a limiter circuit may be provided on the input side or the output side of the rectifier circuit 1405. The limiter circuit controls power so that power which is higher than or equal to a certain level of power is not input to a circuit in a later stage if the amplitude of the input alternating signal is high and an internal generation voltage is high.

The constant voltage circuit 1406 generates a stable power supply voltage from an input voltage and supplies it to each circuit. Note that the constant voltage circuit 1406 may include a reset signal generation circuit. The reset signal generation circuit is a circuit which generates a reset signal of the logic circuit 1409 by utilizing the rise of the stable power supply voltage.

The demodulation circuit 1407 demodulates the input alternating signal by envelope detection and generates the demodulated signal. Furthermore, the modulation circuit 1408 performs modulation in accordance with data to be output from the antenna 1404.

The logic circuit 1409 decodes and processes the demodulated signal. The RAM 1410 retains the input information and includes a row decoder, a column decoder, a driver, a memory region, and the like. Furthermore, the ROM 1411 stores an identification number (ID) or the like and outputs it in accordance with processing.

Note that this embodiment can be combined with any of the other embodiments in this specification as appropriate.

### Embodiment 2

In this embodiment, an example of a memory device included in a semiconductor device will be described.

The memory device of this embodiment is nonvolatile and includes a memory portion A that includes a memory cell capable of high-speed processing and a memory portion B that includes a memory cell capable of retaining data for a long time even when power is off.

The memory portion A corresponds to a working memory, and data exchange between a host device and the memory device is performed in a first memory. The memory portion B corresponds to a long-term memory storage portion and retains information written in the memory portion A for a long time. The memory portion B has a lower processing speed than the memory portion A but has a higher capacity than the memory portion A. Moreover, the memory portion B can retain data for a long time in a state where the power is off

### <<Memory Device 100>>

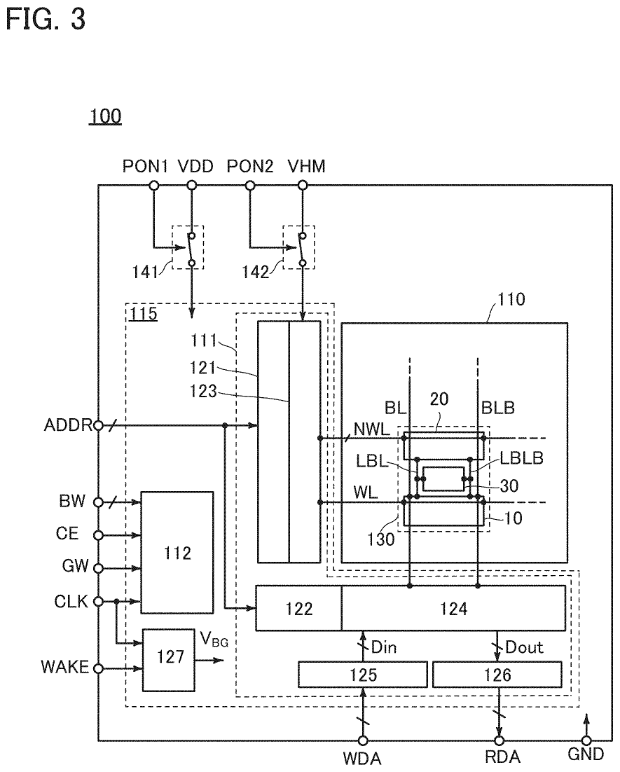

FIG. 3 is a block diagram illustrating a structure example of the memory device. A memory device 100 illustrated in FIG. 3 includes a memory cell array 110, a peripheral circuit 111, a control circuit 112, a voltage generation circuit 127, a power switch (PSW) 141, and a PSW 142. Note that in FIG. 3, a peripheral circuit 115 is illustrated as a circuit including the peripheral circuit 111, the control circuit 112, and the voltage generation circuit 127.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal. The signal CE, the signal GW, and the signal BW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 112.

The control circuit 112 is a logic circuit having a function of controlling the overall operation of the memory device 100. For example, the control circuit 112 performs a logical operation on the signal CE, the signal GW, and the signal BW to determine an operation mode of the memory device 100 (e.g., a writing operation or a reading operation). Alternatively, the control circuit 112 generates a control signal for the peripheral circuit 111 so that the operation mode is executed.

The memory cell array 110 includes a plurality of memory cells 130 and a plurality of wirings WL, NWL, BL, and BLB. The plurality of memory cells 130 are arranged in a matrix.

The memory cells 130 arranged in the same row are electrically connected to the wiring WL and the wiring NWL in the row. The wiring WL and the wiring NWL are each a word line, and the wiring BL and the wiring BLB are a bit line pair for transmitting complementary data. The wiring BLB is a bit line to which data whose logic is inverted from that of the wiring BL is input, and is referred to as a complementary bit line or an inverted bit line in some cases. The memory cell 130 includes two kinds of memory circuits 10 and 20. The memory circuit 10 (hereinafter referred to as “SMC 10”) is a memory circuit that can store 1-bit complementary data. The memory circuit 20 (hereinafter referred to as “NVM 20”) is a memory circuit that can store n-bit (n is an integer larger than 1) complementary data, and can retain data for a long time in a state where power is off. That is, the SMC 10 is a memory cell that constitutes the above-described memory portion A (working memory), and the NVM 20 is a memory cell that constitutes the above-described memory portion B (long-term memory storage portion).

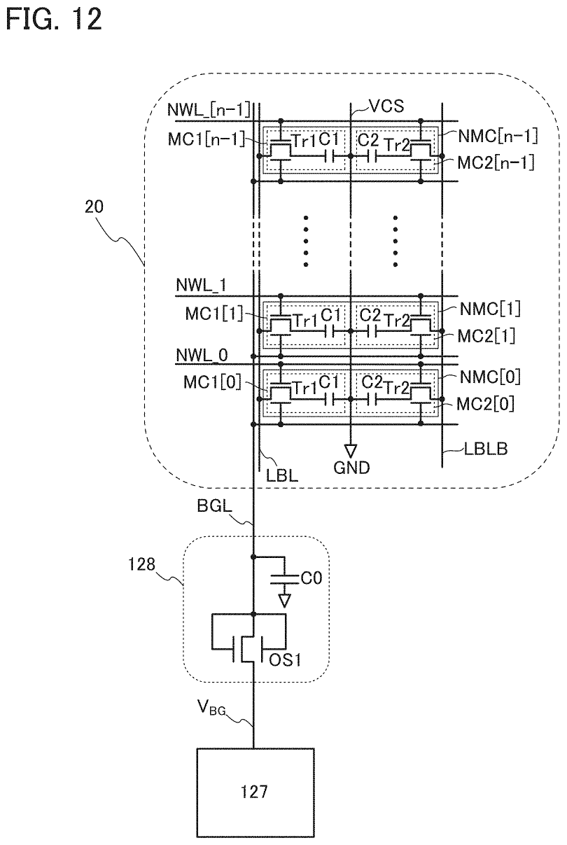

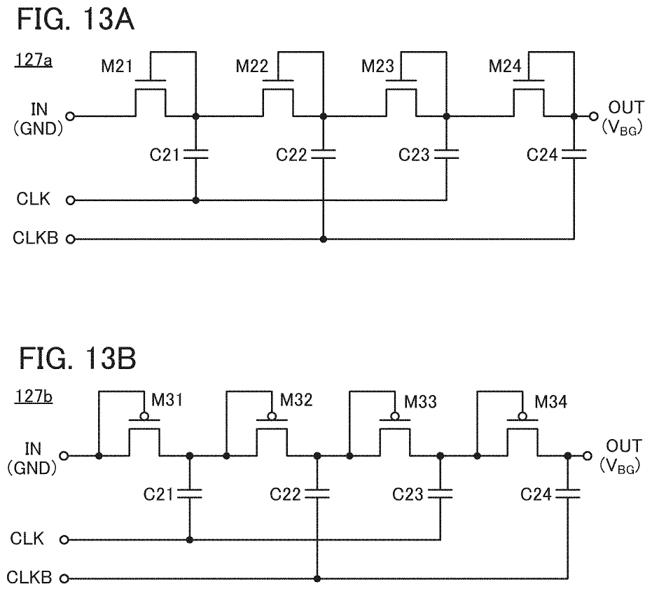

The voltage generation circuit 127 has a function of generating a negative voltage (V_{BG}). V_{BG} is applied to a transistor used in the NVM 20. The signal WAKE functions as a signal that controls input of the signal CLK to the voltage generation circuit 127. For example, when an H-level signal is applied as the signal WAKE, the signal CLK is input to the voltage generation circuit 127, and the voltage generation circuit 127 generates V_{BG}. Note that the details of the voltage generation circuit 127 will be described with reference to after-mentioned FIG. 12 and FIG. 13.

The SMC 10 and the NVM 20 are electrically connected through a local bit line pair (a wiring LBL and a wiring LBLB). The wiring LBL is a local bit line with respect to the wiring BL, and the wiring LBLB is a local bit line with respect to the wiring BLB. The SMC 10 and the NVM 20 are electrically connected through the wiring LBL and the wiring LBLB. The memory cell 130 includes a circuit 30 (hereinafter referred to as “LPC 30”). The LPC 30 is a local precharge circuit for precharging the wiring LBL and the wiring LBLB. A control signal for the LPC 30 is generated in the peripheral circuit 111.

The peripheral circuit 111 is a circuit for writing and reading data to/from the memory cell array 110. The peripheral circuit 111 has a function of driving the wiring WL, the wiring NWL, the wiring BL, and the wiring BLB. The peripheral circuit 111 includes a row decoder 121, a column decoder 122, a row driver 123, a column driver 124, an input circuit 125, and an output circuit 126.

The row decoder 121 and the column decoder 122 have a function of decoding the signal ADDR. The row decoder 121 is a circuit for specifying a row to be accessed, and the column decoder 122 is a circuit for specifying a column to be accessed. The row driver 123 has a function of selecting the wiring WL and the wiring NWL in a row specified by the row decoder 121.

Specifically, the row driver 123 has a function of generating a signal for selecting the wiring WL and the wiring NWL. The column driver 124 has a function of writing data to the memory cell array 110, reading data from the memory cell array 110, retaining the read data, precharging the wiring BL and the wiring BLB, and the like.

The input circuit 125 has a function of retaining the signal WDA. Data retained by the input circuit 125 is output to the column driver 124. Output data (Din) of the input circuit 125 is data written to the memory cell array 110. Data (Dout) read from the memory cell array 110 by the column driver 124 is output to the output circuit 126. The output circuit 126 has a function of retaining Dout. The output circuit 126 outputs the retained data to the outside of the memory device 100. The output data is the signal RDA.

The PSW 141 has a function of controlling supply of VDD to a circuit other than the memory cell array 110 (e.g., the peripheral circuit 115). The PSW 142 has a function of controlling supply of VHM to the row driver 123. Here, in the memory device 100, a high power supply voltage is VDD and a low power supply voltage is GND (a ground potential). In addition, VHM is a high power supply voltage used for setting the wiring NWL to a high level and is higher than VDD. The on/off of the PSW 141 is controlled by the signal PON1, and the on/off of the PSW 142 is controlled by the signal PON2. The number of power domains to which VDD is supplied is one in the peripheral circuit 115 in FIG. 3 but can be two or more. In this case, a power switch is provided for each power domain.

As switches included in the PSW 141 and the PSW 142, for example, electrical switches or mechanical switches can be used. In particular, when electrical switches are used as the switches included in the PSW 141 and the PSW 142, OS transistors, Si transistors, or the like can be used as the electrical switches, for example.

### <<Memory Cell 130>>

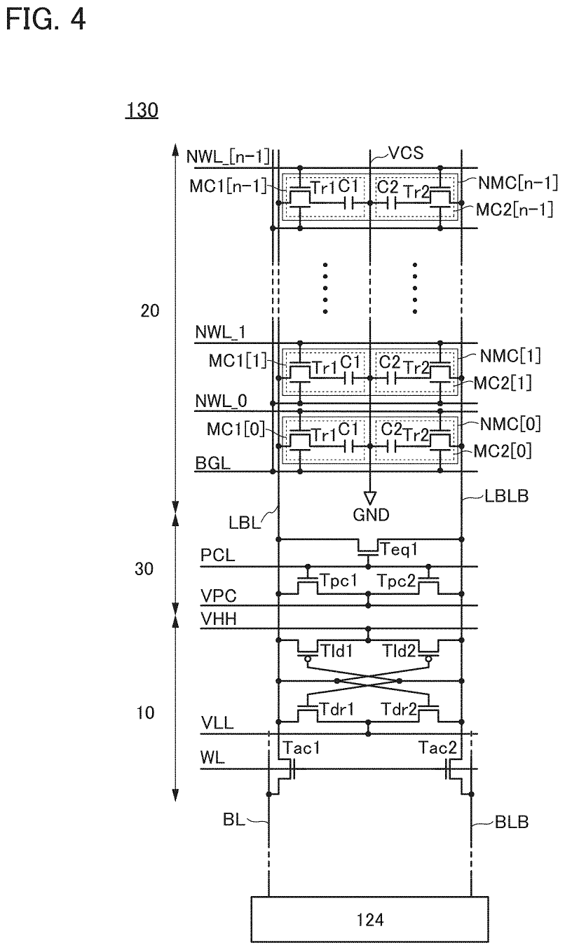

FIG. 4 illustrates a circuit structure example of the memory cell 130.

### <SMC 10>

The SMC 10 is electrically connected to the wiring BL, the wiring BLB, the wiring LBL, the wiring LBLB, a wiring VHH, and a wiring VLL.

The SMC 10 has a circuit structure similar to that of a CMOS type (6-transistor type) SRAM cell and includes a transistor Tld1, a transistor Tld2, a transistor Tdr1, a transistor Tdr2, a transistor Tac1, and a transistor Tac2. The transistor Tld1 and the transistor Tld2 are load transistors (pull-up transistors), the transistor Tdr1 and the transistor Tdr2 are driving transistors (pull-down transistors), and the transistor Tac1 and the transistor Tac2 are access transistors (transfer transistors).

The conduction state between the wiring BL and the wiring LBL is controlled by the transistor Tac1. The conduction state between the wiring BLB and the wiring LBLB is controlled by the transistor Tac2. On/off of the transistor Tac1 and the transistor Tac2 is controlled by the potential of the wiring WL. The transistor Tld1 and the transistor Tdr1 form an inverter, and the transistor Tld2 and the transistor Tdr2 form an inverter. An input terminal of each of these two inverters is electrically connected to an output terminal of the other, whereby a latch circuit is formed. A power supply voltage is supplied to the two inverters through the wiring VHH and the wiring VLL.

### <NVM 20>

The NVM 20 illustrated in FIG. 4 includes n (n is an integer greater than or equal to 1) circuits NMC. The n circuits NMC are electrically connected to different wirings NWL. Furthermore, the n circuits NMC are electrically connected to one wiring VCS. To distinguish the n circuits NMC from each other, signs such as [0] and [1] are used. To distinguish the n wirings NWL from each other, signs such as _0 and _1 are used.

The circuit NMC is a memory circuit (also can be referred to as a memory cell) that can retain 1-bit complementary data. The circuit NMC includes a circuit MC1 and a circuit MC2. The circuit MC1 is a memory cell for retaining data written to the wiring LBL, and the circuit MC2 is a memory cell for retaining data written to the wiring LBLB. The circuit MC1 and circuit MC2 each have a circuit structure similar to that of a 1-transistor 1-capacitor type dynamic random access memory (DRAM) memory cell. The circuit MC1 includes a transistor Tr1 and a capacitor C1. The circuit MC2 includes a transistor Tr2 and a capacitor C2. The capacitor C1 functions as a storage capacitor of the circuit MC1, and the capacitor C2 functions as a storage capacitor of the circuit MC2. The wiring VCS is a power supply line for the storage capacitors of the circuit MC1 and circuit MC2, and a ground potential (GND) is input here.

A gate (first gate) of each of the transistor Tr1 and the transistor Tr2 is electrically connected to the wiring NWL. One of a source and a drain of the transistor Tr1 is electrically connected to the wiring LBL, and one of a source and a drain of the transistor Tr2 is electrically connected to the wiring LBLB. A first terminal of the capacitor C1 is electrically connected to the other of the source and the drain of the transistor Tr1, and a second terminal of the capacitor C1 is electrically connected to the wiring VCS. A first terminal of the capacitor C2 is electrically connected to the other of the source and the drain of the transistor Tr2, and a second terminal thereof is electrically connected to the wiring VCS.

Each of the transistor Tr1 and the transistor Tr2 includes a second gate. The second gate of each of the transistor Tr1 and the transistor Tr2 is electrically connected to a wiring BGL. The wiring BGL is a signal line to which a signal for controlling the potential of the second gates of the transistor Tr1 and the transistor Tr2 is input, or a power supply line to which a fixed potential is input. The threshold voltages of the transistor Tr1 and the transistor Tr2 can be controlled by the potential of the wiring BGL. Thus, the transistor Tr1 and the transistor Tr2 can be prevented from being normally on.

Reducing the off-state current of the transistor Tr1 and the transistor Tr2 can increase the retention time of the circuit NMC. An extremely low off-state current means that, for example, off-state current per micrometer of channel width is lower than or equal to 100 zA (zeptoamperes). Note that since the off-state current is preferably as low as possible, the normalized off-state current is preferably lower than or equal to 10 zA/μm or lower than or equal to 1 zA/μm, further preferably lower than or equal to 10 yA (yoctoamperes)/μm. Note that 1 zA is 1×10⁻²¹ A and 1 yA is 1×10⁻²⁴ A.

To obtain such an extremely low off-state current, a channel formation region of a transistor is formed using a semiconductor with a wide bandgap. An example of such a semiconductor is an oxide semiconductor. An oxide semiconductor has a bandgap of 3.0 eV or larger; thus, an OS transistor has a low leakage current due to thermal excitation and also has an extremely low off-state current. Note that the details of the OS transistor and the oxide semiconductor will be explained in after-mentioned Embodiment 3.

When the transistor Tr1 and the transistor Tr2 are OS transistors, the retention time of the circuit NMC can be prolonged, and the circuit NMC can be used as a nonvolatile memory circuit. Moreover, the OS transistor has small temperature dependence of off-state current characteristics. Thus, the normalized off-state current of an OS transistor can be lower than or equal to 100 zA even at high temperatures (e.g., 100° C. or higher). Thus, when the OS transistor is applied to the circuit NMC, the circuit NMC can retain data without loss of data even in a high-temperature environment. As a result, the memory device 100 having high reliability even in a high-temperature environment can be obtained.

The circuit NMC can retain complementary data by including a pair of memory cells (the circuit MC1 and the circuit MC2) and can retain the complementary data for a long time by using OS transistors as the transistor Tr1 and the transistor Tr2. Since the complementary data is retained in the circuit NMC, the SMC 10 can function as a differential amplifier circuit at the time of reading the complementary data retained in the circuit NMC. For this reason, even when a voltage difference between the voltage retained by the capacitor C1 of the circuit MC1 and the voltage retained by the capacitor C2 of the circuit MC2 is small, reading operation with high reliability can be performed. Moreover, the circuit NMC can perform high-speed reading operation and high-speed writing operation as well as a DRAM memory cell does.

Note that the second gates of the transistor Tr1 and the transistor Tr2 included in the NVM 20 may be omitted depending on circumstances. In the case where the transistor Tr1 and the transistor Tr2 do not include the second gates, the manufacturing process of the memory device 100 can be simplified. Furthermore, the voltage generation circuit 127 illustrated in FIG. 3 can also be omitted.

Other than OS transistors, for example, Si transistors can be used as the transistor Tr1 and the transistor Tr2 that do not include second gates. Since the Si transistor can have a higher on-state current than the OS transistor, data writing to MC1 and MC2 and data reading from the circuit MC1 and the circuit MC2 can be performed at high speed.

### <LPC 30>

The LPC 30 is electrically connected to a wiring PCL and a wiring VPC. The wiring PCL is a signal line for supplying a signal for controlling precharge operation of the wiring LBL and the wiring LBLB. The wiring VPC is a power supply line for supplying a precharge voltage. The LPC 30 includes a transistor Teq1, a transistor Tpc1, and a transistor Tpc2. Gates of the transistor Teq1, the transistor Tpc1, and the transistor Tpc2 are electrically connected to the wiring PCL. The transistor Teq1 controls the conduction state between the wiring LBL and the wiring LBLB. The transistor Tpc1 controls the conduction state between the wiring LBL and the wiring VPC. The transistor Tpc2 controls the conduction state between the wiring LBLB and the wiring VPC.

In the example of FIG. 4, the transistor Teq1, the transistor Tpc1, and the transistor Tpc2 are n-channel transistors, but they may also be p-channel transistors. Alternatively, the transistor Teq1 is not necessarily provided in the LPC 30. In that case, the transistor Tpc1 and the transistor Tpc2 may be either n-channel transistors or p-channel transistors. Alternatively, the LPC 30 can be constituted only by the transistor Teq1. In that case, the transistor Teq1 may also be either an n-channel transistor or a p-channel transistor. The LPC 30 that is constituted by the transistor Teq1 precharges the wirings LBL and LBLB by smoothing the potentials of the wiring LBL and the wiring LBLB.

As the transistor Teq1, the transistor Tpc1, and the transistor Tpc2, for example, Si transistors can be used.

The peripheral circuit 111 has a function of supplying potentials to various kinds of power supply lines (the wiring VHH, the wiring VLL, and the wiring VPC) provided in the memory cell array 110. Therefore, when the PSW 141 is turned off and the supply of VDD to the peripheral circuit 111 is stopped, the supply of potentials to these power supply lines is also stopped.

In a standby state of the memory cell 130 in FIG. 4, an increase in leakage current flowing through the SMC 10 increases static power. In order to reduce the static power, voltage that is lower than VDD should be supplied to the wiring VHH. In the case where a new voltage is supplied to the wiring VHH, however, a circuit that generates the voltage (voltage generation circuit) needs to be additionally provided, which causes an increase in area overhead. Note that the standby state used here refers to a state in which all the word lines in the memory cell 130 (the wiring WL and wiring NWL_0 to the wiring NWL_[n−1]) are not selected.

In order to solve the above problem, in the standby state of the memory cell 130, it is preferable that GND be supplied to the wiring VLL and a precharge voltage be supplied to the wiring VHH. The precharge voltage is lower than VDD. Furthermore, the precharge voltage is also used for the LPC 30, and thus another voltage generation circuit does not need to be provided. Furthermore, the precharge voltage may be supplied to the wiring VLL and VDD may be supplied to the wiring VHH. Supplying the precharge voltage to one of the wiring VHH and the wiring VLL can reduce the static power of the memory device 100.

### <<Operation Example of Memory Device 100>>

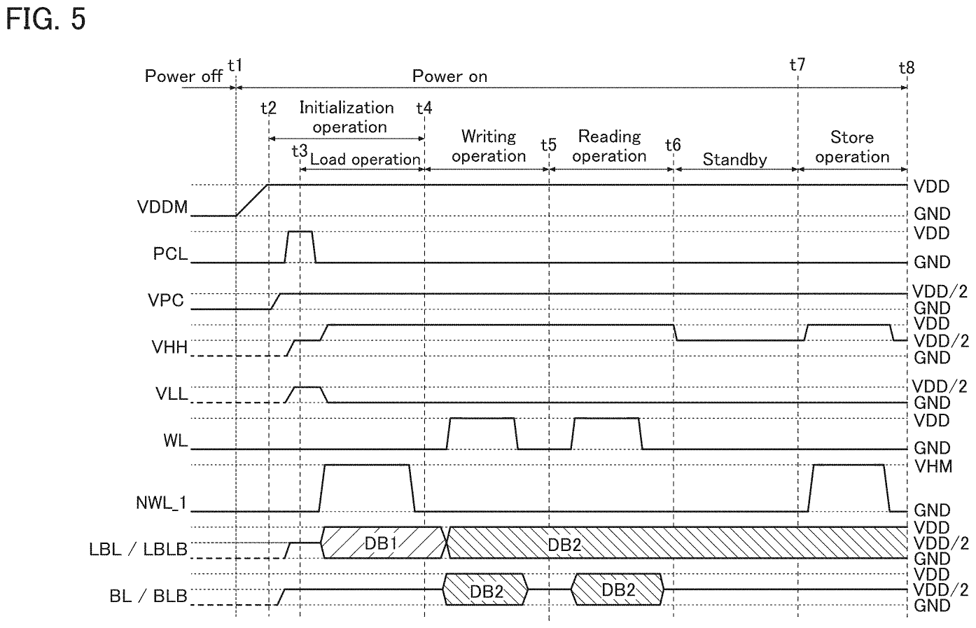

An operation example of the memory device 100 is described using a timing chart in FIG. 5. In this example, an access target during a period during which the host device processes a task is only the SMC 10. When the task is completed, data is transferred from the SMC 10 to the NVM 20, and the data is written to one of the circuits NMC in the NVM 20 (store operation). Furthermore, in the case where another task is executed, the data is transferred from the one of the circuits NMC in the NVM 20 to the SMC 10 (load operation). Here, the operation example of the memory device 100 is described assuming that the transfer destination and the transfer source of the data are a circuit NMC[1].

Time t1 to Time t8 denoted in FIG. 5 represent timings of operations. A wiring VDDM is a power supply line for VDD supply that is provided in the memory device 100. The supply of VDD to the wiring VDDM is controlled by the PSW 141. In addition, for the wiring VHH, the wiring VLL, and the like, waveforms represented by thick dotted lines show that the potentials are uncertain. Furthermore, a low level (L level) for the wiring VDDM or the like is GND. A high level (H level) for the wiring PCL and the wiring WL is VDD, and a high level for the wiring NWL_0 to the wiring NWL_[n−1] is VHM.

Note that the reason why the high level for the wiring NWL_0 to the wiring NWL_[n−1] is VHM is that the threshold voltages of the transistor Tr1 and the transistor Tr2 are assumed to be higher than the threshold voltages of the other transistors such as the transistor Tac1. In the case where data can be written to/read from the NVM 20 by applying VDD to the wiring NWL_0 to the wiring NWL_[n−1], the high level for the wiring NWL_0 to the wiring NWL_[n−1] can be set to VDD. In that case, the PSW 142 is not necessarily provided in the memory device 100 (see FIG. 3).

### <Power Gating>

First, the power gating operation of the memory device 100 is described. Before Time t1, the memory device 100 is in a power-off state in which the supply of VDD is stopped. After Time t1, the memory device 100 is in a power-on state in which VDD is supplied.

Before Time t1, the PSW 141 is turned off and the memory device 100 is in the power-off state. The wiring VDDM is at GND. In addition, the wiring WL, the wiring NWL_0 to the wiring NWL_[n−1], the wiring PCL, and the wiring VPC are also at GND because the supply of VDD to the peripheral circuit 111 is also stopped when the PSW 141 is turned off.

When the PSW 141 is turned on at Time t1, the wiring VDDM is charged, and then its potential is increased to VDD. A period from Time t1 to Time t2 is a time required for power supply resumption. Note that in the timing chart in FIG. 5, the PSW 142 is turned on and off in accordance with the on/off of the PSW 141.

### <Initialization and Load>

When the power is from t2 to Time t4, an initialization operation for bringing the memory device 100 into an initial state is performed. In the operation from Time t2 to Time t3, the bit line pair and the local bit line pair are precharged. Specifically, the wiring VPC, the wiring VHH, and the wiring VLL are set to VDD/2. The bit line pair (the wiring BL and the wiring BLB) and the local bit line pair (the wiring LBL and the wiring LBLB) are each precharged to VDD/2. The precharging of the bit line pair is performed by the column driver 124, and the precharging of the local bit line pair is performed by the LPC 30. By setting the wiring PCL to a high level (H level), the transistor Teq1, the transistor Tpc1, and the transistor Tpc2 are turned on, and precharging and potential smoothing of the wiring LBL and the wiring LBLB are performed.

From Time t3 to Time t4, the memory device 100 performs load operation. Data is loaded from the circuit NMC[1] in the NVM 20 to the SMC 10. Here, the circuit NMC[1] stores data DB1. The wiring PCL is set to an L level, so that the wiring LBL and the wiring LBLB are brought into a floating state. Next, the wiring NWL_1 is set to an H level, so that the transistor Tr1 of a circuit MC1[1] and the transistor Tr2 of a circuit MC2[1] are turned on. The data DB1 is written to the wiring LBL and the wiring LBLB. After the wiring NWL_1 is set to an H level, the wiring VHH is set to VDD and the wiring VLL is set to GND, whereby the SMC 10 is made active. The SMC 10 amplifies and retains the data DB1 written to the wiring LBL and the wiring LBLB. In the case where the MC1[1] retains “1”, the wiring LBL is at VDD and the wiring LBLB is at GND. The wiring NWL_1 is kept at an H level for a certain period, and then set to an L level; thus, the load operation is completed.

### <Writing>

From Time t4 to Time t5, the memory device 100 performs data writing operation. Here, data written to the SMC 10 is data DB2. When write access occurs, the data DB2 is written to the bit line pair by the column driver 124. Here, when the wiring BL is at VDD, the wiring BLB is at GND. The row address is decoded by the row decoder 121, and the wiring WL in a row specified by the row address is set to an H level by the row driver 123. Thus, the transistor Tac1 and the transistor Tac2 are turned on, and the data DB2 is written to the local bit line pair. The wiring WL is kept at an H level for a certain period, and then set to an L level. After the wiring WL is set to an L level, the bit line pair are precharged to VDD/2 and then brought into a floating state by the column driver 124. The writing operation is thus completed.

### <Reading>

From Time t5 to Time t6, the memory device 100 performs data reading operation.

When reading access occurs, the row address is decoded by the row decoder 121, and the wiring WL in a row specified by the row address is set to an H level by the row driver 123. Thus, the transistor Tac1 and the transistor Tac2 are turned on, and the data DB2 of the local bit line pair is written to the bit line pair. The data DB2 written to the bit line pair is read by the column driver 124. The wiring WL is kept at an H level for a certain period, and then set to an L level. After the wiring WL is set to an L level, the bit line pair is charged to VDD/2 and then brought into a floating state by the column driver 124. The data reading operation is thus completed.

### <Standby>

From Time t6 to Time t7, the memory device 100 is in a standby state where access is not requested from the host device. By making the SMC 10 active at this time, the memory device 100 can respond quickly to the next access request. Furthermore, by lowering the wiring VHH from VDD to VDD/2 at this time, the static power of the SMC 10 can be reduced in the memory device 100. In FIG. 5, the static power of the memory device 100 is reduced by setting the wiring VHH to VDD/2 and the wiring VLL to GND; alternatively, the static power may be reduced by setting the wiring VHH to VDD and the wiring VLL to VDD/2.

Note that in this embodiment, the precharge voltage is set to VDD/2, but not limited to this. The value of the precharge voltage can be selected in the range higher than GND and lower than VDD.

Note that the above-described operation for static power reduction may be performed individually on the memory cell 130. Specifically, in the case where the memory cell 130 for which access is required and the memory cell 130 in a standby state coexist in the memory device 100, the above-described operation for static power reduction may be performed only on the memory cell 130 in a standby state.

### <Store>

From Time t7 to Time t8, the memory device 100 performs data store operation. When the memory device 100 receives an instruction to execute another task or an instruction to terminate a task from the host device, the memory device 100 performs store operation. First, the wiring VHH is returned to VDD, and the wiring NWL_1 is set to an H level. The data DB2 written to the local bit line pair is written to the circuit NMC[1]. Here, when the wiring LBL is at VDD, the MC1 [1] retains “1” and the MC2 [1] retains “0”.

The wiring NWL_1 is kept at an H level for a certain period, and then set to an L level. The store operation is thus completed. Next, the memory device 100 sets the wiring VHH to VDD/2 and waits an instruction from the host device. After that, the memory device 100 performs data reading operation or data writing operation in accordance with access request from the host device.

### <<Modification Example of Memory Cell>

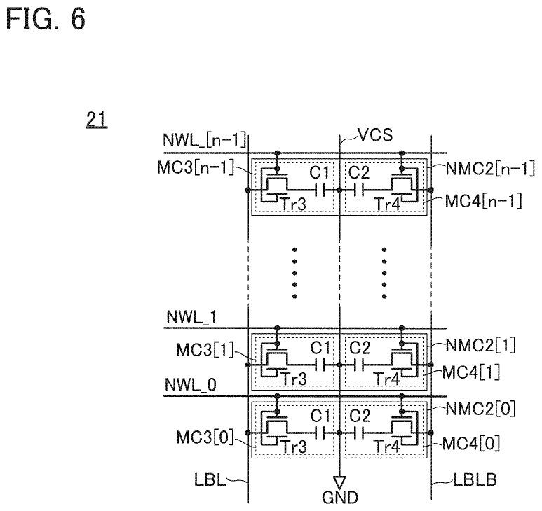

An NVM 21 illustrated in FIG. 6 is a memory circuit including n circuits NMC2. The circuit NMC2 includes a circuit MC3 and a circuit MC4. The circuit MC3 is a modification example of the circuit MC1 and is provided with a transistor Tr3 instead of the transistor Tr1. The circuit MC4 is a modification example of the circuit MC2 and is provided with a transistor Tr4 instead of the transistor Tr2.

The transistor Tr3 is provided with a second gate, and the second gate and a first gate are electrically connected. Similarly, the transistor Tr4 is provided with a second gate, and the second gate and a first gate are electrically connected. Electrical connection between the second gate and the first gate can improve the on-state current of the transistor Tr3 and the transistor Tr4.

### <<Device Structure of Memory Cell Array>>

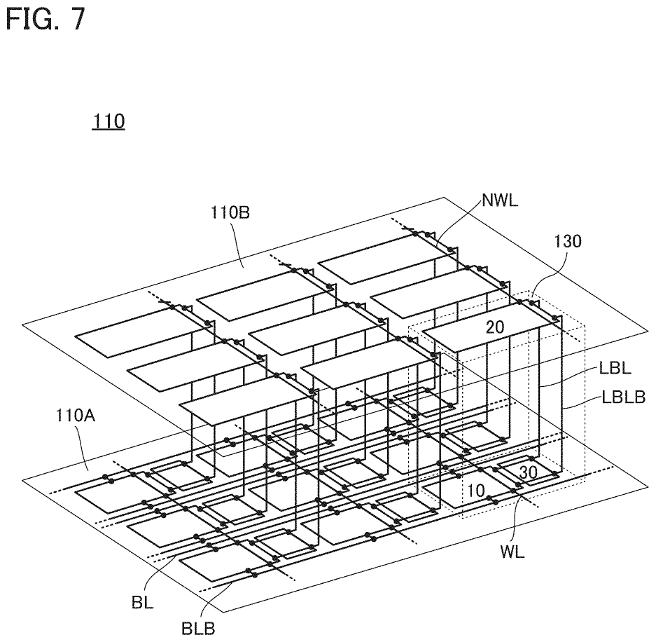

In the memory device 100, the transistor Tr1 and the transistor Tr2 in the NVM 20 can be OS transistors and the other transistors can be, for example, Si transistors or the like. In that case, the memory cell array 110 can have a device structure in which a circuit including the OS transistors is stacked over a circuit including the Si transistors. FIG. 7 schematically illustrates a device structure example of the memory cell array 110.

### <Memory Cell Array>

In the example of FIG. 7, a memory cell array 110B is stacked over a memory cell array 110A. In the memory cell array 110A, SMCs 10 and LPCs 30 are arranged in a matrix. In the memory cell array 110B, NVMs 20 are arranged in a matrix. The memory cell array 110A forms the memory portion A with a high response speed, and the memory cell array 110B forms the memory portion B for long-term data storage. By stacking the memory cell array 110B over the memory cell array 110A, an increase in capacity and a reduction in size of the memory device 100 can be performed effectively.

### <Twin Cell Architecture>

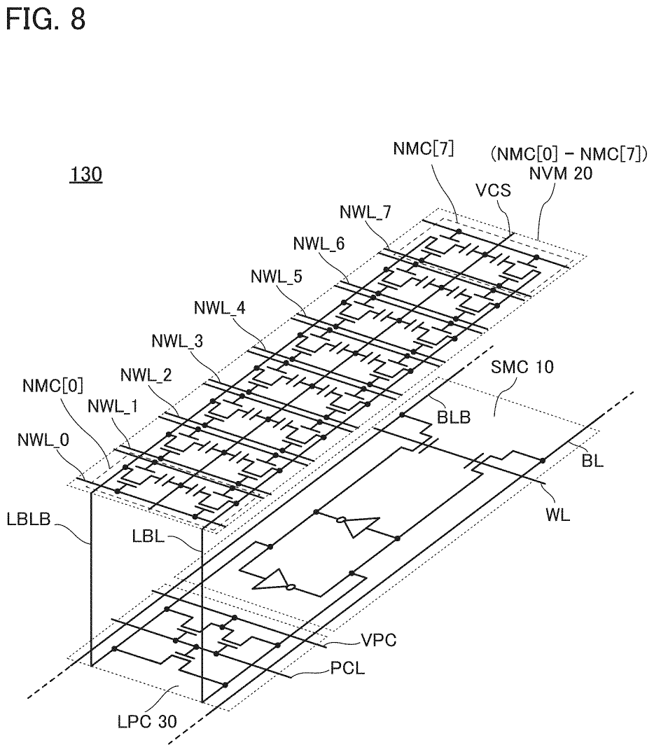

Focusing on one of the memory cells 130, the NVM 20 is formed over a region where the SMC 10 and the LPC 30 are formed. FIG. 8 is a circuit diagram schematically illustrating a device structure example of the memory cell 130. FIG. 8 illustrates an example in which the NVM 20 has a circuit structure for storing 8-bit complementary data. Thus, the NVM 20 includes a circuit NMC[0] to a circuit NMC[7]. The circuit NMC[0] to the circuit NMC[7] are provided over the region where the SMC 10 and the LPC 30 are formed. Note that the above-described structure of the memory cell 130 (the structure in which two complementary memory cells (the circuit MC1 and the circuit MC2) are connected to one wiring NWL) is called twin cell architecture.

Note that in the memory cell 130, the number of circuits NMC is preferably a multiple of 8. That is, the number of bits of data that can be retained by the NVM 20 is preferably a multiple of 8. When the number of circuits NMC is a multiple of 8, the memory cell 130 can handle data in units, for example, of bytes (8 bits), words (32 bits), or half-words (16 bits) units.

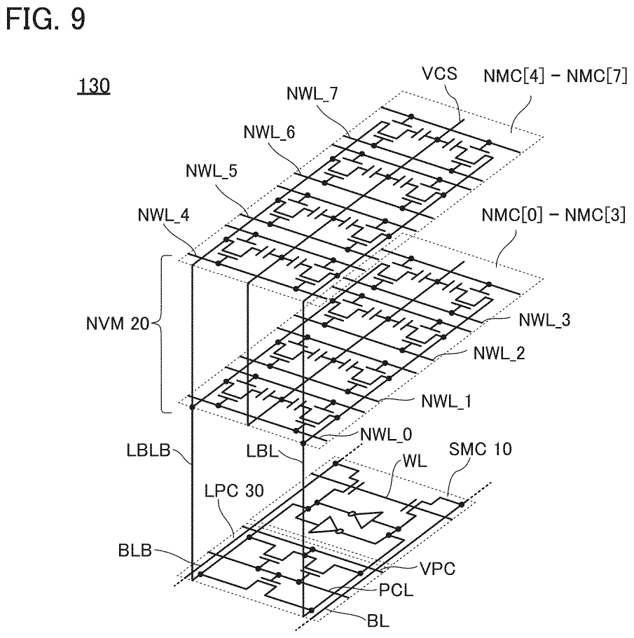

An OS transistor can be stacked over an OS transistor. Accordingly, the memory cell array 110B can have a device structure in which two or more layers of circuits are stacked. FIG. 9 illustrates a device structure example of the memory cell 130 in the case where two memory cell arrays 110B are stacked. Also here, the NVM 20 includes the circuit NMC[0] to the circuit NMC[7]. The circuit NMC[0] to the circuit NMC[3] are stacked over the region where the SMC 10 and the LPC 30 are formed, and the circuit NMC[4] to the circuit NMC[7] are stacked over the region where the circuit NMC[0] to the circuit NMC[3] are formed.

Stacking of the memory cell array 110B over the memory cell array 110A achieves a high capacity and a small size of the memory cell array 110. For example, in the case where the memory cell 130 has the device structure of FIG. 8, the area of the memory cell array 110 per bit equals to the area of one circuit NMC. That is, the area per bit equals to the area of a region where two transistors and two capacitors are provided. Furthermore, in the case where the memory cell 130 has the device structure of FIG. 9, the area of the memory cell array 110 per bit equals to ½ of that of the example in FIG. 8. By stacking and providing the NVM 20 over the SMC 10 in such a manner, the area of the memory cell 130 per bit is small as compared with that of a CMOS type SRAM memory cell.

The memory cell array 110B including the NVMs 20 is highly compatible with a CMOS circuit as compared with other nonvolatile memories such as a flash memory, an MRAM (magnetoresistive random access memory), and a PRAM (phase-change random access memory). A flash memory requires a high voltage for driving. An MRAM and a PRAM are each a current-drive memory, and therefore, an element or a circuit for current drive are required. In contrast, the NVM 20 is operated by controlling the on/off of the transistor Tr1 and the transistor Tr2. That is, the NVM 20 is a circuit including voltage-drive transistors like a CMOS circuit and can be driven at a low voltage. Therefore, a processor and the memory device 100 can be easily incorporated in one chip. Furthermore, the area of the memory device 100 per bit can be reduced without performance degradation. Still furthermore, power consumption of the memory device 100 can be reduced. Moreover, the memory device 100 can store data even in a power-off state, and thus, the power gating of the memory device 100 can be performed.

An SRAM is operated at high speed and therefore used in an on-chip cache memory of a standard processor. An SRAM has the following drawbacks: power is consumed even in a standby state, and it is difficult to increase the capacity. For example, it is said that, in a processor for a mobile device, power consumption of an on-chip cache memory in a standby state accounts for 80% of the average power consumption of the whole processor. In contrast, the memory device 100 is a RAM that has advantages of an SRAM, which are high-speed reading and writing, and does not have the drawbacks of an SRAM. Thus, the use of the memory device 100 in an on-chip cache memory is advantageous in reducing the power consumption of the whole processor. The area of the memory device 100 per bit is small and the capacity can be increased easily; therefore, the memory device 100 is suitable for, for example, a cache memory of Level 2, Level 3, or the like.

### <Folded Architecture>

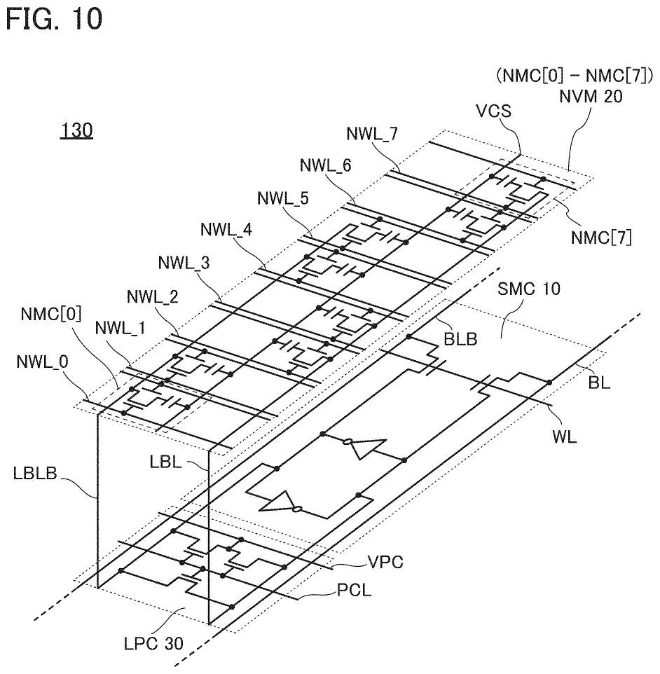

Examples of other layouts of a memory cell include a folded architecture and an open architecture. FIG. 10 illustrates an example in which a folded architecture is applied to the memory cell 130. In the memory cell 130 with the twin cell architecture illustrated in FIG. 8, the circuit NMC includes two transistors and two capacitors; whereas in the memory cell 130 with the folded architecture in FIG. 10, the circuit NMC includes one transistor and one capacitor. In the memory cell 130 with the folded architecture, the circuits NMC are classified as ones connected to the wiring LBL and ones connected to the wiring LBLB. With the use of the folded architecture for the memory cell 130, noise that is output to the wiring LBL or the wiring LBLB by a change in the potential of the wiring NWL can be reduced.

### <Open Architecture>

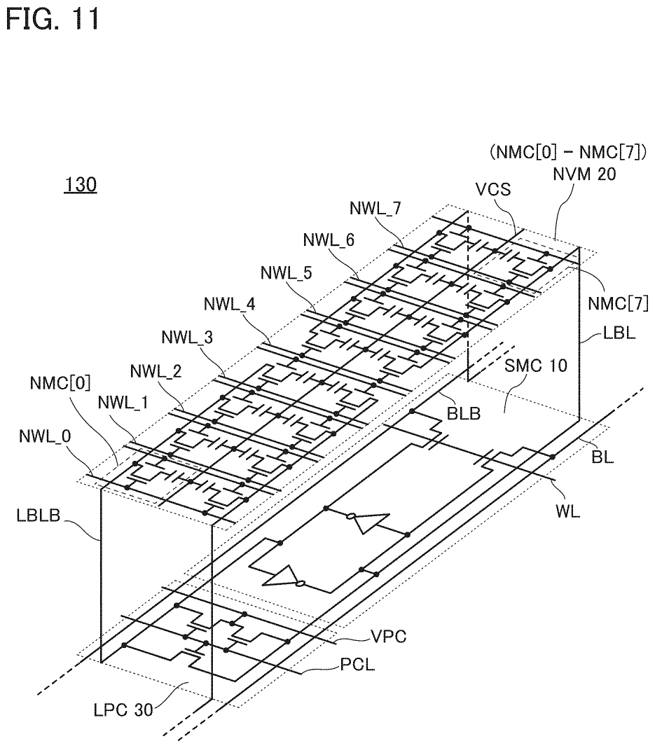

FIG. 11 illustrates an example in which an open architecture is applied to the memory cell 130. In the memory cell 130 with the open architecture illustrated in FIG. 11, the circuit NMC includes one transistor and one capacitor. In FIG. 11, two circuits NMC appear to be connected to one wiring NWL, but one of the two circuits NMC is connected to an adjacent memory cell 130. In the memory cell 130 with the open architecture, the circuits NMC are classified as ones connected to the wiring LBL and ones connected to the wiring LBLB. With the open architecture, the circuits NMC can be highly integrated, and the capacity of data that the memory device 100 can store be increased as compared with the twin cell architecture or the folded architecture.

In the memory cell 130 with the twin cell architecture, complementary data retained in two capacitors is regarded as one bit, whereas in the memory cell 130 with the folded architecture or the open architecture described above, data retained in one capacitor is regarded as one bit. For the other operations of the folded architecture and the open architecture, description of operations of the twin cell architecture can be referred to.

Also in the folded architecture and the open architecture, as in the twin cell architecture, in a standby state, it is preferable that GND be supplied to the wiring VLL and a precharge voltage be supplied to the wiring VHH (alternatively, the precharge voltage be supplied to the wiring VLL and VDD be supplied to the wiring VHH). Thus, the memory device 100 can reduce the static power.

### <<Voltage Retention Circuit and Voltage Generation Circuit>>

Next, a voltage retention circuit 128 and the voltage generation circuit 127 are described with reference to FIG. 12 and FIG. 13.

FIG. 12 illustrates the NVM 20, the voltage retention circuit 128 connected to the NVM 20, and the voltage generation circuit 127 connected to the voltage retention circuit 128.

The voltage retention circuit 128 includes a transistor OS1 and a capacitor C0. A first terminal of the transistor OS1 is electrically connected to a first gate of the transistor OS1, a second gate of the transistor OS1, a first terminal of the capacitor C0, and the wiring BGL. A second terminal of the transistor OS1 is electrically connected to the voltage generation circuit 127 and supplied with a voltage V_{BG}. Note that in the following description, the transistor OS1 is described as an n-channel transistor.

The voltage retention circuit 128 has a function of writing a potential to the second gates of the transistor Tr1 and the transistor Tr2 and retaining the potential. For example, in the case where the voltage retention circuit 128 writes a negative potential to the second gates of the transistor Tr1 and the transistor Tr2, the transistor Tr1 and the transistor Tr2 can keep Vₜₕ high while the negative potentials of the second gates of the transistor Tr1 and the transistor Tr2 are retained. Keeping Vₜₕ high can prevent the transistor Tr1 and the transistor Tr2 from being normally-on, and power consumption of the memory device 100 can be reduced.

In the transistor OS1, the first gate and the second gate preferably have a region where they overlap with each other with a semiconductor layer provided therebetween. Furthermore, the above-described OS transistor is preferably used as the transistor OS1. When the OS transistor is used as the transistor OS1, drain current at V_{GS}=0 V (hereinafter referred to as cutoff current) can be made sufficiently low, and the voltage retention circuit 128 can retain the negative potential applied to the wiring BGL for a long time.

The channel length of the transistor OS1 is preferably longer than that of each of the transistor Tr1 and the transistor Tr2. In the case where the channel length of each of the transistor Tr1 and the transistor Tr2 is shorter than 1 μm, for example, the channel length of the transistor OS1 is longer than or equal to 1 μm, further preferably longer than or equal to 3 μm, further preferably longer than or equal to 5 μm, and further preferably longer than or equal to 10 μm.

When the transistor OS1 has a longer channel length, the transistor OS1 is not affected by a short-channel effect, and the cutoff current can be low. Furthermore, the withstand voltage between a source and a drain of the transistor OS1 can be increased. The high withstand voltage between the source and the drain of the transistor OS1 is preferable because it can facilitate a connection between the transistor OS1 and the voltage generation circuit 127 generating a high voltage.

The transistor OS1 is used in a circuit that needs high integration, such as a memory cell; thus, the channel lengths of the transistor Tr1 and the transistor Tr2 are preferably short. Meanwhile, the voltage retention circuit 128 is formed outside the memory cell; thus, a long channel length of the transistor OS1 does not become a problem. In addition, although the on-state current of a transistor is reduced when the channel length of the transistor is increased, the transistor OS1 is mainly used in an off state and thus is not required to have high on-state current.

The voltage generation circuit 127 has a function of generating a negative potential (V_{BG}). Circuit diagrams in FIG. 13 illustrate examples of the voltage generation circuit 127. These circuits are step-down charge pump, in each of which GND is input to an input terminal IN, and V_{BG} is output from an output terminal OUT. Here, as an example, the number of stages of fundamental circuits in the charge pump circuit is four; however, it is not limited thereto, and the charge pump circuit may be configured with a given number of stages.

A voltage generation circuit 127a illustrated in FIG. 13A includes a transistor M21 to a transistor M24 and a capacitor C21 to a capacitor C24. The transistor M21 to the transistor M24 are hereinafter described as n-channel transistors.

The transistor M21 to the transistor M24 are connected in series between the input terminal IN and the output terminal OUT, and a gate and a first terminal of each transistor are connected so that the transistor functions as a diode. The capacitor C21 to the capacitor C24 are respectively connected to the gates of the transistor M21 to the transistor M24.

The signal CLK is input to first electrodes of the capacitor C21 and the capacitor C23 in the odd-numbered stages, and a signal CLKB is input to first electrodes of the capacitor C22 and the capacitor C24 in the even-numbered stages. The signal CLKB is an inverted clock signal obtained by phase inversion of the signal CLK.

The voltage generation circuit 127a has a function of stepping down GND input to the input terminal IN and generating V_{BG}. The voltage generation circuit 127a can generate a negative potential only by the supply of the signal CLK and the signal CLKB.

The above-described transistor M21 to transistor M24 may be OS transistors. The use of OS transistors is preferable because the reverse current of the diode-connected transistor M21 to transistor M24 can be reduced.

A voltage generation circuit 127b illustrated in FIG. 13B includes a transistor M31 to a transistor M34 that are p-channel transistors. The description of the voltage generation circuit 127a is referred to for the other components.

As described above, the memory device 100 of one embodiment of the present invention can reduce the power consumption and circuit area by employing the above structures.

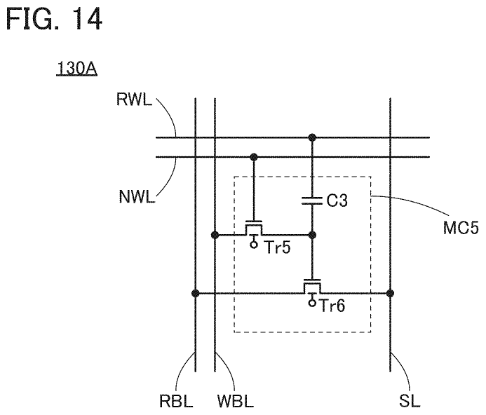

Note that one embodiment of the present invention is not limited to the memory device 100 having the above-described structure. For example, a memory cell 130A illustrated in FIG. 14 may be used as the memory cell 130 of the memory device 100 in FIG. 3. The memory cell 130A is an example of a RAM called a NOSRAM (Nonvolatile Oxiside Semiconductor Random Access Memory) (registered trademark), a gain-cell-type memory cell.

The memory cell 130A is electrically connected to the wiring NWL, a wiring RWL, a wiring WBL, a wiring RBL, and a wiring SL. Since the memory cell 130A has a different circuit structure from the memory cell 130, the wiring illustrated in FIG. 3 and the wiring illustrated in FIG. 14 may have different functions.

The memory cell 130A includes a circuit MC5. The circuit MC5 includes a transistor Tr5, a transistor Tr6, and a capacitor C3. A first terminal of the transistor Tr5 is electrically connected to a gate of the transistor Tr6 and a first terminal of the capacitor C3. A second terminal of the transistor Tr5 is electrically connected to the wiring WBL, and a gate of the transistor Tr5 is electrically connected to the wiring NWL. A first terminal of the transistor Tr6 is electrically connected to the wiring SL, and a second terminal of the transistor Tr6 is electrically connected to the wiring RBL. A second terminal of the capacitor C3 is electrically connected to the wiring RWL.

The wiring NWL has a function of a write word line. Switching between the on state and the off state of the transistor Tr5 can be performed when a high level potential or a low level potential is supplied to the wiring NWL. The wiring NWL can be electrically connected to the row driver 123, for example. At this time, this row driver 123 is preferably a row driver for writing.

The wiring RWL has a function of a read word line. In addition, the wiring RWL can be electrically connected to the row driver 123, for example. At this time, this row driver 123 is preferably a row driver for reading.

The wiring WBL has a function of a write bit line. In addition, the wiring WBL can be electrically connected to the column driver 124, for example. At this time, this column driver 124 is preferably a column driver for writing.

The wiring RBL has a function of a read bit line. In addition, the wiring RBL can be electrically connected to the column driver 124, for example. At this time, this column driver 124 is preferably a column driver for reading.

The wiring SL functions as a wiring having a function of supplying voltage.

Next, an example of writing operation is described. When data is written to the circuit MC5, first, a high-level potential is input to the wiring NWL to turn on the transistor Tr5. Furthermore, a high-level potential is input to the wiring RWL to make the potential of the second terminal of the capacitor C3 a high-level potential. Next, a potential corresponding to the data written to the circuit MC5 is written from the wiring WBL to the first terminal of the capacitor C3 through the first terminal and the second terminal of the transistor Tr5. After that, a low-level potential is input to the wiring NWL to turn off the transistor Tr5. Then, a low-level potential is input to the wiring RWL to make the potential of the second terminal of the capacitor C3 a low-level potential. At this time, since the first terminal of the capacitor C3 is in a floating state, the potential of the second terminal of the capacitor C3 decreases, whereby the potential of the first terminal of the capacitor C3 also decreases.

Next, an example of reading operation is described. When data is read to the circuit MC5, first, a constant potential is supplied to the wiring SL. The constant potential can be, for example, a low-level potential or a ground potential. In particular, the constant potential of the wiring SL is preferably determined so that the gate-source voltage of the transistor Tr6 can be lower than or equal to the threshold voltage. Next, the wiring RBL is precharged to a high-level potential. Then, the potential of the wiring RWL is changed from a low-level potential to a high-level potential, whereby the potential of the first terminal of the capacitor C3 increases, and thus the potential of the gate of the transistor Tr6 also increases. At this time, when the gate-source voltage of the transistor Tr6 becomes higher than the threshold voltage, the transistor Tr6 is turned on. Since the transistor Tr6 is on, conduction continuity is established between the wiring RBL and the wiring SL. Here, since the wiring RBL is precharged to the high-level potential, the potential of the wiring RBL decreases until the transistor Tr6 is turned off. The potential of the wiring RBL is finally determined in accordance with the potential of the capacitor C3; therefore, the potential of the wiring RBL is read at this time, whereby the data written to the circuit MC5 can be read.

As described above, the memory cell 130A illustrated in FIG. 14 can be used as the memory cell 130 of the memory device 100 in FIG. 3. Since no inverter is provided in the SMC 10 of the memory cell 130A unlike in the memory cell 130, the power consumption and the circuit area of the memory cell 130A can be reduced as compared to those of the memory cell 130 in some cases.

Note that this embodiment can be combined with any of the other embodiments in this specification as appropriate.

### Embodiment 3

In this embodiment, structure examples of the memory device described in the above embodiment and structure examples of a transistor that can be used in the memory device are described.

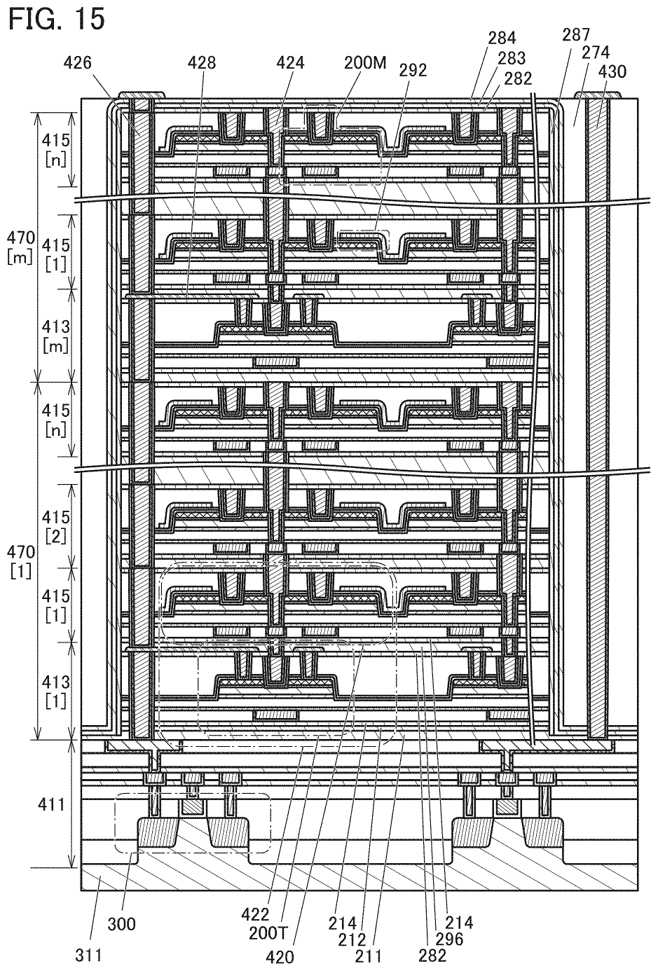

FIG. 15 is a diagram illustrating an example of a semiconductor device in which memory units 470 (a memory unit 470[1] to a memory unit 470[m] (m is a natural number greater than or equal to 2)) are stacked over an element layer 411 including a circuit provided on a semiconductor substrate 311. FIG. 15 illustrates an example where the element layer 411 and a plurality of memory units 470 over the element layer 411 are stacked; the plurality of memory units 470 are each provided with a corresponding transistor layer 413 (a transistor layer 413[1] to a transistor layer 413[m]) and a plurality of memory device layers 415 (a memory device layer 415[1] to a memory device layer 415 [n] (n is a natural number greater than or equal to 2)) over each transistor layer 413. Although the example where the memory device layers 415 are provided over the transistor layer 413 in each of the memory units 470 is illustrated, this embodiment is not limited thereto. The transistor layer 413 may be provided over the plurality of memory device layers 415, or the memory device layers 415 may be provided over and below the transistor layer 413.

The element layer 411 includes a transistor 300 provided on the semiconductor substrate 311 and can function as a circuit (referred to as a peripheral circuit in some cases) of the semiconductor device. The circuit can be, for example, the NVM 20, the LPC 30, or the like that can be used for the memory device 100 in FIG. 3 described in the above embodiment. Other examples include the row decoder 121, the column decoder 122, the row driver 123, the column driver 124, the input circuit 125, and the output circuit 126.

The transistor layer 413 includes a transistor 200T and can function as a circuit for controlling each memory unit 470. The memory device layer 415 includes a memory device 420. The memory device 420 shown in this embodiment includes a transistor 200M and a capacitor 292. In particular, the memory device 420 can be, for example, one of the circuit NMC[0] to the circuit NMC[n−1] in FIG. 4, which can be used for the memory device 100 in FIG. 3 described in the above embodiment. When the circuits MC1 and the circuits MC2 that are included in the circuit NMC[0] to the circuit NMC[n−1] have the structures illustrated in FIG. 4, the transistor 200M illustrated in FIG. 15 can be the transistor Tr1 in FIG. 4 and the capacitor 292 illustrated in FIG. 15 can be the capacitor C1 in FIG. 4.

Although not particularly limited, m is greater than or equal to 2 and less than or equal to 100, preferably greater than or equal to 2 and less than or equal to 50, further preferably greater than or equal to 2 and less than or equal to 10. Although not particularly limited, n is greater than or equal to 2 and less than or equal to 100, preferably greater than or equal to 2 and less than or equal to 50, further preferably greater than or equal to 2 and less than or equal to 10. In addition, the product of m and n is greater than or equal to 4 and less than or equal to 256, preferably greater than or equal to 4 and less than or equal to 128, further preferably greater than or equal to 4 and less than or equal to 64.

FIG. 15 illustrates a cross-sectional view of the transistors 200T and the transistors 200M in the channel length direction, which are included in the memory units.

As illustrated in FIG. 15, the transistor 300 is provided on the semiconductor substrate 311, and the transistor layers 413 and the memory device layers 415 included in the memory units 470 are provided over the transistor 300. In one memory unit 470, the transistor 200T included in the transistor layer 413 and the memory devices 420 included in the memory device layers 415 are electrically connected to each other through a plurality of conductors 424, and the transistor 300 and the transistor 200T included in the transistor layer 413 in each memory unit 470 are electrically connected to each other through a conductor 426. In addition, the conductor 426 is preferably electrically connected to the transistor 200T through a conductor 428 which is electrically connected to any one of a source, a drain, and a gate of the transistor 200T. The conductors 424 are preferably provided in each of the memory device layers 415. Furthermore, the conductor 426 is preferably provided in each of the transistor layers 413 and the memory device layers 415.

Although the details are described later, an insulator that inhibits passage of impurities such as water or hydrogen or oxygen is preferably provided on a side surface of the conductor 424 and a side surface of the conductor 426. For the insulator, for example, silicon nitride, aluminum oxide, or silicon nitride oxide may be used.

The transistor 200M included in the memory device 420 can have a structure similar to that of the transistor 200T included in the transistor layer 413. The transistor 200T and the transistor 200M are collectively referred to as a transistor 200.

The transistor 200 preferably uses a metal oxide functioning as an oxide semiconductor (hereinafter also referred to as an oxide semiconductor) in a semiconductor including a region where a channel is formed (hereinafter also referred to as a channel formation region).

As an oxide semiconductor, a metal oxide such as an In-M-Zn oxide (an element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like) is preferably used. As the oxide semiconductor, indium oxide, an In-M oxide, an In—Zn oxide, or an M-Zn oxide may be used. Note that when an oxide semiconductor having a high proportion of indium is used, the on-state current, the field-effect mobility, or the like of the transistor can be increased.

The transistor 200 using an oxide semiconductor in the channel formation region has an extremely low leakage current in a non-conduction state; hence, a semiconductor device with low power consumption can be provided. An oxide semiconductor can be deposited by a sputtering method or the like, and thus can be used in the transistor 200 included in a highly integrated semiconductor device.

In contrast, a transistor using an oxide semiconductor is likely to have normally-on characteristics (the characteristics are that a channel exists without voltage application to a gate electrode and a current flows through the transistor) owing to an impurity and an oxygen vacancy in the oxide semiconductor that change the electrical characteristics.

In view of this, an oxide semiconductor with a reduced impurity concentration and a reduced density of defect states is preferably used. Note that in this specification and the like, a state with a low impurity concentration and a low density of defect states is referred to as a highly purified intrinsic or substantially highly purified intrinsic state.

Therefore, the concentration of impurities in the oxide semiconductor is preferably reduced as much as possible. Examples of the impurities in the oxide semiconductor include hydrogen, nitrogen, an alkali metal, an alkaline earth metal, iron, nickel, and silicon.

In particular, hydrogen as an impurity contained in the oxide semiconductor might form an oxygen vacancy (also referred to as Vo) in the oxide semiconductor. In some cases, a defect that is an oxygen vacancy into which hydrogen enters (hereinafter referred to as VoH in some cases) generates an electron serving as a carrier. In other cases, reaction of part of hydrogen with oxygen bonded to a metal atom generates an electron serving as a carrier.

Thus, a transistor using an oxide semiconductor which contains a large amount of hydrogen is likely to have normally-on characteristics. Moreover, hydrogen in an oxide semiconductor is easily transferred by a stress such as heat or an electric field; thus, a large amount of hydrogen contained in an oxide semiconductor might decrease the reliability of the transistor.

Therefore, it is preferable to use a highly purified intrinsic oxide semiconductor in which oxygen vacancies and impurities such as hydrogen are reduced as the oxide semiconductor used in the transistor 200.

### <Sealing Structure>

In view of the above, the transistor 200 is preferably sealed using a material that inhibits diffusion of impurities (hereinafter also referred to as a barrier material against impurities) in order to inhibit entry of impurities from the outside.

A barrier property in this specification means a function of inhibiting diffusion of a particular substance (also referred to as low transmission capability). Alternatively, a barrier property in this specification means a function of capturing and fixing (also referred to as gettering) a particular substance.

Examples of a material that has a function of inhibiting diffusion of hydrogen and oxygen include aluminum oxide, hafnium oxide, gallium oxide, indium gallium zinc oxide, silicon nitride, and silicon nitride oxide. It is particularly preferable to use silicon nitride or silicon nitride oxide as a sealing material because of their high barrier properties against hydrogen.

Examples of a material that has a function of capturing and fixing hydrogen include metal oxides such as aluminum oxide, hafnium oxide, gallium oxide, and indium gallium zinc oxide.

As barrier layers between the transistor 300 and the transistor 200, an insulator 211, an insulator 212, and an insulator 214 are preferably provided. When a material that inhibits diffusion or passage of impurities such as hydrogen is used in at least one of the insulator 211, the insulator 212, and the insulator 214, diffusion of impurities such as hydrogen or water contained in the semiconductor substrate 311, the transistor 300, or the like into the transistor 200 can be inhibited. When a material that inhibits passage of oxygen is used in at least one of the insulator 211, the insulator 212, and the insulator 214, diffusion of oxygen contained in the channel formation region of the transistor 200 or the transistor layer 413 into the element layer 411 can be inhibited. For example, it is preferable to use a material that inhibits passage of impurities such as hydrogen or water as the insulator 211 and the insulator 212 and use a material that inhibits passage of oxygen as the insulator 214. It is further preferable to use a material having a property of absorbing or occluding hydrogen as the insulator 214. As the insulator 211 and the insulator 212, a nitride such as silicon nitride or silicon nitride oxide can be used, for example. As the insulator 214, a metal oxide such as aluminum oxide, hafnium oxide, gallium oxide, or indium gallium zinc oxide can be used, for example. In particular, aluminum oxide is preferably used as the insulator 214.

Furthermore, an insulator 287 is preferably provided on side surfaces of the transistor layers 413 and side surfaces of the memory device layers 415, that is, side surfaces of the memory units 470, and an insulator 282 is preferably provided on a top surface of the memory unit 470. In this case, the insulator 282 is preferably in contact with the insulator 287, and the insulator 287 is preferably in contact with at least one of the insulator 211, the insulator 212, and the insulator 214. As the insulator 287 and the insulator 282, a material that can be used for the insulator 214 is preferably used.

An insulator 283 and an insulator 284 are preferably provided to cover the insulator 282 and the insulator 287, and the insulator 283 is preferably in contact with at least one of the insulator 211, the insulator 212, and the insulator 214. Although FIG. 15 illustrates an example where the insulator 287 is in contact with a side surface of the insulator 214, a side surface of the insulator 212, and a top surface and a side surface of the insulator 211, and the insulator 283 is in contact with a side surface and a top surface of the insulator 287 and the top surface of the insulator 211, this embodiment is not limited thereto. The insulator 287 may be in contact with the side surface of the insulator 214 and a top surface and the side surface of the insulator 212, and the insulator 283 may be in contact with the side surface and the top surface of the insulator 287 and the top surface of the insulator 212. For the insulator 282 and the insulator 287, a material that can be used for the insulator 211 and the insulator 212 is preferably used.

In the above-described structure, a material that inhibits passage of oxygen is preferably used for the insulator 287 and the insulator 282. A material having a property of capturing and fixing hydrogen is further preferably used for the insulator 287 and the insulator 282. When the material having a property of capturing and fixing hydrogen is used on the side close to the transistor 200, hydrogen in the transistor 200 or the memory units 470 is captured and fixed by the insulator 214, the insulator 287, and the insulator 282, so that the hydrogen concentration in the transistor 200 can be reduced. Furthermore, a material that inhibits passage of impurities such as hydrogen or water (a material having a barrier property against impurities such as hydrogen or water) is preferably used for the insulator 283 and the insulator 284.

By employing the above-described structure, the memory units 470 are surrounded by the insulator 211, the insulator 212, the insulator 214, the insulator 287, the insulator 282, the insulator 283, and the insulator 284. Specifically, the memory units 470 are surrounded by the insulator 214, the insulator 287, and the insulator 282 (referred to as a first structure body in some cases); and the memory units 470 and the first structure body are surrounded by the insulator 211, the insulator 212, the insulator 283, and the insulator 284 (referred to as a second structure body in some cases). The structure in which the memory units 470 are surrounded by two or more layers of structure bodies in that manner is referred to as a nesting structure in some cases. Here, the memory units 470 being surrounded by the plurality of structure bodies is also described as the memory units 470 being sealed by the plurality of insulators.

The second structure body seals the transistor 200 with the first structure body therebetween. Thus, the second structure body inhibits hydrogen present outside the second structure body, from diffusing to a portion inside the second structure body (to the transistor 200 side). That is, the first structure body can efficiently capture and fix hydrogen present in an inside structure of the second structure body.

In the above structure, specifically, a metal oxide such as aluminum oxide can be used for the first structure body and a nitride such as silicon nitride can be used for the second structure body. More specifically, an aluminum oxide film is preferably placed between the transistor 200 and a silicon nitride film.

Furthermore, by appropriately setting deposition conditions for the materials used for the structure bodies, the hydrogen concentrations in the film can be reduced.

In general, a film formed by a CVD method has more favorable coverage than a film formed by a sputtering method. On the other hand, many compound gases used for a CVD method contain hydrogen and a film formed by a CVD method has higher hydrogen content than a film formed by a sputtering method.

Accordingly, it is preferable to use a film with a reduced hydrogen concentration (specifically, a film formed by a sputtering method) as a film which is close to the transistor 200, for example. Meanwhile, in the case where a film that has favorable coverage as well as a relatively high hydrogen concentration (specifically, a film formed by a CVD method) is used as a film that inhibits impurity diffusion, it is preferable that a film having a function of capturing and fixing hydrogen and a reduced hydrogen concentration be placed between the transistor 200 and the film that has a relatively high hydrogen concentration as well as favorable coverage.

In other words, a film with a relatively low hydrogen concentration is preferably used as the film which is placed close to the transistor 200. In contrast, a film with a relatively high hydrogen concentration is preferably placed apart from the transistor 200.

Specifically, when the transistor 200 is sealed with a silicon nitride film formed by a CVD method in the above-described structure, an aluminum oxide film formed by a sputtering method is preferably placed between the transistor 200 and the silicon nitride film formed by a CVD method. It is further preferable that a silicon nitride film formed by a sputtering method be placed between the silicon nitride film formed by a CVD method and the aluminum oxide film formed by a sputtering method.

Note that in the case where a CVD method is employed for film formation, a compound gas containing no hydrogen atom or having a low hydrogen atom content may be used for the film formation to reduce the concentration of hydrogen contained in the formed film.

It is also preferable to provide the insulator 282 and the insulator 214 between the transistor layer 413 and the memory device layers 415 or between the memory device layers 415. Furthermore, it is preferable to provide an insulator 296 between the insulator 282 and the insulator 214. The insulator 296 can be formed using a material similar to those for the insulator 283 and the insulator 284. Alternatively, silicon oxide or silicon oxynitride can be used. Alternatively, a known insulating material may be used. Here, the insulator 282, the insulator 296, and the insulator 214 may be elements that form the transistor 200. It is preferable that the insulator 282, the insulator 296, and the insulator 214 also serve as components of the transistor 200 in order to reduce the number of steps for manufacturing the semiconductor device.

Each side surface of the insulator 282, the insulator 296, and the insulator 214 provided between the transistor layer 413 and the memory device layers 415 or between the memory device layers 415 is preferably in contact with the insulator 287. With such a structure, the transistor layers 413 and the memory device layers 415 are surrounded by and sealed with the insulator 282, the insulator 296, the insulator 214, the insulator 287, the insulator 283, and the insulator 284.

An insulator 274 may be provided around the insulator 284. A conductor 430 may be provided so as to be embedded in the insulator 274, the insulator 284, the insulator 283, and the insulator 211. The conductor 430 is electrically connected to the transistor 300, that is, the circuit included in the element layer 411.

Furthermore, since the capacitor 292 is formed in the same layer as the transistor 200M in the memory device layers 415, the height of the memory device 420 can be approximately equal to that of the transistor 200M; thus, the height of each memory device layer 415 can be prevented from being excessively increased. Accordingly, the number of memory device layers 415 can be increased relatively easily. For example, approximately 100 units each including the transistor layer 413 and the memory device layers 415 may be stacked.

### <Transistor 200>

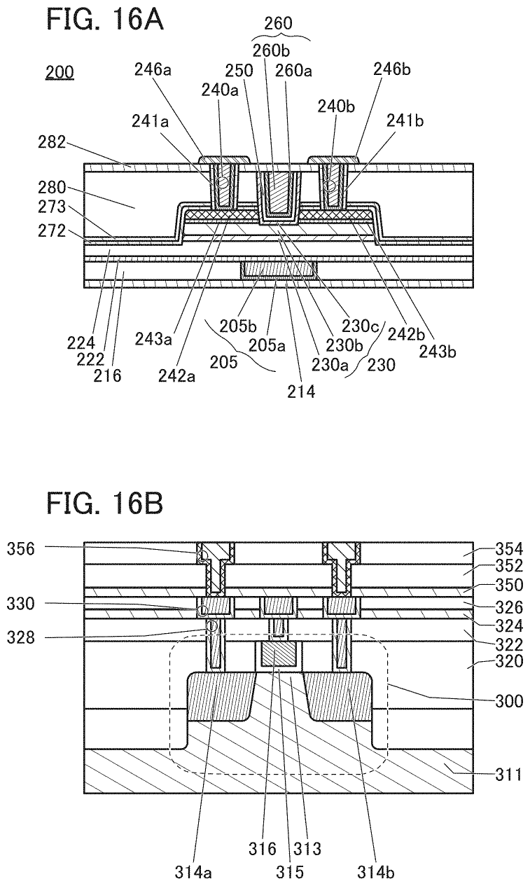

The transistor 200 that can be used as the transistor 200T included in the transistor layer 413 and the transistor 200M included in the memory device 420 is described with reference to FIG. 16A.

As illustrated in FIG. 16A, the transistor 200 includes an insulator 216, a conductor 205 (a conductor 205a and a conductor 205b), an insulator 222, an insulator 224, an oxide 230 (an oxide 230a, an oxide 230b, and an oxide 230c), a conductor 242 (a conductor 242a and a conductor 242b), an oxide 243 (an oxide 243a and an oxide 243b), an insulator 272, an insulator 273, an insulator 250, and a conductor 260 (a conductor 260a and a conductor 260b).

Furthermore, the insulator 216 and the conductor 205 are provided over the insulator 214, and an insulator 280 and the insulator 282 are provided over the insulator 273. The insulator 214, the insulator 280, and the insulator 282 can be regarded as part of the transistor 200.

The insulator 280 preferably includes an excess-oxygen region and preferably releases oxygen by heating. When the heated insulator 280 releases oxygen, the oxygen can be efficiently supplied to the oxide 230a and the oxide 230b through the oxide 230c. For example, the insulator 280 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride are preferable because they are thermally stable. In particular, silicon oxide and porous silicon oxide are preferable because an excess-oxygen region can be easily formed in a step after formation of the insulator 280 in some cases. The concentration of impurities such as water or hydrogen in the insulator 280 is preferably reduced.

The semiconductor device of one embodiment of the present invention also includes a conductor 240 (a conductor 240a and a conductor 240b) that is electrically connected to the transistor 200 and functions as a plug. Note that an insulator 241 (an insulator 241a and an insulator 241b) may be provided in contact with a side surface of the conductor 240 functioning as a plug. A conductor 246 (a conductor 246a and a conductor 246b) that is electrically connected to the conductor 240 and functions as a wiring is provided over the insulator 282 and the conductor 240.

For the conductor 240a and the conductor 240b, a conductive material containing tungsten, copper, or aluminum as its main component is preferably used, for example. The conductor 240a and the conductor 240b may each have a stacked-layer structure.

In the case where the conductor 240 has a stacked-layer structure, a conductive material having a function of inhibiting passage of oxygen and impurities such as water or hydrogen is preferably used for the conductor 240. For example, tantalum, tantalum nitride, titanium, titanium nitride, ruthenium, ruthenium oxide, or the like is preferably used. A single layer or a stacked layer of the conductive material having a function of inhibiting passage of oxygen and impurities such as water or hydrogen may be used. With the use of the conductive material, entry of impurities diffused from the insulator 280 and the like, such as water or hydrogen, into the oxide 230 through the conductor 240a and the conductor 240b can be further reduced. In addition, oxygen added to the insulator 280 can be prevented from being absorbed by the conductor 240a and the conductor 240b.

For the insulator 241 provided in contact with the side surface of the conductor 240, for example, silicon nitride, aluminum oxide, silicon nitride oxide, or the like can be used. Since the insulator 241 is provided in contact with the insulator 272, the insulator 273, the insulator 280, and the insulator 282, impurities such as water or hydrogen can be inhibited from being mixed into the oxide 230 through the conductor 240a and the conductor 240b from the insulator 280 or the like. In particular, silicon nitride is suitable because of its high barrier property against hydrogen. In addition, oxygen contained in the insulator 280 can be prevented from being absorbed by the conductor 240a and the conductor 240b.

As the conductor 246, a conductive material containing tungsten, copper, or aluminum as its main component is preferably used. Furthermore, the conductor may have a stacked-layer structure and may be a stack of titanium or titanium nitride and the above-described conductive material, for example. Note that the conductor may be formed to be embedded in an opening provided in an insulator.

In the transistor 200, the conductor 260 functions as a first gate of the transistor, and the conductor 205 functions as a second gate of the transistor. The conductor 242a and the conductor 242b function as a source electrode and a drain electrode.

The oxide 230 functions as a semiconductor including a channel formation region.

The insulator 250 functions as a first gate insulator, and the insulator 222 and the insulator 224 function as a second gate insulator.

Here, in the transistor 200 illustrated in FIG. 16A, the conductor 260 is formed in a self-aligned manner in an opening portion provided in the insulator 280, the insulator 273, the insulator 272, the conductor 242, and the like, with the oxide 230c and the insulator 250 therebetween.

In other words, the conductor 260 is formed to fill the opening provided in the insulator 280 and the like with the oxide 230c and the insulator 250 therebetween; therefore, positional alignment of the conductor 260 in the region between the conductor 242a and the conductor 242b is not needed.

Here, the oxide 230c is preferably provided in the opening that is provided in the insulator 280 and the like. Thus, the insulator 250 and the conductor 260 include a region that overlaps with a stacked-layer structure of the oxide 230b and the oxide 230a with the oxide 230c therebetween. With this structure, the oxide 230c and the insulator 250 can be sequentially formed and thus, the interface between the oxide 230 and the insulator 250 can be kept clean. Thus, the influence of interface scattering on carrier conduction is small, and the transistor 200 can have a high on-state current and excellent frequency characteristics.

In the transistor 200 illustrated in FIG. 16A, a bottom surface and a side surface of the conductor 260 are in contact with the insulator 250. In addition, a bottom surface and a side surface of the insulator 250 are in contact with the oxide 230c.

As illustrated in FIG. 16A, the transistor 200 has a structure in which the insulator 282 and the oxide 230c are in direct contact with each other. Owing to this structure, diffusion of oxygen contained in the insulator 280 into the conductor 260 can be inhibited.

Therefore, oxygen contained in the insulator 280 can be supplied to the oxide 230a and the oxide 230b efficiently through the oxide 230c; hence, oxygen vacancies in the oxide 230a and the oxide 230b can be reduced and the electrical characteristics and the reliability of the transistor 200 can be improved.

The detailed structure of the semiconductor device including the transistor 200 of one embodiment of the present invention is described below.

In the transistor 200, as the oxide 230 (the oxide 230a, the oxide 230b, and the oxide 230c) that includes the channel formation region, a metal oxide functioning as an oxide semiconductor (hereinafter also referred to as an oxide semiconductor) is preferably used.

For example, a metal oxide having an energy gap of 2 eV or more, preferably 2.5 eV or more is preferably used as the metal oxide functioning as an oxide semiconductor. With the use of a metal oxide having such a wide energy gap, the leakage current in an off state (off-state current) of the transistor 200 can be extremely low. With the use of such a transistor, a semiconductor device with low power consumption can be provided.

Specifically, as in the description of the transistor 200 in FIG. 15, a metal oxide such as an In-M-Zn oxide is preferably used as the oxide 230. In particular, aluminum, gallium, yttrium, or tin is preferably used as the element M. Furthermore, as in the description of the transistor 200 in FIG. 15, an In-M oxide, an In—Zn oxide, or an M-Zn oxide may be used as the oxide 230.

As illustrated in FIG. 16A, the oxide 230 preferably includes the oxide 230a over the insulator 224, the oxide 230b over the oxide 230a, and the oxide 230c that is placed over the oxide 230b and is at least partly in contact with a top surface of the oxide 230b. Here, a side surface of the oxide 230c is preferably provided in contact with the oxide 243a, the oxide 243b, the conductor 242a, the conductor 242b, the insulator 272, the insulator 273, and the insulator 280.

That is, the oxide 230 includes the oxide 230a, the oxide 230b over the oxide 230a, and the oxide 230c over the oxide 230b. Including the oxide 230a below the oxide 230b makes it possible to inhibit diffusion of impurities into the oxide 230b from the components formed below the oxide 230a. Moreover, including the oxide 230c over the oxide 230b makes it possible to inhibit diffusion of impurities into the oxide 230b from the components formed above the oxide 230c.

Note that the transistor 200 has a structure in which three layers of the oxide 230a, the oxide 230b, and the oxide 230c are stacked in the channel formation region and the vicinity thereof; however, the present invention is not limited thereto. For example, a single layer of the oxide 230b, a two-layer structure of the oxide 230b and the oxide 230a, a two-layer structure of the oxide 230b and the oxide 230c, or a stacked-layer structure of four or more layers may be provided. For example, a four-layer structure including the oxide 230c with a two-layer structure may be provided.

In addition, the oxide 230 preferably has a stacked-layer structure of a plurality of oxide layers that differ in the atomic ratio of metal atoms. Specifically, the atomic proportion of the element M in the constituent elements in the metal oxide used as the oxide 230a is preferably greater than the atomic proportion of the element M in the constituent elements in the metal oxide used as the oxide 230b. Moreover, the atomic ratio of the element M to In in the metal oxide used as the oxide 230a is preferably greater than the atomic ratio of the element M to In in the metal oxide used as the oxide 230b. Furthermore, the atomic ratio of In to the element M in the metal oxide used as the oxide 230b is preferably greater than the atomic ratio of In to the element Min the metal oxide used as the oxide 230a. A metal oxide that can be used as the oxide 230a or the oxide 230b can be used as the oxide 230c.

Here, the composition of the metal oxide that can be used as the oxide 230 is described assuming that the element M is Ga. Specifically, as the oxide 230a, a metal oxide having a composition of In:Ga:Zn=1:3:4 [atomic ratio] or the vicinity thereof or a composition of 1:1:0.5 [atomic ratio] or the vicinity thereof is preferably used.

As the oxide 230b, a metal oxide having a composition of In:Ga:Zn=4:2:3 [atomic ratio] or the neighborhood thereof or a composition of 1:1:1 [atomic ratio] or the neighborhood thereof is used. As the oxide 230b, a metal oxide having a composition of In:Ga:Zn=5:1:3 [atomic ratio] or the neighborhood thereof or a composition of In:Ga:Zn=10:1:3 [atomic ratio] or the neighborhood thereof may be used as well. As the oxide 230b, an In—Zn oxide (e.g., a composition of In:Zn=2:1 [atomic ratio] or the neighborhood thereof, a composition of In:Zn=5:1 [atomic ratio] or the neighborhood thereof, or a composition of In:Zn=10:1 [atomic ratio] or the neighborhood thereof) may be used as well. An In oxide may be used as the oxide 230b.

Furthermore, as the oxide 230c, a metal oxide having In:Ga:Zn=1:3:4 [atomic ratio or the composition in the neighborhood thereof], a composition of Ga:Zn=2:1 [atomic ratio] or the neighborhood thereof, or a composition of Ga:Zn=2:5 [atomic ratio] or the neighborhood thereof is preferably used. As the oxide 230c, a single layer or a stacked layer may be provided using a material that can be used for the oxide 230b. For example, in the case where the oxide 230c has a stacked-layer structure, the oxide 230c can specifically have a stacked-layer structure of a composition of In:Ga:Zn=4:2:3 [atomic ratio] or the neighborhood thereof and a composition of In:Ga:Zn=1:3:4 [atomic ratio] or the neighborhood thereof, a stacked-layer structure of a composition of Ga:Zn=2:1 [atomic ratio] or the neighborhood thereof and a composition of In:Ga:Zn=4:2:3 [atomic ratio] or the neighborhood thereof, a stacked-layer structure of a composition of Ga:Zn=2:5 [atomic ratio] or the neighborhood thereof and a composition of In:Ga:Zn=4:2:3 [atomic ratio] or the neighborhood thereof, a stacked-layer structure of gallium oxide and a composition of In:Ga:Zn=4:2:3 [atomic ratio] or the neighborhood thereof, or the like.

Note that when, for example, the transistors that are included in the circuit MC1 and the circuit MC2, the transistor Teq1, the transistor Tpc1, and the transistor Tpc2 that are included in the LPC 30, the transistor Tac1 and the transistor Tac2 that are included in the SMC 10, and the like in FIG. 4 described in the above embodiment are each an OS transistor, the OS transistors may have different compositions from each other. For example, a metal oxide having In:Ga:Zn=4:2:3 [atomic ratio] or a composition in the vicinity thereof may be used as the oxides 230c included in the OS transistors in the circuit MC1 and the circuit MC2, and a metal oxide having In:Ga:Zn=5:1:3 [atomic ratio] or a composition in vicinity thereof, In:Ga:Zn=10:1:3 [atomic ratio] or a composition in the vicinity thereof, In:Zn=10:1 [atomic ratio] or a composition in the vicinity thereof, In:Zn=5:1 [atomic ratio] or a composition in the vicinity thereof, or In:Zn=2:1 [atomic ratio] or a composition in the vicinity thereof may be used as the oxides 230c included in the OS transistors in the LPC 30 and the SMC 10.

In the oxide 230b and the oxide 230c, increasing the proportion of indium in the films enables higher on-state current, higher field-effect mobility, or the like of the transistor. Moreover, the above-described composition in the neighborhood includes ±30% of the intended atomic ratio.

The oxide 230b may have crystallinity. For example, a CAAC-OS (c-axis aligned crystalline oxide semiconductor) described later is preferably used. An oxide having crystallinity, such as a CAAC-OS, has a dense structure with small amounts of impurities and defects (e.g., oxygen vacancies) and high crystallinity. This can inhibit oxygen extraction from the oxide 230b by the source electrode or the drain electrode. In addition, the amount of oxygen extracted from the oxide 230b can be reduced even when heat treatment is performed; thus, the transistor 200 is stable at high temperatures (what is called thermal budget) in a manufacturing process.

The conductor 205 is placed to overlap with the oxide 230 and the conductor 260. Furthermore, the conductor 205 is preferably provided to be embedded in the insulator 216.

When the conductor 205 functions as a gate electrode, by changing a potential applied to the conductor 205 not in conjunction with but independently of a potential applied to the conductor 260, the threshold voltage of the transistor 200 can be adjusted. In particular, by applying a negative potential to the conductor 205, the threshold voltage of the transistor 200 can be further increased, and the off-state current can be reduced. Thus, a drain current when the potential applied to the conductor 260 is 0 V can be lower in the case where a negative potential is applied to the conductor 205 than in the case where the negative potential is not applied to the conductor 205.

As illustrated in FIG. 16A, the conductor 205 is preferably provided to be larger than a region of the oxide 230 that does not overlap with the conductor 242a or the conductor 242b. Although not illustrated, the conductor 205 preferably extends to a region outside the oxide 230a and the oxide 230b in the channel width direction of the oxide 230. That is, the conductor 205 and the conductor 260 preferably overlap with each other with the insulators therebetween on the outside of a side surface of the oxide 230 in the channel width direction. Providing the conductor 205 with a large area can reduce local charging (charge up) in treatment using plasma of a manufacturing step after forming the conductor 205 in some cases. Note that one embodiment of the present invention is not limited thereto. The conductor 205 overlaps with at least the oxide 230 positioned between the conductor 242a and the conductor 242b.

When a bottom surface of the insulator 224 is used as a reference, a bottom surface of the conductor 260 in a region where the oxide 230a and the oxide 230b do not overlap with the conductor 260 is preferably positioned at a lower level than a bottom surface of the oxide 230b is.

Although not illustrated, when the conductor 260 functioning as a gate covers, in the channel width direction, a side surface and the top surface of the oxide 230b serving as the channel formation region with the oxide 230c and the insulator 250 therebetween, electric fields generated from the conductor 260 are likely to affect the entire channel formation region formed in the oxide 230b. Thus, the on-state current of the transistor 200 can be increased and the frequency characteristics can be improved. In this specification, a transistor structure in which a channel formation region is electrically surrounded by electric fields of the conductor 260 and the conductor 205 is referred to as a surrounded channel (S-channel) structure.

The conductor 205a is preferably a conductor that inhibits passage of oxygen and impurities such as water or hydrogen. For example, titanium, titanium nitride, tantalum, or tantalum nitride can be used. Moreover, for the conductor 205b, a conductive material containing tungsten, copper, or aluminum as its main component is preferably used. Although the conductor 205 is illustrated as having two layers, a multilayer structure having three or more layers may be employed.

Here, it is preferable that an oxide semiconductor, an insulator or a conductor positioned in a layer below the oxide semiconductor, and an insulator or a conductor positioned in a layer above the oxide semiconductor be successively formed using different kinds of films without being exposed to the air, in which case a substantially highly purified intrinsic oxide semiconductor film where the concentration of impurities (in particular, hydrogen and water) is reduced can be formed.

At least one of the insulator 222, the insulator 272, and the insulator 273 preferably functions as a barrier insulating film that inhibits entry of impurities such as water or hydrogen into the transistor 200 from the substrate side or from above. Thus, at least one of the insulator 222, the insulator 272, and the insulator 273 is preferably formed using an insulating material which has a function of inhibiting diffusion of impurities (through which the impurities do not easily pass) such as a hydrogen atom, a hydrogen molecule, a water molecule, a nitrogen atom, a nitrogen molecule, a nitrogen oxide molecule (e.g., N₂O, NO, or NO₂), or a copper atom. Alternatively, it is preferable to use an insulating material which has a function of inhibiting diffusion of oxygen (e.g., at least one of an oxygen atom, an oxygen molecule, and the like) (through which the oxygen does not easily pass).

For example, it is preferable that the insulator 273 be formed using silicon nitride, silicon nitride oxide, or the like, and the insulator 222 and the insulator 272 be formed using aluminum oxide, hafnium oxide, or the like.

Accordingly, impurities such as water or hydrogen can be inhibited from being diffused to the transistor 200 side through the insulator 222. Alternatively, oxygen contained in the insulator 224 or the like can be inhibited from being diffused to the substrate side through the insulator 222.

Impurities such as water or hydrogen can be inhibited from diffusing to the transistor 200 side from the insulator 280 and the like, which are positioned with the insulator 272 and the insulator 273 therebetween. In this manner, the transistor 200 is preferably surrounded by the insulator 272 and the insulator 273 having a function of inhibiting diffusion of oxygen and impurities such as water or hydrogen.

Here, it is preferable that the insulator 224 in contact with the oxide 230 release oxygen by heating. In this specification, oxygen that is released by heating is referred to as excess oxygen in some cases. For example, silicon oxide, silicon oxynitride, or the like is used as appropriate for the insulator 224. When an insulator containing oxygen is provided in contact with the oxide 230, oxygen vacancies in the oxide 230 can be reduced and the reliability of the transistor 200 can be improved.

As the insulator 224, specifically, an oxide material that releases part of oxygen by heating is preferably used. An oxide that releases oxygen by heating is an oxide film in which the number of released oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in thermal desorption spectroscopy analysis (TDS analysis). Note that the temperature of the film surface in the TDS analysis is preferably within the range of higher than or equal to 100° C. and lower than or equal to 700° C., or higher than or equal to 100° C. and lower than or equal to 400° C.

The insulator 222 preferably functions as a barrier insulating film that inhibits entry of impurities such as water or hydrogen into the transistor 200 from the substrate side. For example, the insulator 222 preferably has lower hydrogen permeability than the insulator 224. Surrounding the insulator 224, the oxide 230, and the like by the insulator 222 and the insulator 283 can inhibit entry of impurities such as water or hydrogen into the transistor 200 from the outside.

Furthermore, it is preferable that the insulator 222 have a function of inhibiting diffusion of oxygen (e.g., at least one of an oxygen atom, an oxygen molecule, and the like) (through which the oxygen does not easily pass). For example, the insulator 222 preferably has lower oxygen permeability than the insulator 224. The insulator 222 preferably has a function of inhibiting diffusion of oxygen or impurities, in which case diffusion of oxygen contained in the oxide 230 into a layer below the insulator 222 can be reduced. Moreover, the conductor 205 can be inhibited from reacting with oxygen contained in the insulator 224 or the oxide 230.

As the insulator 222, an insulator containing an oxide of one or both of aluminum and hafnium, which is an insulating material, is preferably used. For the insulator containing an oxide of one or both of aluminum and hafnium, aluminum oxide, hafnium oxide, an oxide containing aluminum and hafnium (hafnium aluminate), or the like is preferably used. In the case where the insulator 222 is formed using such a material, the insulator 222 functions as a layer that inhibits release of oxygen from the oxide 230 and entry of impurities such as hydrogen into the oxide 230 from the periphery of the transistor 200.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the insulator.

Alternatively, for example, a single layer or stacked layers of an insulator containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST), may be used as the insulator 222. In the case where the insulator 222 has stacked layers, three layers of zirconium oxide, aluminum oxide, and zirconium oxide stacked in this order, or four layers of zirconium oxide, aluminum oxide, zirconium oxide, and aluminum oxide stacked in this order can be employed, for example. As the insulator 222, a compound containing hafnium and zirconium may be employed, for example. When the semiconductor device is miniaturized and highly integrated, a dielectric used for a gate insulator and a capacitor become thin, which might cause a problem of a leakage current from a transistor and the capacitor. When a high-k material is used for an insulator functioning as a dielectric used for a gate insulator and a capacitor, a gate potential during operation of the transistor can be lowered and the capacitance of the capacitor can be assured while the physical thickness is maintained.

Note that the insulator 222 and the insulator 224 may each have a stacked-layer structure of two or more layers. In such cases, without limitation to a stacked-layer structure formed of the same material, a stacked-layer structure formed of different materials may be employed.

The oxide 243 (the oxide 243a and the oxide 243b) may be placed between the oxide 230b and the conductor 242 (the conductor 242a and the conductor 242b) which functions as the source electrode and the drain electrode. This structure in which the conductor 242 and the oxide 230b are not in contact with each other can prevent the conductor 242 from absorbing oxygen in the oxide 230b. That is, preventing oxidation of the conductor 242 can inhibit a decrease in conductivity of the conductor 242. Thus, the oxide 243 preferably has a function of inhibiting oxidation of the conductor 242.

It is preferable to place the oxide 243 having a function of inhibiting passage of oxygen between the oxide 230b and the conductor 242, which functions as the source electrode and the drain electrode, in which case the electrical resistance between the conductor 242 and the oxide 230b is reduced. Such a structure can improve the electrical characteristics of the transistor 200 and the reliability of the transistor 200.

As the oxide 243, a metal oxide containing an element M, which is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like, is preferably used. In particular, aluminum, gallium, yttrium, or tin is preferably used as the element M. The concentration of the element M is preferably higher in the oxide 243 than in the oxide 230b. Alternatively, gallium oxide may be used as the oxide 243. A metal oxide such as an In-M-Zn oxide may be used as the oxide 243. Specifically, the atomic ratio of the element M to In in the metal oxide used as the oxide 243 is preferably greater than the atomic ratio of the element M to In in the metal oxide used as the oxide 230b. The thickness of the oxide 243 is preferably greater than or equal to 0.5 nm and less than or equal to 5 nm, further preferably greater than or equal to 1 nm and less than or equal to 3 nm. The oxide 243 preferably has crystallinity. In the case where the oxide 243 has crystallinity, release of oxygen from the oxide 230 can be favorably inhibited. When the oxide 243 has a hexagonal crystal structure, for example, release of oxygen from the oxide 230 can be inhibited in some cases.

Note that the oxide 243 is not necessarily provided. In that case, contact between the conductor 242 (the conductor 242a and the conductor 242b) and the oxide 230 may make oxygen in the oxide 230 diffuse into the conductor 242, resulting in oxidation of the conductor 242. It is highly possible that oxidation of the conductor 242 lowers the conductivity of the conductor 242. Note that diffusion of oxygen in the oxide 230 into the conductor 242 can be rephrased as absorption of oxygen in the oxide 230 by the conductor 242.

When oxygen in the oxide 230 diffuses into the conductor 242 (the conductor 242a and the conductor 242b), another layer is sometimes formed between the conductor 242a and the oxide 230b, and between the conductor 242b and the oxide 230b. The layer contains more oxygen than the conductor 242 and thus the layer presumably has an insulating property. In this case, a three-layer structure of the conductor 242, the layer, and the oxide 230b can be regarded as a three-layer structure of metal-insulator-semiconductor and is sometimes referred to as an MIS (Metal-Insulator-Semiconductor) structure or a diode junction structure having an MIS structure as its main part.

The above-described layer is not necessarily formed between the conductor 242 and the oxide 230b, and the layer may be formed between the conductor 242 and the oxide 230c or formed between the conductor 242 and the oxide 230b and between the conductor 242 and the oxide 230c.

The conductor 242 (the conductor 242a and the conductor 242b) functioning as the source electrode and the drain electrode is provided over the oxide 243. The thickness of the conductor 242 is greater than or equal to 1 nm and less than or equal to 50 nm, preferably greater than or equal to 2 nm and less than or equal to 25 nm, for example.

For the conductor 242, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing the above-described metal element; an alloy containing a combination of the above-described metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen.

The insulator 272 is provided in contact with a top surface of the conductor 242 and preferably functions as a barrier layer. With this structure, absorption of excess oxygen contained in the insulator 280 by the conductor 242 can be inhibited. Furthermore, by inhibiting oxidation of the conductor 242, an increase in the contact resistance between the transistor 200 and a wiring can be inhibited. Consequently, the transistor 200 can have favorable electrical characteristics and reliability.

Thus, the insulator 272 preferably has a function of inhibiting diffusion of oxygen. For example, the insulator 272 preferably has a function of inhibiting diffusion of oxygen more than the insulator 280 does. An insulator containing an oxide of one or both of aluminum and hafnium is preferably formed as the insulator 272, for example. An insulator containing aluminum nitride may be used as the insulator 272, for example.

As illustrated in FIG. 16A, the insulator 272 is in contact with part of a top surface of the conductor 242a, a side surface of the conductor 242a, part of a top surface of the conductor 242b, and a side surface of the conductor 242b. The insulator 273 is placed over the insulator 272. With such a structure, oxygen added to the insulator 280 can be inhibited from being absorbed by the conductor 242.

The insulator 250 functions as a gate insulator. The insulator 250 is preferably placed in contact with a top surface of the oxide 230c. For the insulator 250, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which have thermal stability, are preferable.

Like the insulator 224, the insulator 250 is preferably formed using an insulator from which oxygen is released by heating. When an insulator from which oxygen is released by heating is provided as the insulator 250 in contact with the top surface of the oxide 230c, oxygen can be effectively supplied to the channel formation region of the oxide 230b. Furthermore, as in the insulator 224, the concentration of impurities such as water or hydrogen in the insulator 250 is preferably reduced. The thickness of the insulator 250 is preferably greater than or equal to 1 nm and less than or equal to 20 nm.

Furthermore, a metal oxide may be provided between the insulator 250 and the conductor 260. The metal oxide preferably inhibits diffusion of oxygen from the insulator 250 into the conductor 260. Providing the metal oxide that inhibits diffusion of oxygen inhibits diffusion of oxygen from the insulator 250 into the conductor 260. That is, a reduction in the amount of oxygen supplied to the oxide 230 can be inhibited. In addition, oxidation of the conductor 260 due to oxygen from the insulator 250 can be inhibited.

The metal oxide has a function of part of the gate insulator in some cases. Therefore, when silicon oxide, silicon oxynitride, or the like is used for the insulator 250, a metal oxide that is a high-k material with a high dielectric constant is preferably used as the metal oxide. When the gate insulator has a stacked-layer structure of the insulator 250 and the metal oxide, the stacked-layer structure can be thermally stable and have a high dielectric constant. Thus, a gate potential that is applied during operation of the transistor can be reduced while the physical thickness of the gate insulator is maintained. Furthermore, the equivalent oxide thickness (EOT) of the insulator functioning as the gate insulator can be reduced.

Specifically, it is possible to use a metal oxide containing one kind or two or more kinds selected from hafnium, aluminum, gallium, yttrium, zirconium, tungsten, titanium, tantalum, nickel, germanium, magnesium, and the like. It is particularly preferable to use an insulator containing an oxide of one or both of aluminum and hafnium, such as aluminum oxide, hafnium oxide, or an oxide containing aluminum and hafnium (hafnium aluminate).

Alternatively, the metal oxide has a function of part of the gate in some cases. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate, a conductive material containing oxygen and a metal element contained in a metal oxide where the channel is formed. Alternatively, a conductive material containing the above-described metal element and nitrogen may be used. Alternatively, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

The conductor 260 is illustrated to have a two-layer structure in FIG. 16A, but may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, NO₂), and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen contained in the insulator 250. As a conductive material having a function of inhibiting diffusion of oxygen, for example, tantalum, tantalum nitride, ruthenium, ruthenium oxide, or the like is preferably used.

Moreover, a conductive material containing tungsten, copper, or aluminum as its main component is preferably used for the conductor 260b. The conductor 260 also functions as a wiring and thus is preferably formed using a conductor having high conductivity. For example, a conductive material containing tungsten, copper, or aluminum as its main component can be used. The conductor 260b may have a stacked-layer structure, for example, a stacked-layer structure of the above-described conductive material and titanium or titanium nitride.

### <Transistor 300>

The transistor 300 is described with reference to FIG. 16B. The transistor 300 is provided on the semiconductor substrate 311 and includes a conductor 316 functioning as a gate, an insulator 315 functioning as a gate insulator, a semiconductor region 313 formed of a part of the semiconductor substrate 311, and a low-resistance region 314a and a low-resistance region 314b functioning as the source region and the drain region. The transistor 300 may be a p-channel transistor or an n-channel transistor.

As the semiconductor substrate 311, a single crystal substrate or a silicon substrate is preferably used, for example.

A region of the semiconductor region 313 where a channel is formed, a region in the vicinity thereof, the low-resistance region 314a and the low-resistance region 314b functioning as the source region and the drain region, and the like preferably contain a semiconductor such as a silicon-based semiconductor, further preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and changing the lattice spacing is used. Alternatively, the transistor 300 may be an HEMT (High Electron Mobility Transistor) with the use of GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to a semiconductor material used for the semiconductor region 313.

For the conductor 316 functioning as a gate electrode, a semiconductor material such as silicon containing an element that imparts n-type conductivity, such as arsenic or phosphorus, or an element that imparts p-type conductivity, such as boron, or a conductive material such as a metal material, an alloy material, or a metal oxide material can be used.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

Here, in the transistor 300 illustrated in FIG. 16B, the semiconductor region 313 (part of the semiconductor substrate 311) where a channel is formed has a projecting shape. In addition, the conductor 316 is provided to cover a side surface and a top surface of the semiconductor region 313 with the insulator 315 therebetween. Note that a material adjusting the work function may be used for the conductor 316. The transistor 300 having such a structure is also referred to as a FIN transistor because the projecting portion of the semiconductor substrate 311 is utilized. Note that an insulator functioning as a mask for forming the projecting portion may be included in contact with an upper portion of the projecting portion. Although the case where the projecting portion is formed by processing part of the semiconductor substrate 311 is described here, a semiconductor film having a projecting shape may be formed by processing an SOI substrate.

Note that the transistor 300 illustrated in FIG. 15 and FIG. 16B is an example and the structure is not limited thereto; an appropriate transistor is used in accordance with a circuit configuration or a driving method. For example, in the case where the semiconductor device is a single-polarity circuit using only OS transistors (which represents a circuit that includes not transistors having different polarities but transistors having the same polarity, e.g., only n-channel transistors), the transistor 300 has a structure similar to the structure of the transistor 200T using an oxide semiconductor, for example. In this case, another substrate may be used instead of the semiconductor substrate 311 that employs a single crystal substrate, a silicon substrate, or the like.

Specific examples of the substrate include an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, paper including a fibrous material, and a base material film. Examples of the glass substrate include barium borosilicate glass, aluminoborosilicate glass, and soda lime glass. As examples of the flexible substrate, the attachment film, the base material film, and the like, the following can be given. The examples include plastics typified by polyethylene terephthalate (PET), polyethylene naphthalate (PEN), polyether sulfone (PES), and polytetrafluoroethylene (PTFE). Another example is a synthetic resin such as acrylic. Other examples are polypropylene, polyester, polyvinyl fluoride, and polyvinyl chloride. Other examples are polyamide, polyimide, aramid, epoxy, an inorganic vapor deposition film, paper, and the like.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride can be used, for example.

Note that in this specification, silicon oxynitride refers to a material that contains oxygen at a higher proportion than nitrogen, and silicon nitride oxide refers to a material that contains nitrogen at a higher proportion than oxygen. Furthermore, in this specification, aluminum oxynitride refers to a material that contains oxygen at a higher proportion than nitrogen, and aluminum nitride oxide refers to a material that contains nitrogen at a higher proportion than oxygen.

The insulator 322 may have a function of a planarization film for eliminating a level difference caused by the transistor 300 or the like provided below the insulator 322. For example, a top surface of the insulator 322 may be planarized by planarization treatment using a chemical mechanical polishing (CMP) method or the like to increase planarity.

The insulator 324 is preferably formed using a film having a barrier property that prevents diffusion of hydrogen and impurities from the semiconductor substrate 311, the transistor 300, or the like into a region where the transistor 200T, the transistor 200M, or the like is provided.

For the film having a barrier property against hydrogen, silicon nitride deposited by a CVD method can be used, for example. Here, diffusion of hydrogen into a semiconductor element including an oxide semiconductor, such as the transistor 200T, the transistor 200M, or the like, degrades the characteristics of the semiconductor element in some cases. Therefore, it is preferable to provide a film that inhibits diffusion of hydrogen between the transistor 300 and the transistor 200T, the transistor 200M, or the like. The film that inhibits hydrogen diffusion is specifically a film from which a small amount of hydrogen is released.

The amount of released hydrogen can be analyzed by thermal desorption spectroscopy (TDS) or the like, for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm², in the TDS analysis in a film-surface temperature range of 50° C. to 500° C., for example.

Note that the permittivity of the insulator 326 is preferably lower than that of the insulator 324. For example, the dielectric constant of the insulator 326 is preferably lower than 4, further preferably lower than 3. The dielectric constant of the insulator 326 is, for example, preferably 0.7 times or less, further preferably 0.6 times or less the dielectric constant of the insulator 324. When a material with a low dielectric constant is used for the interlayer film, the parasitic capacitance generated between wirings can be reduced.

In addition, a conductor 328, a conductor 330, and the like that are sometimes connected to the transistor 200T, the transistor 200M, or the like are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, there are cases where part of a conductor functions as a wiring and part of a conductor functions as a plug.

As a material of each of plugs and wirings (e.g., the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce the wiring resistance.

A wiring layer may be provided over the insulator 326 and the conductor 330. For example, in FIG. 16B, an insulator 350, an insulator 352, and an insulator 354 are stacked sequentially. Furthermore, a conductor 356 is formed in the insulator 350, the insulator 352, and the insulator 354. The conductor 356 has a function of a plug or a wiring that is connected to the transistor 300. Note that the conductor 356 can be provided using a material similar to those for the conductor 328 and the conductor 330.

For example, like the insulator 324, the insulator 350 is preferably formed using an insulator having a barrier property against hydrogen. The conductor 356 preferably includes a conductor having a barrier property against hydrogen. In particular, the conductor having a barrier property against hydrogen is formed in an opening portion of the insulator 350 having a barrier property against hydrogen. In such a structure, the transistor 300 can be separated from the transistor 200T, the transistor 200M, and the like by a barrier layer, so that the diffusion of hydrogen from the transistor 300 into the transistor 200T, the transistor 200M, or the like can be inhibited.

For the conductor having a barrier property against hydrogen, tantalum nitride is preferably used, for example. In addition, the use of a stack including tantalum nitride and tungsten, which has high conductivity, can inhibit diffusion of hydrogen from the transistor 300 while the conductivity of the wiring is maintained. In that case, a structure is preferable in which a tantalum nitride layer having a barrier property against hydrogen is in contact with the insulator 350 having a barrier property against hydrogen.

### <Memory Device 420>

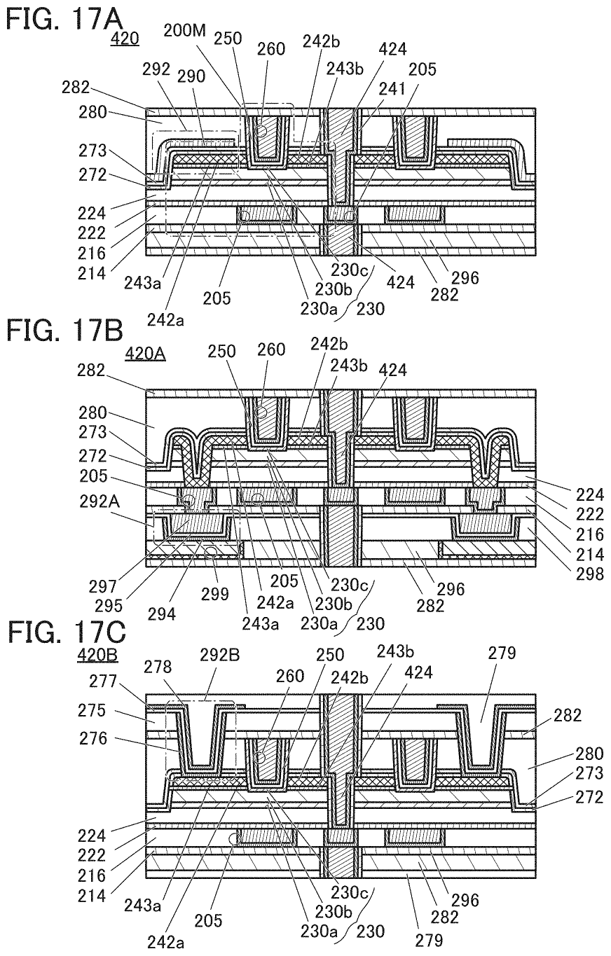

Next, the memory device 420 illustrated in FIG. 15 is described with reference to FIG. 17A. As for the transistor 200M included in the memory device 420, the description overlapping with that of the transistor 200 is omitted.

In the memory device 420, the conductor 242a of the transistor 200M functions as one electrode of the capacitor 292, and the insulator 272 and the insulator 273 function as a dielectric. A conductor 290 is provided to overlap with part of the conductor 242a with the insulator 272 and the insulator 273 sandwiched therebetween and functions as the other electrode of the capacitor 292. The conductor 290 may be used as the other electrode of the capacitor 292 included in an adjacent memory device 420. Alternatively, the conductor 290 may be electrically connected to the conductor 290 included in an adjacent memory device 420.

The conductor 290 is provided on not only the top surface of the conductor 242a but also the side surface of the conductor 242a with the insulator 272 and the insulator 273 sandwiched therebetween. This is preferable because the capacitor 292 can have a larger capacitance than the capacitance obtained depending on the area where the conductor 242a and the conductor 290 overlap with each other.

The conductor 424 is electrically connected to the conductor 242b and is electrically connected to the conductor 424 positioned in a lower layer through the conductor 205.

As a dielectric of the capacitor 292, silicon nitride, silicon nitride oxide, aluminum oxide, hafnium oxide, or the like can be used. Furthermore, these materials can be stacked. In the case where the dielectric of the capacitor 292 has a stacked-layer structure, stacked layers of aluminum oxide and silicon nitride or stacked layers of hafnium oxide and silicon oxide can be used. Here, the top and bottom of the stacked layers are not limited. For example, silicon nitride may be stacked over aluminum oxide, or aluminum oxide may be stacked over silicon nitride.

As the dielectric of the capacitor 292, zirconium oxide having a higher permittivity than the above-described materials may be used. As the dielectric of the capacitor 292, a single layer of zirconium oxide may be used, or zirconium oxide may be used in part of stacked layers. For example, stacked layers of zirconium oxide and aluminum oxide can be used. Furthermore, the dielectric of the capacitor 292 may be three stacked layers; zirconium oxide may be used as the first layer and the third layer and aluminum oxide may be used as the second layer between the first layer and the third layer.

When zirconium oxide having a high permittivity is used as the dielectric of the capacitor 292, the area occupied by the capacitor 292 in the memory device 420 can be reduced. Thus, the area necessary for the memory device 420 can be reduced, and the bit cost can be improved, which is preferable.

For the conductor 290, any of the materials that can be used for the conductor 205, the conductor 242, the conductor 260, the conductors 424, and the like can be used.

This embodiment shows an example where the transistors 200M and the capacitors 292 are each symmetrically placed with the conductor 424 sandwiched therebetween. When a pair of transistors 200M and a pair of capacitors 292 are placed in this manner, the number of conductors 424 electrically connected to the transistors 200M can be reduced. This is preferable because the area necessary for the memory device 420 can be reduced and the bit cost can be improved.

In the case where the insulator 241 is provided on the side surface of the conductor 424, the conductor 424 is connected to at least part of the top surface of the conductor 242b.

With the use of the conductors 424 and the conductor 205, the transistor 200T and the memory device 420 in the memory unit 470 can be electrically connected to each other.

### <Modification Example 1 of Memory Device 420>

Next, with reference to FIG. 17B, a memory device 420A is described as a modification example of the memory device 420. The memory device 420A includes the transistor 200M and a capacitor 292A electrically connected to the transistor 200M. The capacitor 292A is provided below the transistor 200M.

In the memory device 420A, the conductor 242a is placed in an opening that is provided in the oxide 243a, the oxide 230b, the oxide 230a, the insulator 224, and the insulator 222 and is electrically connected to the conductor 205 at a bottom portion of the opening. The conductor 205 is electrically connected to the capacitor 292A.

The capacitor 292A includes a conductor 294 functioning as one of electrodes, an insulator 295 functioning as a dielectric, and a conductor 297 functioning as the other of the electrodes. The conductor 297 overlaps with the conductor 294 with the insulator 295 sandwiched therebetween. Furthermore, the conductor 297 is electrically connected to the conductor 205.

The conductor 294 is provided in a bottom portion and on a side surface of an opening formed in an insulator 298 provided over the insulator 296, and the insulator 295 is provided so as to cover the insulator 298 and the conductor 294. Furthermore, the conductor 297 is provided so as to be embedded in a depression portion that the insulator 295 has.

Furthermore, a conductor 299 is provided so as to be embedded in the insulator 296, and the conductor 299 is electrically connected to the conductor 294. The conductor 299 may be electrically connected to the conductor 294 of an adjacent memory device 420A.

The conductor 297 is also provided on not only a top surface of the conductor 294 but also a side surface of the conductor 294 with the insulator 295 sandwiched therebetween. This is preferable because the capacitor 292A can have a larger capacitance than the capacitance obtained depending on the area where the conductor 294 and the conductor 297 overlap with each other.

As the insulator 295 functioning as a dielectric of the capacitor 292A, silicon nitride, silicon nitride oxide, aluminum oxide, hafnium oxide, or the like can be used. Furthermore, these materials can be stacked. In the case where the insulator 295 has a stacked-layer structure, stacked layers of aluminum oxide and silicon nitride or stacked layers of hafnium oxide and silicon oxide can be used. Here, the top and bottom of the stacked layers are not limited. For example, silicon nitride may be stacked over aluminum oxide, or aluminum oxide may be stacked over silicon nitride.

As the insulator 295, zirconium oxide having a higher permittivity than the above-described materials may be used. As the insulator 295, a single layer of zirconium oxide may be used, or zirconium oxide may be used in part of stacked layers. For example, stacked layers of zirconium oxide and aluminum oxide can be used. Furthermore, the insulator 295 may be three stacked layers; zirconium oxide may be used as the first layer and the third layer and aluminum oxide may be used as the second layer between the first layer and the third layer.

When zirconium oxide having a high permittivity is used for the insulator 295, the area occupied by the capacitor 292A in the memory device 420A can be reduced. Thus, the area necessary for the memory device 420A can be reduced, and the bit cost can be improved, which is preferable.

For the conductor 297, the conductor 294, and the conductor 299, any of the materials that can be used for the conductor 205, the conductor 242, the conductor 260, the conductors 424, and the like can be used.

Furthermore, as the insulator 298, any of the materials that can be used for the insulator 214, the insulator 216, the insulator 224, the insulator 280, and the like can be used.

### <Modification Example 2 of Memory Device 420>

Next, with reference to FIG. 17C, a memory device 420B is described as a modification example of the memory device 420. The memory device 420B includes the transistor 200M and a capacitor 292B electrically connected to the transistor 200M. The capacitor 292B is provided above the transistor 200M.

The capacitor 292B includes a conductor 276 functioning as one of electrodes, an insulator 277 functioning as a dielectric, and a conductor 278 functioning as the other of the electrodes. The conductor 278 overlaps with the conductor 276 with the insulator 277 sandwiched therebetween.

An insulator 275 is provided over the insulator 282, and the conductor 276 is provided in a bottom portion and on a side surface of an opening formed in the insulator 275, the insulator 282, the insulator 280, the insulator 273, and the insulator 272. The insulator 277 is provided so as to cover the insulator 282 and the conductor 276. Furthermore, the conductor 278 is provided so as to overlap with the conductor 276 in a depression portion that the insulator 277 has, and at least part of the conductor 278 is provided over the insulator 275 with the insulator 277 therebetween. The conductor 278 may be used as the other of the electrodes of the capacitor 292B included in an adjacent memory device 420B. Alternatively, the conductor 278 may be electrically connected to the conductor 278 included in an adjacent memory device 420B.

The conductor 278 is provided on not only a top surface of the conductor 276 but also a side surface of the conductor 276 with the insulator 277 sandwiched therebetween. This is preferable because the capacitor 292B can have a larger capacitance than the capacitance obtained depending on the area where the conductor 276 and the conductor 278 overlap with each other.

An insulator 279 may be provided so as to fill the depression portion that the conductor 278 has.

As the insulator 277 functioning as a dielectric of the capacitor 292B, silicon nitride, silicon nitride oxide, aluminum oxide, hafnium oxide, or the like can be used. Furthermore, these materials can be stacked. In the case where the insulator 277 has a stacked-layer structure, stacked layers of aluminum oxide and silicon nitride or stacked layers of hafnium oxide and silicon oxide can be used. Here, the top and bottom of the stacked layers are not limited. For example, silicon nitride may be stacked over aluminum oxide, or aluminum oxide may be stacked over silicon nitride.

As the insulator 277, zirconium oxide having a higher permittivity than the above-described materials may be used. As the insulator 277, a single layer of zirconium oxide may be used, or zirconium oxide may be used in part of stacked layers. For example, stacked layers of zirconium oxide and aluminum oxide can be used. Furthermore, the insulator 277 may be three stacked layers; zirconium oxide may be used as the first layer and the third layer and aluminum oxide may be used as the second layer between the first layer and the third layer.

When zirconium oxide having a high permittivity is used for the insulator 277, the area occupied by the capacitor 292B in the memory device 420B can be reduced. Thus, the area necessary for the memory device 420B can be reduced, and the bit cost can be improved, which is preferable.

For the conductor 276 and the conductor 278, any of the materials that can be used for the conductor 205, the conductor 242, the conductor 260, the conductors 424, and the like can be used.

Furthermore, for the insulator 275 and the insulator 279, any of the materials that can be used for the insulator 214, the insulator 216, the insulator 224, the insulator 280, and the like can be used.

### <Modification Example 3 of Memory Device>

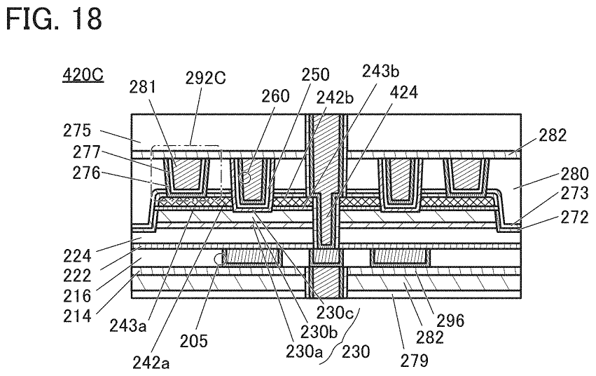

Next, with reference to FIG. 18, a memory device 420C is described as a modification example of the memory device 420. The memory device 420C includes the transistor 200M and a capacitor 292C electrically connected to the transistor 200M. The capacitor 292C is provided above the transistor 200M.

The capacitor 292C includes the conductor 276 functioning as one of electrodes, the insulator 277 functioning as a dielectric, and a conductor 281 functioning as the other of the electrodes. The conductor 281 overlaps with the conductor 276 with the insulator 277 sandwiched therebetween.

The insulator 275 is provided over the insulator 282. The conductor 276 is provided in a bottom portion and on a side surface of an opening formed in the insulator 280, the insulator 273, and the insulator 272. The insulator 277 is provided to cover the conductor 276. Furthermore, the conductor 281 is provided to overlap with the conductor 276 in a depression portion of the insulator 277. The conductor 281 may be electrically connected to the conductor 281 included in an adjacent memory device 420B (not illustrated in FIG. 18).

Note that the opening in which the insulator 280, the insulator 273, and the insulator 272 are provided may be formed concurrently with the opening in which the conductor 260, the insulator 250, and the oxide 230c are provided. This can shorten the manufacturing process of the memory device 420C in some cases.

The insulator 277 functioning as the dielectric of the capacitor 292C can be formed using a material that can be used for the insulator 277 functioning as the dielectric of the capacitor 292B, for example.

For the conductor 276 and the conductor 281, any of the materials that can be used for the conductor 205, the conductor 242, the conductor 260, the conductors 424, and the like can be used.

Furthermore, for the insulator 275, any of the materials that can be used for the insulator 214, the insulator 216, the insulator 224, the insulator 280, and the like can be used.

### <Connection Between Memory Device 420 and Transistor 200T>

In a region 422 surrounded by a dashed-dotted line in FIG. 15, the memory device 420 is electrically connected to the gate of the transistor 200T through the conductor 424 and the conductor 205; however, this embodiment is not limited thereto.

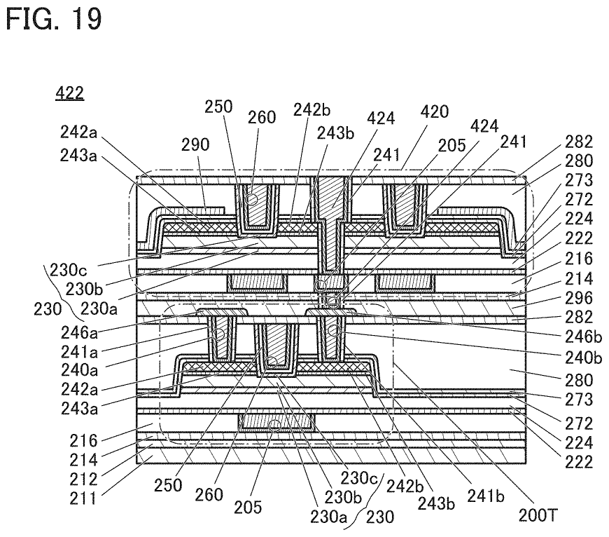

FIG. 19 illustrates an example where the memory device 420 is electrically connected to the conductor 242b functioning as one of the source and the drain of the transistor 200T through the conductor 424, the conductor 205, the conductor 246b, and the conductor 240b.

Thus, the method for connecting the memory device 420 and the transistor 200T can be determined in accordance with the function of the circuit included in the transistor layer 413.

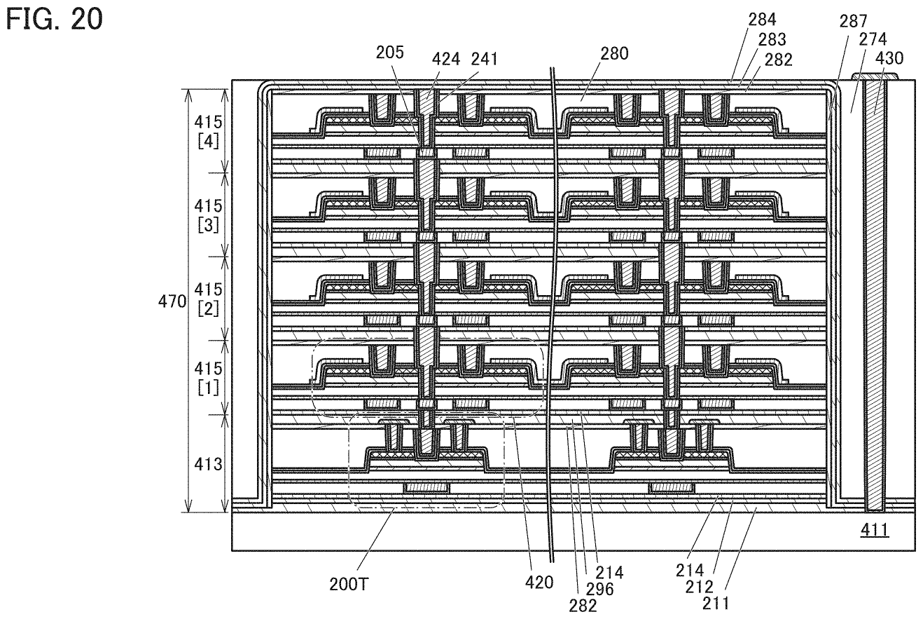

FIG. 20 illustrates an example where the memory unit 470 includes the transistor layer 413 including the transistor 200T and four memory device layers 415 (the memory device layer 415[1] to the memory device layer 415[4]).

The memory device layer 415[1] to the memory device layer 415[4] each include a plurality of memory devices 420.

The memory device 420 is electrically connected to the memory devices 420 included in different memory device layers 415 and the transistor 200T included in the transistor layer 413 through the conductors 424 and the conductors 205.

The memory unit 470 is sealed by the insulator 211, the insulator 212, the insulator 214, the insulator 287, the insulator 282, the insulator 283, and the insulator 284. The insulator 274 is provided in the periphery of the insulator 284. Furthermore, the conductor 430 is provided in the insulator 274, the insulator 284, the insulator 283, and the insulator 211 and is electrically connected to the element layer 411.

The insulator 280 is provided in the sealing structure. As in the description of the transistor 200, the insulator 280 preferably has a function of releasing oxygen by heating. In addition, the insulator 280 preferably includes an excess-oxygen region.

As in the description of the sealing structure, the insulator 211, the insulator 283, and the insulator 284 are suitably a material having a high barrier property against hydrogen. Specifically, silicon nitride, silicon nitride oxide, or the like can be used for the insulator 211, the insulator 283, and the insulator 284, for example. The insulator 214, the insulator 282, and the insulator 287 are suitably a material having a function of capturing or fixing hydrogen. Specifically, aluminum oxide, hafnium oxide, an oxide containing aluminum and hafnium (hafnium aluminate), gallium oxide, indium gallium zinc oxide, or the like can be used for the insulator 214, the insulator 282, and the insulator 287.

Note that materials for the insulator 211, the insulator 212, the insulator 214, the insulator 287, the insulator 282, the insulator 283, and the insulator 284 may have an amorphous or crystalline structure, although the crystal structure of the materials is not particularly limited. For example, an amorphous aluminum oxide film is suitably used as the material having a function of capturing or fixing hydrogen. Amorphous aluminum oxide may capture or fix hydrogen more than aluminum oxide having high crystallinity.

Here, as the model of excess oxygen in the insulator 280 with respect to diffusion of hydrogen from an oxide semiconductor in contact with the insulator 280, the following model can be given.

Hydrogen existing in the oxide semiconductor diffuses into another structure body through the insulator 280 in contact with the oxide semiconductor. The hydrogen diffuses in such a manner that excess oxygen in the insulator 280 reacts with the hydrogen in the oxide semiconductor to form an OH bond, which diffuses through the insulator 280. The hydrogen atom having the OH bond reacts with the oxygen atom bonded to an atom (e.g., a metal atom or the like) in the insulator 282 when reaching a material having a function of capturing or fixing hydrogen (typically the insulator 282), and is captured or fixed in the insulator 282. The oxygen atom which had the OH bond of the excess oxygen is assumed to remain as excess oxygen in the insulator 280. In short, the excess oxygen in the insulator 280 probably serves a bridge linking role in diffusing the hydrogen.

A manufacturing process of the semiconductor device is one of important factors for the model.

For example, the insulator 280 containing excess oxygen is formed over the oxide semiconductor, and then the insulator 282 is formed. After that, heat treatment is preferably performed. Specifically, the heat treatment is performed at 350° C. or higher, preferably 400° C. or higher under an atmosphere containing oxygen, an atmosphere containing nitrogen, or a mixed atmosphere of oxygen and nitrogen. The heat treatment time is one hour or more, preferably four hours or more, further preferably eight hours or more.

The heat treatment enables diffusion of hydrogen from the oxide semiconductor to the outside through the insulator 280, the insulator 282, and the insulator 287. This can reduce the absolute amount of hydrogen in and in the vicinity of the oxide semiconductor.

The insulator 283 and the insulator 284 are formed after the heat treatment. Since the insulator 283 and the insulator 284 are materials having a high barrier property against hydrogen, the insulator 283 and the insulator 284 can inhibit hydrogen diffused to the outside or external hydrogen from entering the inside, specifically, the oxide semiconductor or the insulator 280 side.

Although the structure in which the heat treatment is performed after the insulator 282 is formed is described as an example, one embodiment of the present invention is not limited thereto.

For example, the above-described heat treatment may be performed after formation of the transistor layer 413 or after formation of the memory device layer 415[1] to the memory device layer 415[3]. When hydrogen is diffused to the outside by the above-described heat treatment, hydrogen is diffused to above the transistor layer 413 or in the lateral direction. Similarly, in the case where the heat treatment is performed after the formation of the memory device layer 415[1] to the memory device layer 415[3], hydrogen is diffused to above or in the lateral direction.

The insulator 211 and the insulator 283 are bonded through the above manufacturing process, whereby the above-described sealing structure are formed.

The above-described structure and manufacturing process enable a semiconductor device using an oxide semiconductor with reduced hydrogen concentration to be provided. Accordingly, a highly reliable semiconductor device can be provided. With one embodiment of the present invention, a semiconductor device having favorable electrical characteristics can be provided.

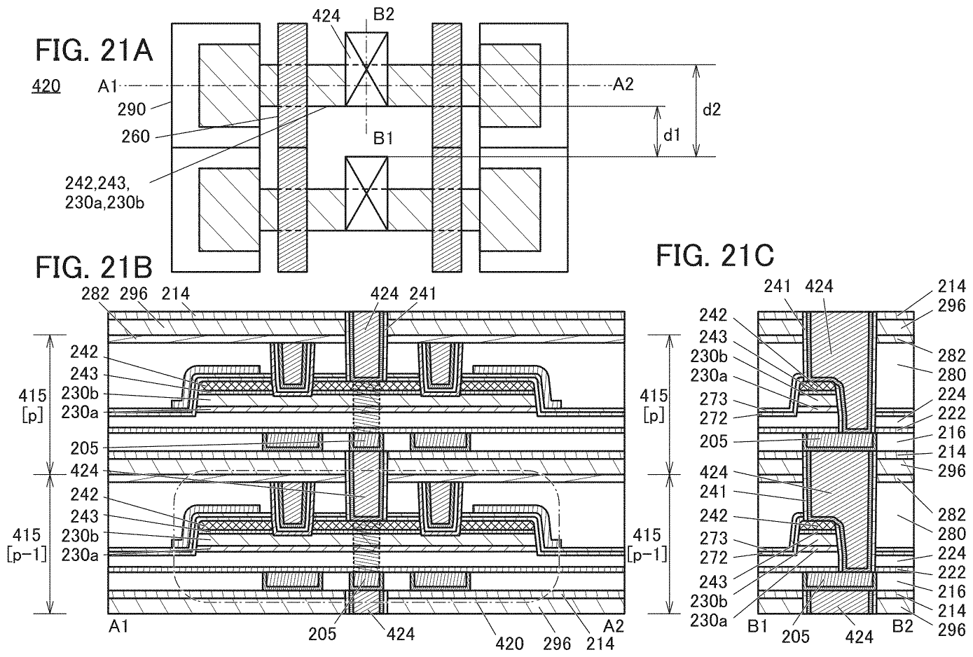

FIG. 21A to FIG. 21C are diagrams illustrating an example that is different in the arrangement of the conductors 424. FIG. 21A illustrates a top view of the memory device 420, FIG. 21B is a cross-sectional view of a portion indicated by a dashed-dotted line A1-A2 in FIG. 21A, and FIG. 21C is a cross-sectional view of a portion indicated by a dashed-dotted line B1-B2 in FIG. 21A. In FIG. 21A, the conductor 205 is not illustrated to facilitate understanding of the drawing. In the case where the conductor 205 is provided, the conductor 205 includes a region overlapping with the conductor 260 and the conductor 424.

As illustrated in FIG. 21A, an opening where the conductor 424 is provided, i.e., the conductor 424, is provided not only in a region overlapping with the oxide 230a and the oxide 230b but also outside the oxide 230a and the oxide 230b. FIG. 21A illustrates an example where the conductor 424 is provided in a region not overlapping with the oxide 230a and the oxide 230b on the B2 side; however, this embodiment is not limited thereto. The conductor 424 may be provided in a region not overlapping with the oxide 230a and the oxide 230b on the B1 side, or may be provided in regions not overlapping with the oxide 230a and the oxide 230b on both the B1 side and the B2 side.

FIG. 21B and FIG. 21C illustrate an example where the memory device layer 415[p] is stacked over the memory device layer 415[p−1] (p is a natural number greater than or equal to 2 and less than or equal to n). The memory device 420 included in the memory device layer 415[p−1] is electrically connected to the memory device 420 included in the memory device layer 415 [p] through the conductor 424 and the conductor 205.

FIG. 21B illustrates an example where in the memory device layer 415[p−1], the conductor 424 is connected to the conductor 242 of the memory device layer 415[p−1] and the conductor 205 of the memory device layer 415[p]. Here, the conductor 424 is also connected to the conductor 205 of the memory device layer 415[p−1] at the outside on the B2 side of the conductor 242, the oxide 243, the oxide 230b, and the oxide 230a.

As illustrated in FIG. 21C, the conductor 424 is formed along the side surfaces on the B2 side of the conductor 242, the oxide 243, the oxide 230b, and the oxide 230a, and is electrically connected to the conductor 205 through an opening formed in the insulator 280, the insulator 273, the insulator 272, the insulator 224, and the insulator 222. Here, an example where the conductor 424 is provided along the side surfaces on the B2 side of the conductor 242, the oxide 243, the oxide 230b, and the oxide 230a is indicated by a dotted line in FIG. 21B. Furthermore, the insulator 241 is formed between the conductor 424 and the side surfaces on the B2 side of the conductor 242, the oxide 243, the oxide 230b, the oxide 230a, the insulator 224, and the insulator 222, in some cases.

Provision of the conductor 424 in a region not overlapping with the conductor 242 or the like allows the memory device 420 to be electrically connected to the memory device 420 provided in another memory device layer 415. In addition, the memory device 420 can also be electrically connected to the transistor 200T provided in the transistor layer 413.

Furthermore, when the conductor 424 serves as a bit line, provision of the conductor 424 in a region not overlapping with the conductor 242 or the like can increase the distance between bit lines of the memory devices 420 that are adjacent to each other in the B1-B2 direction. As illustrated in FIG. 21, the distance between the conductors 424 over the conductors 242 is d1; the distance between the conductors 424 positioned below the oxide 230a, that is, in an opening formed in the insulator 224 and the insulator 222 is d2; and d2 is larger than d1. The parasitic capacitance of the conductors 424 can be reduced when the distance is partly d2 compared with the case where the distance between the conductors 424 that are adjacent to each other in the B1-B2 direction is d1. The reduction of the parasitic capacitance of the conductors 424 is preferable to reduce the capacitance necessary for the capacitor 292.

Note that this embodiment can be combined with any of the other embodiments in this specification as appropriate.

### Embodiment 4

Described in this embodiment is a metal oxide (hereinafter also referred to as an oxide semiconductor) that can be used in an OS transistor described in the above embodiment.

A metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

### <Classification of Crystal Structures>

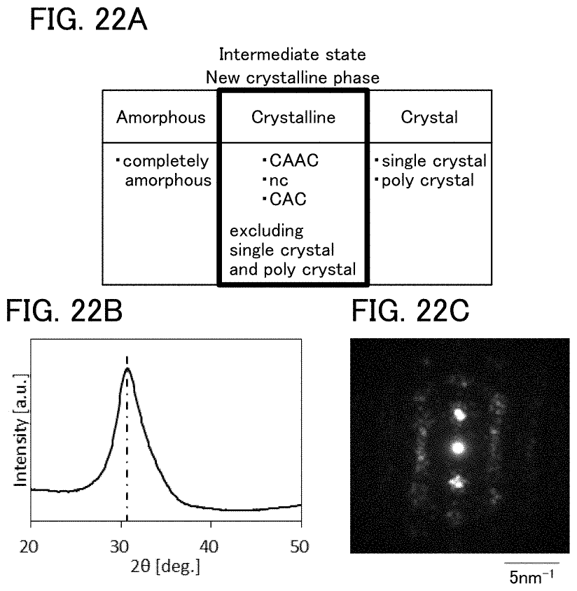

First, the classification of the crystal structures of an oxide semiconductor will be described with reference to FIG. 22A. FIG. 22A is a diagram showing the classification of crystal structures of an oxide semiconductor, typically IGZO (a metal oxide containing In, Ga, and Zn).

As shown in FIG. 22A, an oxide semiconductor is roughly classified into “Amorphous”, “Crystalline”, and “Crystal”. The term “Crystalline” includes CAAC (c-axis-aligned crystalline), nc (nanocrystalline), and CAC (cloud-aligned composite) (excluding single crystal and poly crystal). Note that single crystal, poly crystal, and completely amorphous are excluded from the category of “Crystalline”. The term “Crystal” includes single crystal and poly crystal.

Note that the structures in the thick frame in FIG. 22A are in an intermediate state between “Amorphous” and “Crystal”, and belong to a new crystalline phase. That is, these structures are completely different from “Amorphous”, which is energetically unstable, and “Crystal”.

A crystal structure of a film or a substrate can be evaluated with an X-ray diffraction (XRD) spectrum. FIG. 22B shows an XRD spectrum, which is obtained by GIXD (Grazing-Incidence XRD) measurement, of a CAAC-IGZO film classified into “Crystalline” (the vertical axis represents intensity in arbitrary unit (a. u.)). Note that a GIXD method is also referred to as a thin film method or a Seemann-Bohlin method. The XRD spectrum that is shown in FIG. 22B and obtained by GIXD measurement is hereinafter simply referred to as an XRD spectrum. The CAAC-IGZO film in FIG. 22B has a composition in the neighborhood of In:Ga:Zn=4:2:3 [atomic ratio]. The CAAC-IGZO film in FIG. 22B has a thickness of 500 nm.

As shown in FIG. 22B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. 22B, the peak at 2θ of around 31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 22C shows a diffraction pattern of the CAAC-IGZO film. FIG. 22C shows a diffraction pattern obtained by the NBED method in which an electron beam is incident in the direction parallel to the substrate. The composition of the CAAC-IGZO film in FIG. 22C is In:Ga:Zn=4:2:3 [atomic ratio] or the neighborhood thereof. In the nanobeam electron diffraction method, electron diffraction is performed with a probe diameter of 1 nm.

As shown in FIG. 22C, a plurality of spots indicating c-axis alignment are observed in the diffraction pattern of the CAAC-IGZO film.

### <<Structure of Oxide Semiconductor>>

Oxide semiconductors might be classified in a manner different from that in FIG. 22A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a stacked-layer structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is unlikely to occur. Entry of impurities, formation of defects, or the like might decrease the crystallinity of an oxide semiconductor, which means that the CAAC-OS can be referred to as an oxide semiconductor having small amounts of impurities and defects (e.g., oxygen vacancies). Therefore, an oxide semiconductor including the CAAC-OS is physically stable. Accordingly, the oxide semiconductor including the CAAC-OS is resistant to heat and has high reliability. In addition, the CAAC-OS is stable with respect to high temperatures in the manufacturing process (i.e., thermal budget). Accordingly, the use of the CAAC-OS for the OS transistor can extend the degree of freedom of the manufacturing process.

[nc-OS]

In the nc-OS, a microscopic region (e.g., a region greater than or equal to 1 nm and less than or equal to 10 nm, in particular, a region greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. There is no regularity of crystal orientation between different nanocrystals in the nc-OS. Hence, the orientation in the whole film is not observed. Accordingly, in some cases, the nc-OS cannot be distinguished from an a-like OS or an amorphous oxide semiconductor, depending on the analysis method. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic proportions of In, Ga, and Zn in the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] than the second region and lower [Ga] than the second region. Moreover, the second region has higher [Ga] than the first region and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (A and excellent switching operation can be achieved.

An oxide semiconductor can have any of various structures that show various different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, a case where the above-described oxide semiconductor is used for a transistor is described.

When the above-described oxide semiconductor is used for a transistor, a transistor with high field-effect mobility can be achieved. In addition, a highly reliable transistor can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm³, still further preferably lower than or equal to 1×10¹¹ cm³, yet further preferably lower than 1×10¹⁰ cm³, and higher than or equal to 1×10⁻⁹ cm³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Electric charges captured by the trap states in an oxide semiconductor take a long time to be released and may behave like fixed electric charges. A transistor whose channel formation region is formed in an oxide semiconductor having a high density of trap states has unstable electrical characteristics in some cases.

In order to obtain stable electrical characteristics of the transistor, it is effective to reduce the impurity concentration in the oxide semiconductor. In order to reduce the impurity concentration in the oxide semiconductor, the impurity concentration in a film that is adjacent to the oxide semiconductor is preferably reduced. Examples of impurities include hydrogen, nitrogen, an alkali metal, an alkaline earth metal, iron, nickel, and silicon.

### <Impurities>

Here, the influence of each impurity in the oxide semiconductor is described.

When silicon or carbon, which is a Group 14 element, is contained in an oxide semiconductor, defect states are formed in the oxide semiconductor. Thus, the concentration of silicon or carbon in the oxide semiconductor and in the vicinity of an interface with the oxide semiconductor (the concentration obtained by secondary ion mass spectrometry (SIMS)) is lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor using an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. Thus, a transistor using an oxide semiconductor that contains nitrogen as the semiconductor tends to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in an oxide semiconductor reacts with oxygen bonded to a metal atom to be water, and thus causes an oxygen vacancy in some cases. Entry of hydrogen into the oxygen vacancy generates an electron serving as a carrier in some cases. Furthermore, some hydrogen may react with oxygen bonded to a metal atom and generate an electron serving as a carrier. Thus, a transistor using an oxide semiconductor that contains hydrogen tends to have normally-on characteristics. For this reason, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

Note that this embodiment can be combined with any of the other embodiments in this specification as appropriate.

### Embodiment 5

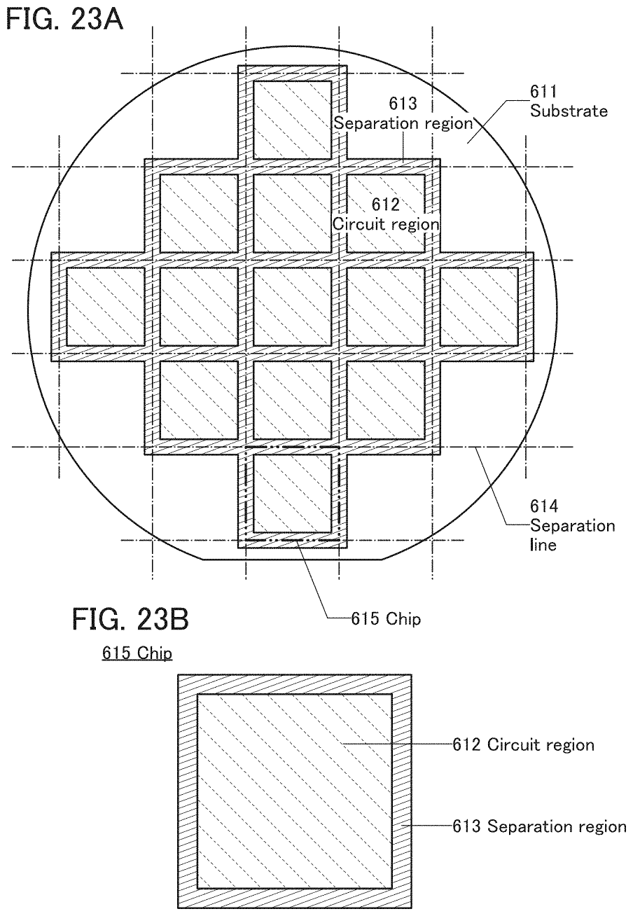

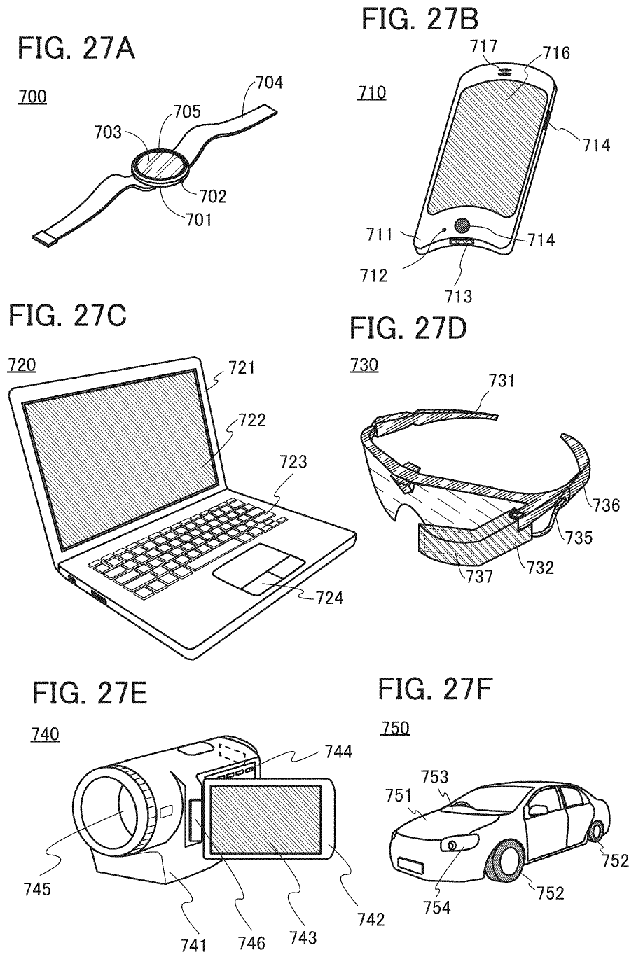

In this embodiment, examples of a semiconductor wafer, an IC chip, and an electronic component each including the memory device or the semiconductor device described in the above embodiments will be described with reference to FIG. 23 and FIG. 27.

### [Semiconductor Wafer and Chip]

FIG. 23A is a top view illustrating a substrate 611 before dicing treatment. As the substrate 611, a semiconductor substrate (also referred to as “semiconductor wafer”) can be used, for example. The substrate 611 has a plurality of circuit regions 612. The semiconductor device shown in any of the above embodiments, for example, can be provided in the circuit region 612.

Each of the circuit regions 612 is surrounded by a separation region 613. Separation lines (also referred to as “dicing lines”) 614 are set at a position overlapping the separation regions 613. Chips 615 each including the circuit region 612 can be cut from the substrate 611 by cutting the substrate 611 along the separation lines 614. FIG. 23B is an enlarged view of the chip 615.

Furthermore, a conductive layer or a semiconductor layer may be provided in the separation regions 613. Providing a conductive layer or a semiconductor layer in the separation regions 613 relieves ESD that might be caused in a dicing step, preventing a decrease in the yield in the dicing step. Furthermore, a dicing step is generally performed while letting pure water whose specific resistance is decreased by the inclusion of a carbonic acid gas or the like flow to a cut portion, in order to cool down a substrate, remove swarf, and prevent electrification, for example. Providing a conductive layer or a semiconductor layer in the separation regions 613 allows a reduction in the usage of the pure water. Therefore, the cost of manufacturing the semiconductor device can be reduced. Moreover, the productivity of the semiconductor device can be improved.

For a semiconductor layer provided in the separation regions 613, it is preferable to use a material having a bandgap larger than or equal to 2.5 eV and smaller than or equal to 4.2 eV, preferably larger than or equal to 2.7 eV and smaller than or equal to 3.5 eV. The use of such a material allows accumulated charge to be released slowly; thus, rapid move of charge due to ESD can be suppressed and electrostatic breakdown is less likely to occur.

### [Electronic Component]

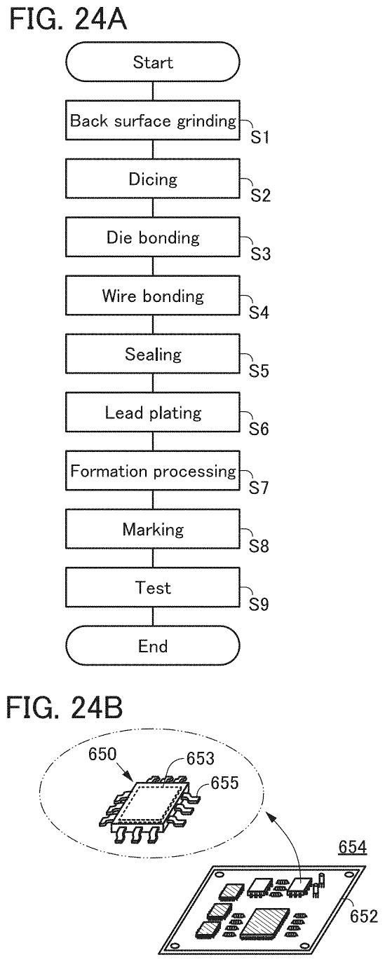

FIG. 24 shows an example where the chip 615 is used for an electronic component.

Note that an electronic component is also referred to as a semiconductor package or an IC package. For electronic components, there are various standards and names corresponding to a terminal extraction direction and a terminal shape.

An electronic component is completed by combining the semiconductor device described in any of the above embodiments and components other than the semiconductor device in the assembly process (post-process).

The post-process is described with reference to a flow chart shown in FIG. 24A. After an element substrate including the semiconductor device described in any of the above embodiments is completed in a pre-process, a “back surface grinding step” is performed to grind a back surface (a surface where the semiconductor device and the like are not formed) of the element substrate (Step S1). When the element substrate is thinned by grinding, warpage or the like of the element substrate is reduced, resulting in the reduction in size of the electronic component.

Next, a “dicing step” is performed to divide the element substrate into a plurality of chips (Step S2). Then, a “die bonding step” is performed to pick up the divided chips separately and bond them to a lead frame (Step S3). To bond a chip and a lead frame in the die bonding step, resin bonding, tape-automated bonding, or the like is selected as determined as appropriate by products. Note that the chip may be bonded to an interposer substrate instead of the lead frame.

Next, a “wire bonding step” is performed to electrically connect a lead of the lead frame and an electrode on the chip through a metal fine line (wire) (Step S4). A silver line or a gold line can be used as the metal fine line. Furthermore, ball bonding or wedge bonding can be used as the wire bonding.

The wire-bonded chip is subjected to a “sealing step (molding step)” of sealing the chip with an epoxy resin or the like (Step S5). Through the sealing step, the inside of the electronic component is filled with a resin, so that a circuit portion incorporated in the chip and a wire for connecting the chip to the lead can be protected from external mechanical force, and deterioration of characteristics (decrease in reliability) due to moisture or dust can be reduced.

Subsequently, a “lead plating step” is performed to plate the lead of the lead frame (Step S6). With the plating process, corrosion of the lead can be prevented, and soldering for mounting the electronic component on a printed circuit board in a later step can be performed more surely. Then, a “formation step” is performed to cut and process the lead (Step S7).

Next, a “marking step” in which printing (marking) is performed on a surface of the package is conducted (Step S8). After a “testing step” (Step S9) for checking whether an external shape is good and whether there is a malfunction, for example, the electronic component is completed.

Furthermore, FIG. 24B is a schematic perspective view of the completed electronic component. FIG. 24B shows a schematic perspective view of a QFP (Quad Flat Package) as an example of the electronic component. An electronic component 650 illustrated in FIG. 24B includes a lead 655 and a semiconductor device 653. As the semiconductor device 653, the memory device or the semiconductor device described in any of the above embodiments can be used, for instance.

The electronic component 650 in FIG. 24B is, for example, mounted on a printed circuit board 652. A plurality of electronic components 650 are used in combination and electrically connected to each other over the printed circuit board 652; thus, a board 654 on which the electronic components are mounted is completed. The completed board 654 is used in an electronic device or the like.

Note that this embodiment can be combined with any of the other embodiments in this specification as appropriate.

### Embodiment 6

In this embodiment, a system including any of the semiconductor device, the electronic component (semiconductor wafer), and the like disclosed in this specification and the like is described.

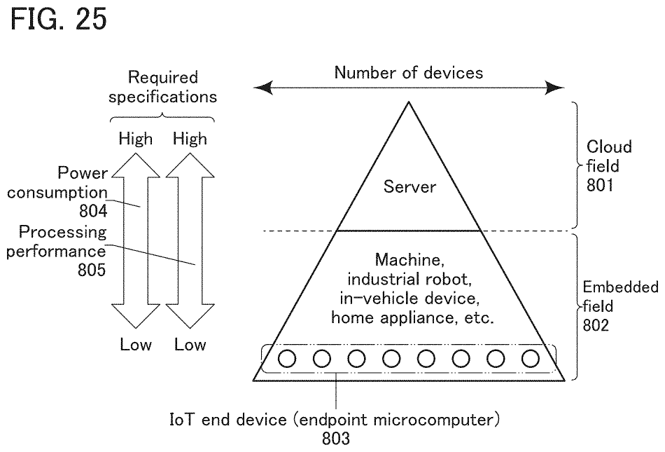

The semiconductor device such as the CPU, the RFIC, or the like described in the above embodiment can be suitably used for a small-scale system such as an IoT (Internet of Things) end device (also referred to as “endpoint microcomputer”) 803 in the IoT field, for example. FIG. 25 illustrates a hierarchical structure of an IoT network and tendencies of required specifications. FIG. 25 illustrates power consumption 804 and processing performance 805 as the required specifications. The hierarchical structure of the IoT network is roughly divided into a cloud field 801 at the upper level and an embedded field 802 at the lower level. The cloud field 801 includes a server, for example. The embedded field 802 includes a machine, an industrial robot, an in-vehicle device, and a home appliance, for example.

Higher processing performance is required rather than lower power consumption at the upper level. Thus, a high-performance CPU, a high-performance GPU, a large-scale SoC (System on a Chip), and the like are used in the cloud field 801. Furthermore, lower power consumption is required rather than higher processing performance at the lower level where the number of devices is explosively increased.

Note that an “endpoint” refers to an end region of the embedded field 802. Examples of devices used in the endpoint include microcomputers used in a factory, a home appliance, infrastructure, agriculture, and the like.

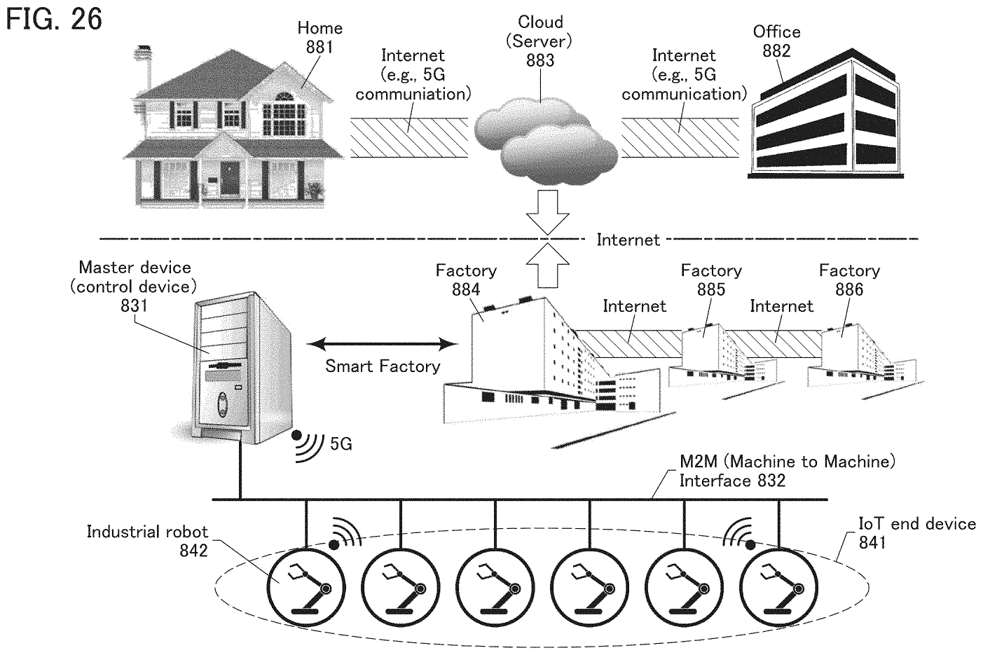

FIG. 26 shows a conceptual diagram showing factory automation as an application example of the endpoint microcomputer. A factory 884 is connected to a cloud 883 through Internet connection (Internet). The cloud 883 is connected to a home 881 and an office 882 through the Internet connection. The Internet connection may be wired communication or wireless communication. For example, in the case of wireless communication, the fourth-generation mobile communication system (4G) or the fifth-generation mobile communication system (5G) may be used. The factory 884 may be connected to a factory 885 and a factory 886 through the Internet connection.

The factory 884 includes a master device (control device) 831. The master device 831 is connected to the cloud 883 and has a function of transmitting and receiving data. The master device 831 is connected to a plurality of industrial robots 842 included in an IoT end device 841 through an M2M (Machine to Machine) interface 832. As the M2M interface 832, for example, industrial Ethernet (registered trademark), which is a kind of wired communication, or local 5G, which is a kind of wireless communication, may be used.

A factory manager can check the operational status or the like from the home 881 or the office 882 connected to the factory 884 through the cloud 883. In addition, the manager can check wrong items and part shortage, instruct a storage space, and measure takt time, for example.

In recent years, IoT has been globally introduced into factories; under the name “Smart Factory”. Smart Factory has been reported to enable not only simple examination and inspection by an endpoint microcomputer but also detection of failures and prediction of abnormality, for example.

Note that this embodiment can be combined with any of the other embodiments in this specification as appropriate.

### Embodiment 7

The memory device or the semiconductor device described in any of the above embodiments is preferably used in an electronic device incorporating a battery. With use of the memory device or the semiconductor device described in any of the above embodiments for an electronic device incorporating a battery, power consumption of the electronic device can be reduced, and power of the battery can be saved. FIG. 27A to FIG. 27F illustrates specific examples.

FIG. 27A illustrates a wristwatch terminal 700. The wristwatch terminal 700 includes a housing 701, a winding crown 702, a display portion 703, a belt 704, a sensing unit 705, and the like. A battery and the memory device or the semiconductor device are provided inside the housing 701. The display portion 703 may be provided with a touch panel. A user can input information by using a finger touching the touch panel as a pointer.

The sensing unit 705 has a function of obtaining information by sensing a surrounding state. For example, a camera, an acceleration sensor, a direction sensor, a pressure sensor, a temperature sensor, a humidity sensor, an illuminance sensor, or a GPS (Global Positioning System) signal receiver circuit can be used as the sensing unit 705.

For example, when an arithmetic device in the housing 701 determines that the ambient light level sensed by an illuminance sensor of the sensing unit 705 is sufficiently higher than predetermined illuminance, the luminance of the display portion 703 is lowered. Meanwhile, when the arithmetic device determines that the ambient light level is not sufficiently high, the luminance of the display portion 703 is increased. As a result, an electronic device with reduced power consumption can be provided.

FIG. 27B illustrates a mobile phone 710. The mobile phone 710 includes a housing 711, a display portion 716, operation buttons 714, an external connection port 713, a speaker 717, a microphone 712, and the like. A battery and the memory device or the semiconductor device are provided inside the housing 711. When the display portion 716 is touched with a finger or the like, information can be input to the mobile phone 710. Various operations such as making a call and inputting letters can be performed by touch on the display portion 716 with a finger or the like. In addition, power ON/OFF operation or switching types of images displayed on the display portion 716 can be performed with the operation button 714. For example, the screen can be switched from a mail creation screen to a main menu screen.

FIG. 27C illustrates a laptop personal computer 720 including a housing 721, a display portion 722, a keyboard 723, a pointing device 724, and the like. A battery and the memory device or the semiconductor device are provided inside the housing 711.

FIG. 27D illustrates a goggle-type display 730. The goggle-type display 730 includes temples 731, a housing 732, a cable 735, a battery 736, and a display portion 737. The battery 736 is held in the temple 731. The display portion 737 is provided in the housing 732. The housing 732 incorporates a variety of electronic components such as a semiconductor device, a wireless communication device, and a memory device. Power is supplied from the battery 736 through the cable 735 to the display portion 737 and the electronic components in the housing 732. A variety of information such as an image transmitted wirelessly is displayed on the display portion 737.

A camera may be provided in the housing 732 of the goggle-type display 730. A user can operate the goggle-type display 730 owing to the camera, which senses movement of the eye and eyelid of the user. Furthermore, the temple 731 of the goggle-type display 730 may be provided with various sensors such as a temperature sensor, a pressure sensor, an acceleration sensor, and a biosensor. For example, the goggle-type display 730 obtains biological information on the user with a biosensor and stores the information in the memory device of the housing 732. Furthermore, the goggle-type display 730 may transmit biological information to another information terminal with a radio signal.

FIG. 27E illustrates a video camera 740. The video camera 740 includes a first housing 741, a second housing 742, a display portion 743, an operation key 744, a lens 745, a joint 746, and the like. The operation key 744 and the lens 745 are provided in the first housing 741, and the display portion 743 is provided in the second housing 742. Furthermore, a battery and the memory device or the semiconductor device are provided inside the first housing 741. The battery may be provided outside the first housing 741. The first housing 741 and the second housing 742 are connected to each other with the joint 746, and the angle between the first housing 741 and the second housing 742 can be changed with the joint 746. Images on the display portion 743 may be switched in accordance with the angle at the joint 746 between the first housing 741 and the second housing 742.

FIG. 27F illustrates an automobile 750. The automobile 750 includes a car body 751, wheels 752, a dashboard 753, lights 754, and the like. A battery and the memory device or the semiconductor device are provided inside the car body 751.

Note that each of the electronic devices illustrated in FIG. 27A to FIG. 27F can be provided with the semiconductor device, the electronic component, and the like described in the above embodiments. Note that the electronic devices described in this embodiment can have a function of the IoT end device 803 described in Embodiment 6.

Note that this embodiment can be combined with any of the other embodiments in this specification as appropriate.

(Notes on Description of this Specification and the Like)

Ordinal numbers such as “first”, “second”, and “third” in this specification and the like are used in order to avoid confusion among components. Thus, the terms do not limit the number of components. In addition, the terms do not limit the order of components. Furthermore, in this specification and the like, for example, a “first” component in one embodiment can be referred to as a “second” component in other embodiments or claims. Furthermore, in this specification and the like, for example, a “first” component in one embodiment can be omitted in other embodiments or the scope of claims.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In this specification and the like, the term such as an “electrode” or a “wiring” does not limit a function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, voltage and potential can be interchanged with each other as appropriate. The voltage refers to a potential difference from a reference potential, and when the reference potential is a ground potential, for example, the voltage can be rephrased into the potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of determining whether current flows or not by being conducting (on) or not conducting (off). Alternatively, a switch has a function of selecting and changing a current path. Examples of the switch that can be used are an electrical switch, a mechanical switch, and the like. That is, a switch can be any element capable of controlling a current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined.

Note that in the case where a transistor is used as a switch, the “conduction state” of the transistor refers to a state in which a source and a drain of the transistor can be regarded as being electrically short-circuited. In addition, the “non-conduction state” of the transistor refers to a state in which the source and the drain of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical system) technology, such as a digital micromirror device (DMD). Such a switch includes an electrode that can be moved mechanically, and operates by controlling conduction and non-conduction with movement of the electrode.

In the case where there is an explicit description, X and Y are connected, in this specification and the like, for example, the case where X and Y are electrically connected, the case where X and Y are functionally connected, and the case where X and Y are directly connected are disclosed in this specification and the like. Accordingly, without being limited to a predetermined connection relation, for example, a connection relation shown in drawings or text, a connection relation other than one shown in drawings or text is regarded as being disclosed in the drawings or the text.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, and the case where X and Y are connected without the element that allows the electrical connection between X and Y (e.g., a switch, a transistor, a capacitor, an inductor, a resistor, a diode, a display element, a light-emitting element, and a load) provided therebetween.

For example, in the case where X and Y are electrically connected, one or more elements that allow an electrical connection between X and Y (e.g., a switch, a transistor, a capacitor, an inductor, a resistor, a diode, a display element, a light-emitting element, and a load) can be connected between X and Y. Note that the switch has a function of being controlled to be turned on or off That is, a switch has a function of being in a conduction state (on state) or a non-conduction state (off state) to control whether or not current flows. Note that the case where X and Y are electrically connected includes the case where X and Y are directly connected.

An example of the case where X and Y are functionally connected is the case where one or more circuits that allow functional connection between X and Y (for example, a logic circuit (an inverter, a NAND circuit, a NOR circuit, or the like), a signal converter circuit (a DA converter circuit, an AD converter circuit, a gamma correction circuit, or the like), a potential level converter circuit (a power supply circuit (for example, a step-up circuit, a step-down circuit, or the like), a level shifter circuit for changing the potential level of a signal, or the like), a voltage source, a current source, a switching circuit, an amplifier circuit (a circuit capable of increasing signal amplitude, the amount of current, or the like, an operational amplifier, a differential amplifier circuit, a source follower circuit, a buffer circuit, or the like), a signal generator circuit, a memory circuit, a control circuit, or the like) can be connected between X and Y. For example, even when another circuit is interposed between X and Y, X and Y are functionally connected when a signal output from Xis transmitted to Y. Note that the case where X and Y are functionally connected includes the case where X and Y are directly connected and the case where X and Y are electrically connected.

Note that in the case where there is an explicit description, X and Y are electrically connected, the case where X and Y are electrically connected (i.e., the case where X and Y are connected with another element or another circuit provided therebetween), the case where X and Y are functionally connected (i.e., the case where X and Y are functionally connected with another circuit provided therebetween), and the case where X and Y are directly connected (i.e., the case where X and Y are connected without another element or another circuit provided therebetween) are disclosed in this specification and the like. That is, in the case where there is an explicit description, being electrically connected, the same contents as the case where there is only an explicit description, being connected, are disclosed in this specification and the like.

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y can be expressed as follows.

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, the expression “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order” can be used. Alternatively, the expression “Xis electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order” can be used. When the connection order in a circuit structure is defined by an expression similar to the above examples, a source (or a first terminal or the like) and a drain (or a second terminal or the like) of a transistor can be distinguished from each other to specify the technical scope.

Alternatively, as another expression, the expression “a source (or a first terminal or the like) of a transistor is electrically connected to X through at least a first connection path, the first connection path does not include a second connection path, the second connection path is a path through the transistor and between the source (or the first terminal or the like) of the transistor and a drain (or a second terminal or the like) of the transistor, the first connection path is a path through Z1, the drain (or the second terminal or the like) of the transistor is electrically connected to Y through at least a third connection path, the third connection path does not include the second connection path, and the third connection path is a path through Z2” can be used, for example. Alternatively, the expression “a source (or a first terminal or the like) of a transistor is electrically connected to X through Z1 by at least a first connection path, the first connection path does not include a second connection path, the second connection path includes a connection path through the transistor, a drain (or a second terminal or the like) of the transistor is electrically connected to Y through Z2 by at least a third connection path, and the third connection path does not include the second connection path” can be used. Alternatively, the expression “a source (or a first terminal or the like) of a transistor is electrically connected to X by at least a first electrical path through Z1, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y by at least a third electrical path through Z2, the third electrical path does not include a fourth electrical path, and the fourth electrical path is an electrical path from the drain (or the second terminal or the like) of the transistor to the source (or the first terminal or the like) of the transistor” can be used. When the connection path in a circuit configuration is defined by an expression similar to the above examples, a source (or a first terminal or the like) and a drain (or a second terminal or the like) of a transistor can be distinguished from each other to specify the technical scope.

Note that these expressions are examples and the expression is not limited to these expressions. Here, X, Y, Z1, and Z2 denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

### Example 1

In this example, an MCU (micro control unit) chip including the memory device 100 described in Embodiment 2 and a CPU core was fabricated, and it was verified that the fabricated chip operates with low power consumption.

In this example, the memory device 100 is called DOSRAM (Dynamic Oxide Semiconductor Random Access Memory).

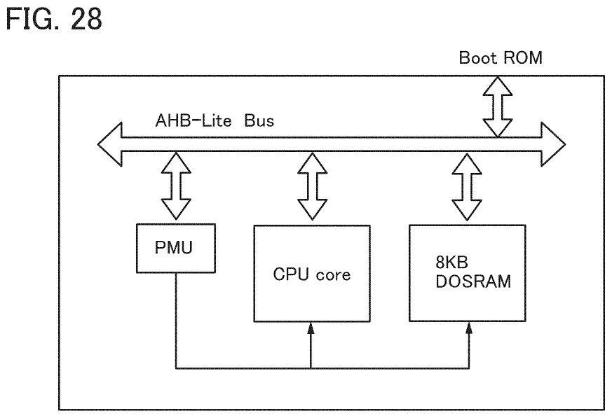

FIG. 28 illustrates a block diagram of the fabricated chip. The chip includes an 8 KB (byte) DOSRAM, a CPU core, a PMU (power management unit), and an AHB-Lite bus. The DOSRAM and a flip-flop in the CPU core include Si transistors and OS transistors formed over the Si transistors. Power supply to the DOSRAM and the CPU core is controlled by the PMU. Data transmission in the chip is performed through a 32-bit bus. Note that information transmission and reception to/from a boot ROM are also illustrated in the chip in FIG. 28.

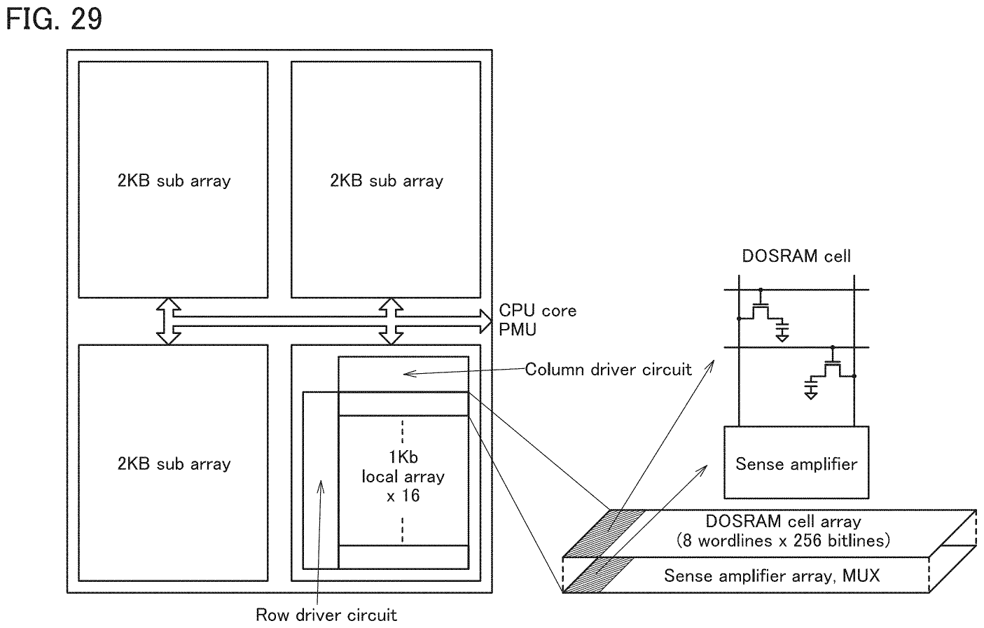

FIG. 29 illustrates a block diagram of the 8 KB DOSRAM. The 8 KB DOSRAM includes four 2 KB sub arrays, and each sub array includes 16 1 Kb (bit) local arrays, a column driver circuit, and a row driver circuit. The 1 Kb local array has a structure in which a DOSRAM cell array including eight word lines (8 wordlines) and 256 bit lines (256 bitlines) is stacked over 128 sense amplifiers (SAs) (which are collectively referred to as a sense amplifier array) and a multiplexer (MUX). This stacked-layer structure makes it possible to reduce a region that is activated during memory access.

The 1 Kb local array in FIG. 29 was fabricated using the memory cell 130 with the folded architecture illustrated in FIG. 10. The sense amplifier in FIG. 29 corresponds to the SMC 10 in FIG. 10. The fabricated memory cell (the circuit NMC in FIG. 10) had an area of 2.9 μm² and a capacitance of 3.5 fF.

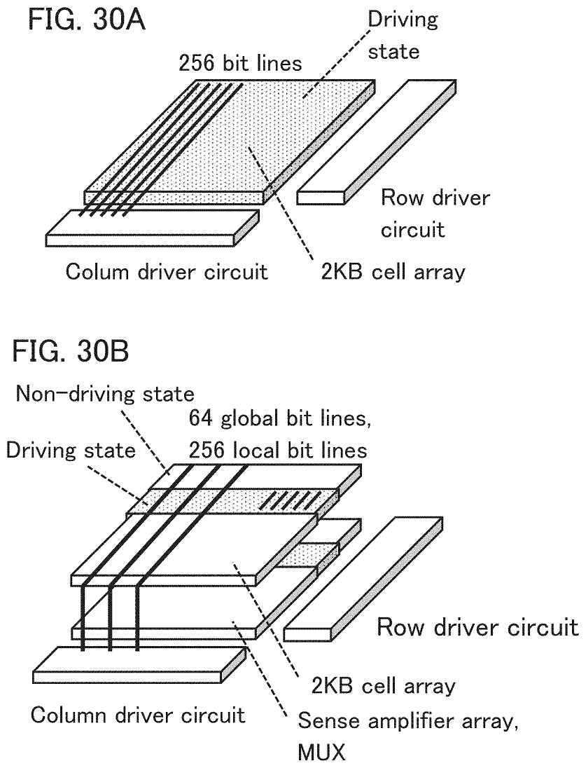

FIG. 30A and FIG. 30B are schematic diagrams each illustrating the structure of the DOSRAM. FIG. 30A illustrates the case where a 2 KB cell array, a column driver, and a row driver are formed in the same layer. In addition, a sense amplifier, a multiplexer, and the like may also be formed in the layer (not illustrated). In FIG. 30A, 256 long bit lines need to be in a driving state. FIG. 30B illustrates the case where a cell array is stacked over a sense amplifier and a multiplexer. The bit lines can be classified into 256 local bit lines (short bit lines) and 64 global bit lines (long bit lines) depending on the stacked-layer structure. Through the multiplexer, 64 of the 256 local bit lines are connected to the global bit lines. The structure of FIG. 30B can reduce the number of long bit lines and bit line capacitance. In addition, storage capacitor can be reduced and load for driving the DOSRAM can be reduced. Furthermore, part of the 2 KB cell array can be in a driving state and the rest of the 2 KB cell array can be in a non-driving state; therefore, the power consumption can be reduced as compared with the structure of the DOSRAM in FIG. 30A.

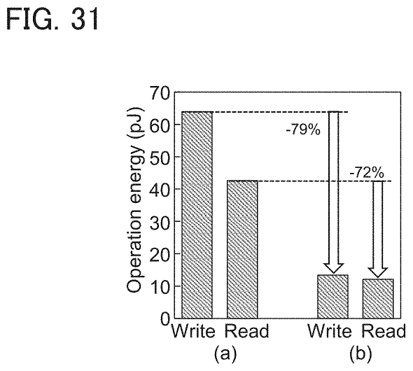

FIG. 31 shows calculation results of active energy of a 2 KB DOSRAM. In FIG. 31, (a) shows the case where a cell array, a sense amplifier, and a multiplexer are formed in the same layer (the case of FIG. 30A), and (b) shows the case where a cell array is stacked over a sense amplifier and a multiplexer (the case of FIG. 30B). Furthermore, operation energy required for writing operation (Write) is shown on the left in each of (a) and (b), and operation energy required for reading operation (Read) is shown on the right in each of (a) and (b). It was found from the results of FIG. 31 that the operation energy of the stacked-layer structure (b) was reduced by 70% or more compared with that of the structure (a) without a stacked-layer structure.

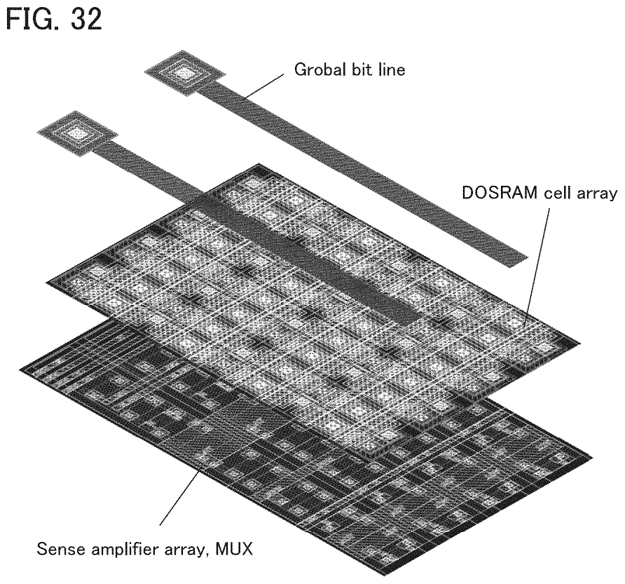

FIG. 32 shows part of the layout of the fabricated DOSRAM. FIG. 32 shows a sense amplifier, a multiplexer, a DOSRAM cell array, and a global bit line.

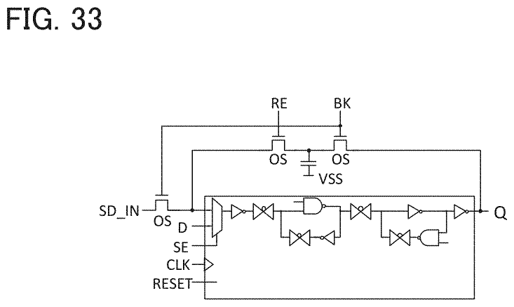

FIG. 33 is a circuit diagram of a flip-flop including OS transistors used in the CPU core (hereinafter referred to as an OS-FF). Three OS transistors and one capacitor are added to a scan flip-flop. In the scan flip-flop in FIG. 33, a signal SD_IN is obtained and a signal Q is output. Backup and recovery of the OS-FF are performed using a backup signal BK and a recovery signal RE transmitted from the PMU. In addition, in the scan flip-flop, one of the signal SD_IN and a signal D is selected, as a signal input to the scan flip-flop, by a select signal SE. Moreover, in the scan flip-flop, operation of the flip-flop is performed by a clock signal CK, and data retained in the scan flip-flop is reset by a signal RESET.

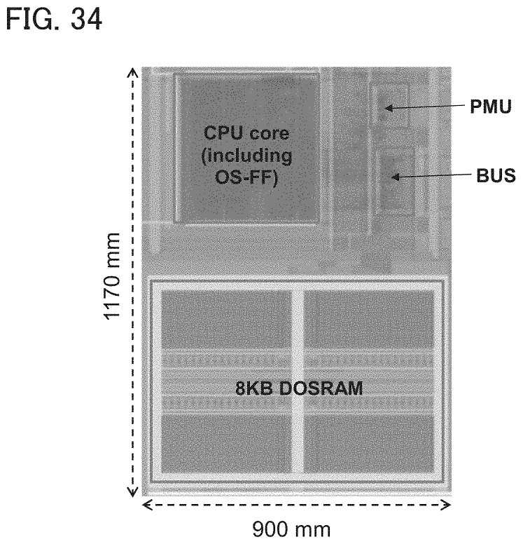

FIG. 34 is an optical micrograph of the fabricated chip. A CPU core including an OS-FF, a PMU, a BUS, and an 8 KB DOSRAM cell array are shown in FIG. 34. The power supply voltage of a logic circuit portion was set to 1.1 V, and the power supply voltages of a circuit using an OS transistor and an I/O were set to 3.3 V. The technology node of the Si transistor was 65 nm and the technology node of the OS transistor was 60 nm.

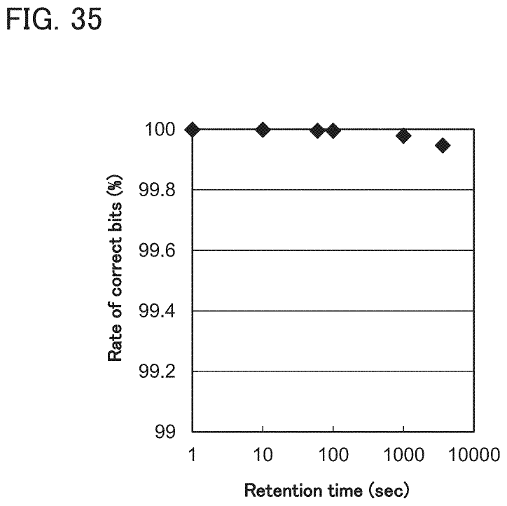

FIG. 35 shows retention characteristics of the fabricated DOSRAM at 85° C. In FIG. 35, the horizontal axis represents retention time and the vertical axis represents the percentage of DOSRAM cells that retain correct data (Rate of correct bits). It was verified that 99.95% of data was retained after an hour. This indicates that the DOSRAM can retain data for a long time without refreshing data. That is, the DOSRAM can perform a long-term power gating.

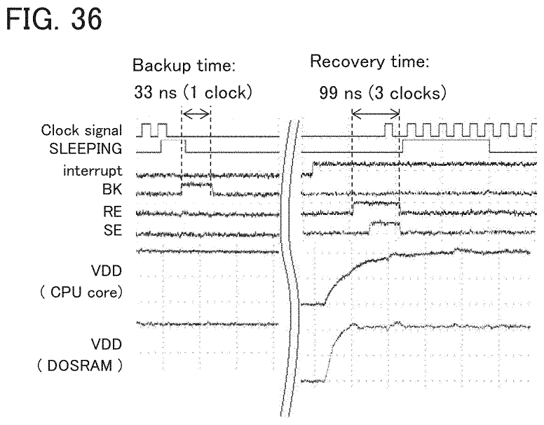

FIG. 36 shows backup-recovery waveforms of the fabricated chip. In a 30-MHz OS-FF, a backup time was 1 clock (33 ns) and a recovery time was three clocks (99 ns). In FIG. 36, a signal (SLEEPING) for stopping the operation of the chip is transmitted to the chip before backup operation is performed and after recovery operation is performed. Furthermore, in FIG. 36, an interrupt signal (interrupt) is transmitted to the chip before the recovery operation is performed. Note that the DOSRAM can retain data without supply of power and does not need backup-recovery operations, and only power ON/OFF may be performed.

Table 1 shows a summary of operation modes and power consumption of the chip. In Table 1, active power of the DOSRAM was measured by repeating nine clock (seven times of reading and two times of writing) operations. As shown in Table 1, a reduction in standby power by power gating was observed in both the DOSRAM and the CPU core.

TABLE 1

| | Acive | Clock Gating | Power Gating |
|---|---|---|---|
| | (μW/MHz) | (μW) | (μW) |
| M0 core | 16.5 | 11.6 | 0.006 |
| 8kB DOSRAM | 11.7 | 1.43 | 0.003 |

Table 2 shows comparison between other low-power-consumption MCUs which have been reported so far and the chip fabricated in this example. In Table 2, A represents data of the MCU described in Non-Patent Document 2, B represents data of the MCU described in Non-Patent Document 3, C represents data of the MCU described in Non-Patent Document 4, and D represents data of the chip fabricated in this example. It was verified that the fabricated chip is superior to the other chips in a technology node, a clock frequency, and active power. It was also verified that the fabricated chip achieves the lowest power consumption regardless of the ratio of active and standby.

TABLE 2

| | A | B | C | D |
|---|---|---|---|---|
| Technology (Si) | 130 nm | 90 nm | 90 nm | 65 nm |
| Memory device | FRAM | SpinRAM | N/A | OS memory |
| Clock frequency (MHz) | 8 | 20 | 16 | 30 |
| Active Power (mW/MHz) | 170 | 145 | 28.3 | 28.2 |
| Standby Power (mW) | 0 | 1.22 | 0.32 | 0.009 |
| 100K-cycle in 1sec (mW) | 17.00 | 15.71 | 3.15 | 2.83 |
| 10K-cycle in 1sec (mW) | 1.70 | 2.67 | 0.60 | 0.29 |
| 1K-cycle in 1sec (mW) | 0.17 | 1.36 | 0.35 | 0.04 |

### Example 2

In this example, an actually fabricated MCU chip that includes the memory device 100 described in Embodiment 2 and a CPU core will be described.

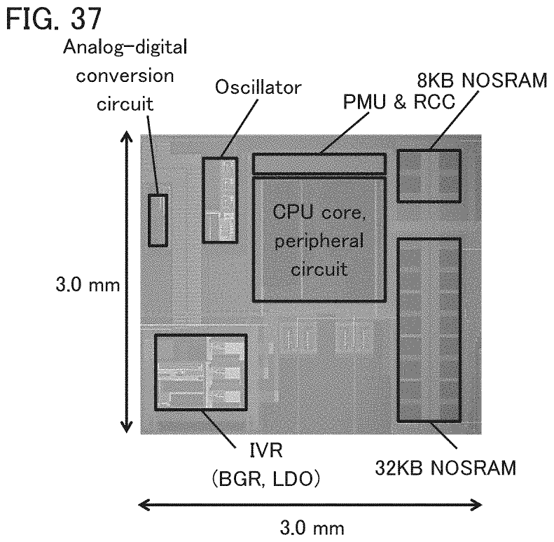

FIG. 37 is an optical micrograph of the fabricated MCU chip. The MCU chip includes a region including a CPU core and a peripheral circuit, a region including a power management unit (PMU) and a reset and clock controller (RCC), an analog-digital conversion circuit, an oscillator, an internal voltage generation circuit (IVR), an 8 KB NOSRAM, and a 32 KB NOSRAM.

Note that the CPU core includes a flip-flop including OS transistors (OS-FF), like the CPU core of the MCU chip described in Example 1. Therefore, backup at the time of power gating in the CPU core and recovery after power supply resumption are performed.

That is, the MCU chip shown in FIG. 37 has the structure of the MCU chip described in Example 1, in which an analog-digital conversion circuit and an oscillator are provided and the 8 KB DOSRAM is replaced with an 8 KB NOSRAM and a 32 KB NOSRAM. The MCU chip shown in FIG. 36 is different from the MCU chip in Example 1 in supporting a transmission standard based on a serial interface (UART) and including a power supply circuit. In addition, a supply voltage of the power supply circuit is 1.2 V and 3.3 V.

The MCU chip shown in FIG. 37 uses a technology node of a 110-nm Si CMOS and a 60-nm IGZO-FET (BEOL).

The operation frequency of the MCU chip in FIG. 37 is 48 MHz at the maximum.

Here, the power consumption of the MCU chip shown in FIG. 37 is described. In the whole system of the MCU chip in FIG. 37, power consumption at the time of operation at 48 MHz at the maximum was 6.60 mV and standby power at the time of power gating was 880 nV.

A time required for saving data of the OS-FF provided in the CPU core was approximately 20 ns, and a time required for data restoration of the OS-FF and a restart of the whole MCU system was 4.8 μs.

The above results confirm a reduction in the standby power of the MCU chip in FIG. 37, the time required for saving data, the time required for data restoration and a restart of the CPU core, and a reduction in each of the times.

### Example 3

A cutoff frequency f_{T} of a field-effect transistor including IGZO with a CAAC structure in its semiconductor layer (also referred to as a “CAAC-IGZO FET”) was measured under various temperature environments. The cutoff frequency f_{T} refers to a frequency (input frequency) at which a current gain is 1 (0 dB).

The cutoff frequency f_{T} is obtained by the following formula (1).

$$\begin{matrix}[ Formula 1 ] & \\ {f}_{T} = \frac{{g}_{m}}{2 π {C}_{g}} & ( 1 )\end{matrix}$$

Here, C_{g} and gₘ represent gate capacitance of a transistor and a mutual conductance, respectively. A mutual conductance gₘ at a certain drain voltage can be obtained by the following formula (2).

$$\begin{matrix}[ Formula 2 ] & \\ {g}_{m} = {( \frac{\partial {I}_{d}}{\partial {V}_{g}} )}_{{V}_{d}} & ( 2 )\end{matrix}$$

In the above formula (2), V_{g}, I_{d}, and V_{d} are a gate voltage, a drain current, and a drain voltage of a transistor, respectively.

<Measurement of Cutoff Frequency f_{T}>

The cutoff frequency f_{T} of a CAAC-IGZO FET with L=30 nm and W=30 nm was measured. Note that L represents the channel length of the CAAC-IGZO FET, and W represents the channel width of the CAAC-IGZO FET. The measurement was performed under temperature environments of −40° C., 27° C., and 85° C. The measurement was performed on 672 CAAC-IGZO FETs connected in parallel (M=672).

The cutoff frequencies f_{T} of a Si FET at 27° C. and 150° C. were measured. Measurement DUT was performed with the use of a Si FET with L/W=60 nm/480 nm. For the Si FET measurement, 21 Si FETs were connected in parallel (M=21).

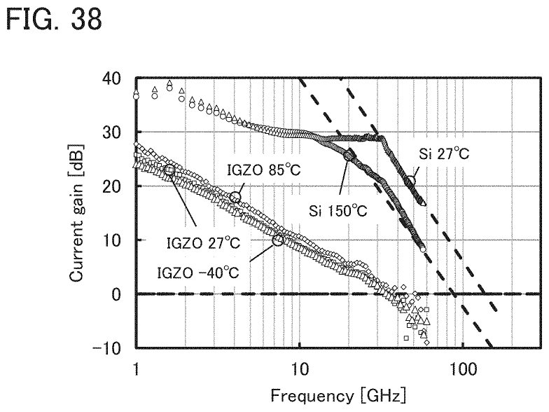

FIG. 38 shows the measurement results. A frequency at which a current gain was 1, i.e., 0 dB was obtained by extrapolation to obtain the cutoff frequency f_{T} of the Si FET. The cutoff frequency f_{T} at the measurement temperature of 27° C. was 137 GHz and the cutoff frequency f_{T} at the measurement temperature of 150° C. was 88 GHz. At this time, the change rate in the cutoff frequency f_{T} of the Si FET at the measurement temperatures from 27° C. to 150° C. was −36%.

In the case of the CAAC-IGZO FET, the cutoff frequency f_{T} at the measurement temperature of −40° C. was 34 GHz, the cutoff frequency f_{T} at the measurement temperature 27° C. was 34 GHz, and the cutoff frequency f_{T} at the measurement temperature 85° C. was 38 GHz. At this time, the change rate in the cutoff frequency f_{T} of the CAAC-IGZO FET at the measurement temperatures from 27° C. to 85° C. was 12%. In addition, no change was observed in the cutoff frequency f_{T} of the CAAC-IGZO FET at the measurement temperatures from 27° C. to −40° C.

Although the measurement temperature range differs between the Si FET and the CAAC-IGZO FET, it is probable that temperature dependence of the cutoff frequency f_{T} of the CAAC-IGZO FET is lower than that of the Si FET.

### REFERENCE NUMERALS

ADDR: signal, BGL: wiring, BL: wiring, BLB: wiring, BW: signal, C0: capacitor, C1: capacitor, C2: capacitor, C21: capacitor, C23: capacitor, C22: capacitor, C24: capacitor, C3: capacitor, CE: signal, CLK: signal, DB1: data, DB2: data, GW: signal, LBL: wiring, LBLB: wiring, M21: transistor, M24: transistor, M31: transistor, M34: transistor, NWL: wiring, NWL_0: wiring, NWL_1: wiring, OS1: transistor, PCL: wiring, PON1: signal, PON2: signal, RDA: signal, VCS: wiring, VDDM: wiring, VHH: wiring, VLL: wiring, VPC: wiring, WDA: signal, WL: wiring, RWL: wiring, WBL: wiring, RBL: wiring, SL: wiring, t1: time, t2: time, t3: time, t4: time, t5: time, t6: time, t7: time, t8: time, Tac1: transistor, Tac2: transistor, Tdr1: transistor, Tdr2: transistor, Teq1: transistor, Tld1: transistor, Tld2: transistor, Tpc1: transistor, Tpc2: transistor, Tr1: transistor, Tr2: transistor, Tr3: transistor, Tr4: transistor, Try: transistor, Tr6: transistor, 10: SMC, 20: NVM, 21: NVM, 30: LPC, 100: memory device, 110: memory cell array, 110A: memory cell array, 110B: memory cell array, 111: peripheral circuit, 112: control circuit, 115: peripheral circuit, 121: row decoder, 122: column decoder, 123: row driver, 124: column driver, 125: input circuit, 126: output circuit, 127: voltage generation circuit, 127a: voltage generation circuit, 127b: voltage generation circuit, 128: voltage retention circuit, 130: memory cell, 130A: memory cell, 141: PSW, 142: PSW, 200: transistor, 200M: transistor, 200T: transistor, 205: conductor, 205a: conductor, 205b: conductor, 211: insulator, 212: insulator, 214: insulator, 216: insulator, 222: insulator, 224: insulator, 230: oxide, 230a: oxide, 230b: oxide, 230c: oxide, 240: conductor, 240a: conductor, 240b: conductor, 241: insulator, 241a: insulator, 241b: insulator, 242: conductor, 242a: conductor, 242b: conductor, 243: oxide, 243a: oxide, 243b: oxide, 246: conductor, 246a: conductor, 246b: conductor, 250: insulator, 260: conductor, 260a: conductor, 260b: conductor, 272: insulator, 273: insulator, 274: insulator, 275: insulator, 276: conductor, 277: insulator, 278: conductor, 279: insulator, 280: insulator, 281: conductor, 282: insulator, 283: insulator, 284: insulator, 287: insulator, 290: conductor, 292: capacitor, 292A: capacitor, 292B: capacitor, 292C: capacitor, 294: conductor, 295: insulator, 296: insulator, 297: conductor, 298: insulator, 299: conductor, 300: transistor, 311: semiconductor substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 411: element layer, 413: transistor layer, 413[1]: transistor layer, 413[m]: transistor layer, 415: memory device layer, 415[1]: memory device layer, 415[2]: memory device layer, 415[3]: memory device layer, 415[4]: memory device layer, 415[p−1]: memory device layer, 415[p]: memory device layer, 415[n]: memory device layer, 420: memory device, 420A: memory device, 420B: memory device, 420C: memory device, 422: region, 424: conductor, 426: conductor, 428: conductor, 430: conductor, 470: memory unit, 470[1]: memory unit, 470[m]: memory unit, 611: substrate, 612: circuit region, 613: separation region, 614: separation line, 615: chip, 650: electronic component, 652: printed circuit board, 653: semiconductor device, 654: substrate, 655: lead, 700: wristwatch terminal, 701: housing, 702: winding crown, 703: display portion, 704: belt, 705: sensing unit, 710: mobile phone, 711: housing, 712: microphone, 713: external connection port, 714: operation button, 716: display portion, 717: speaker, 720: laptop personal computer, 721: housing, 722: display portion, 723: keyboard, 724: pointing device, 730: goggle-type display, 731: temple, 732: housing, 735: cable, 736: battery, 737: display portion, 740: video camera, 741: housing, 742: housing, 743: display portion, 744: operation key, 745: lens, 746: joint, 750: automobile, 751: car body, 752: wheel, 753: dashboard, 754: light, 801: cloud field, 802: field, 803: IoT end device, 804: power consumption, 805: processing performance, 831: master device, 832: M2M interface, 841: IoT end device, 842: industrial robot, 881: home, 882: office, 883: cloud, 884: factory, 885: factory, 886: factory, 1300: CPU, 1302: power controller, 1303: power switch, 1304: cache memory, 1305: bus interface, 1306: debug interface, 1307: control device, 1308: program counter, 1309: pipeline register, 1310: pipeline register, 1311: ALU, 1312: register file, 1330: CPU core, 1331: PMU, 1332: peripheral circuit, 1333: data bus, 1400: RFIC, 1404: antenna, 1405: rectifier circuit, 1406: constant voltage circuit, 1407: demodulation circuit, 1408: modulation circuit, 1409: logic circuit, 1410: RAM, 1411: ROM, 1412: battery, 1420: communication device, 1421: antenna, 1422: radio signal

1. A semiconductor device comprising:
a power management unit, a CPU core, and a memory device,
wherein the power management unit comprises a power switch and a power controller,
wherein the power switch is configured to control supply of a power supply voltage to the CPU core and the memory device,
wherein the power controller is configured to control operation of the power switch,
wherein the memory device comprises a working memory and a long-term memory storage portion,
wherein the CPU core is configured to transmit a timing of stopping the supply of the power supply voltage, to the power controller, and
wherein the memory device is configured to save data retained in the working memory to the long-term memory storage portion before the supply of the power supply voltage is stopped by the power switch.

2. The semiconductor device according to claim 1,
wherein each of the power management unit, the CPU core, and the memory device comprises a transistor, and
wherein the transistor comprises silicon in a channel formation region.

3. The semiconductor device according to claim 1,
wherein the power management unit comprises a transistor, and
wherein the transistor comprises silicon in a channel formation region.

4. The semiconductor device according to claim 1,
wherein the CPU core comprises a transistor, and
wherein the transistor comprises silicon in a channel formation region.

5. The semiconductor device according to claim 1,
wherein the memory device comprises a transistor, and
wherein the transistor comprises silicon in a channel formation region.

6. The semiconductor device according to claim 1,
wherein each of the power management unit, the CPU core, and the memory device comprises a transistor, and
wherein the transistor comprises a metal oxide in a channel formation region.

7. The semiconductor device according to claim 1,
wherein the power management unit comprises a transistor, and
wherein the transistor comprises a metal oxide in a channel formation region.

8. The semiconductor device according to claim 1,
wherein the CPU core comprises a transistor, and
wherein the transistor comprises a metal oxide in a channel formation region.

9. The semiconductor device according to claim 1,
wherein the memory device comprises a transistor, and
wherein the transistor comprises a metal oxide in a channel formation region.

10. The semiconductor device according to claim 6,
wherein the metal oxide is an In-M-Zn oxide (M is aluminum, gallium, yttrium, tin, copper, vanadium, beryllium, boron, titanium, iron, nickel, germanium, zirconium, molybdenum, lanthanum, cerium, neodymium, hafnium, tantalum, tungsten, or magnesium).

11. A semiconductor wafer comprising:
a plurality of semiconductor devices according to claim 1; and
a separation region.

12. An electronic device comprising:
the semiconductor device according to claim 1; and
a battery.
